(19) United States
(12) Patent Application Publication
(10) Pub. No.: US 2024/0337932 A1
(43) Pub. Date: Oct. 10, 2024

(54) PHOTOSENSITIVE RESIN COMPOSITION, PHOTOSENSITIVE RESIN LAYER USING THE SAME, AND COLOR FILTER

(71) Applicant: SAMSUNG SDI CO., LTD., Yongin-si (KR)

(72) Inventors: Heejo MOON, Suwon-si (KR); Baek Soung PARK, Suwon-si (KR); Juho JUNG, Suwon-si (KR); Chang-Hyun KWON, Suwon-si (KR); Kwangwon SEO, Suwon-si (KR)

(21) Appl. No.: 18/384,038

(22) Filed: Oct. 26, 2023

(30) Foreign Application Priority Data
Apr. 5, 2023 (KR) 10-2023-0044995

(51) Int. Cl. G03F 7/004; C09B 23/10; G03F 7/00

(52) U.S. Cl. CPC G03F 7/0048; C09B 23/105; G03F 7/0007; G02B 5/223

(57) ABSTRACT

A photosensitive resin composition, a photosensitive resin layer, and a color filter manufactured using the same the photosensitive resin composition includes a colorant; a photopolymerizable compound; a photopolymerization initiator; a binder resin; and a solvent, wherein the colorant includes a pigment, a dispersant, and a dispersion aid represented by Chemical Formula 1:

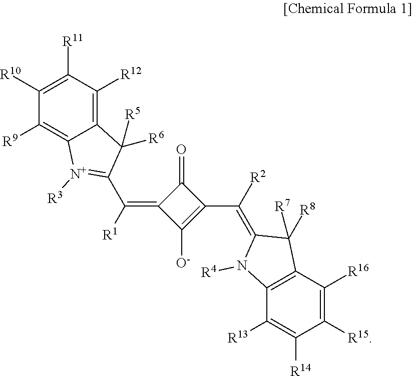

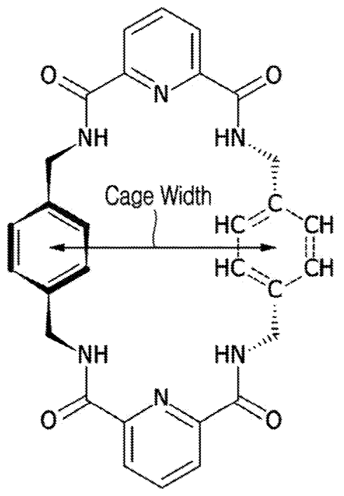

### CROSS-REFERENCE TO RELATED APPLICATION

This application claims priority to and the benefit of Korean Patent Application No. 10-2023-0044995, filed in the Korean Intellectual Property Office on Apr. 5, 2023, the entire contents of which are incorporated herein by reference.

### BACKGROUND

### 1. Field of the Invention

Embodiments relate to a photosensitive resin composition, a photosensitive resin layer using the same, and a color filter.

### 2. Description of the Related Art

A liquid crystal display device among many types of displays has an advantage of lightness, thinness, low cost, low power consumption for operation, and improved adherence to an integrated circuit and has been more widely used for a laptop computer, a monitor, and a TV screen.

### SUMMARY

The embodiments may be realized by providing a photosensitive resin composition, including a colorant; a photopolymerizable compound; a photopolymerization initiator; a binder resin; and a solvent, wherein the colorant includes a pigment, a dispersant, and a dispersion aid represented by Chemical Formula 1,

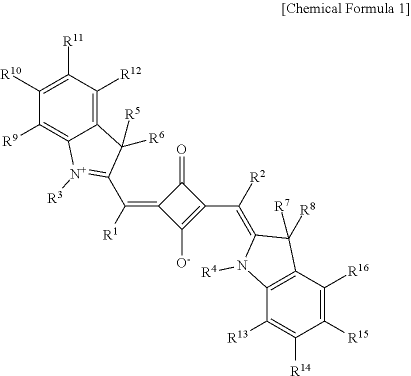

in Chemical Formula 1, R¹ to R⁸ are each independently a hydrogen atom or a substituted or unsubstituted C1 to C20 alkyl group, and R⁹ to R¹⁶ are each independently a hydrogen atom, a substituted or unsubstituted C1 to C20 alkyl group, or a basic functional group, provided that at least one of R⁹ to R¹⁶ is a basic functional group.

The embodiments may be realized by providing a photosensitive resin layer manufactured using the photosensitive resin composition according to an embodiment.

The embodiments may be realized by providing a color filter including the photosensitive resin layer according to an embodiment.

The embodiments may be realized by providing a display device including the color filter according to an embodiment.

### BRIEF DESCRIPTION OF THE DRAWINGS

Features will become apparent to those of skill in the art by describing in detail exemplary embodiments with reference to the attached drawing in which:

the FIGURE shows the structure of the shell and its width.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

As used herein, when specific definition is not otherwise provided, “substituted” refers to replacement of at least one hydrogen atom of a compound by a substituent of a halogen atom (F, Cl, Br, or I), a hydroxy group, a C1 to C20 alkoxy group, a nitro group, a cyano group, an amine group, an imino group, an azido group, an amidino group, a hydrazino group, a hydrazono group, a carbonyl group, a carbamyl group, a thiol group, an ester group, an ether group, a carboxyl group or a salt thereof, a sulfonic acid group or a salt thereof, a phosphoric acid or a salt thereof, a C1 to C20 alkyl group, a C2 to C20 alkenyl group, a C2 to C20 alkynyl group, a C6 to C30 aryl group, a C3 to C20 cycloalkyl group, a C3 to C20 cycloalkenyl group, a C3 to C20 cycloalkynyl group, a C2 to C20 heterocycloalkyl group, a C2 to C20 heterocycloalkenyl group, a C2 to C20 heterocycloalkynyl group, or a combination thereof.

As used herein, when specific definition is not otherwise provided, a “heterocycloalkyl group”, a “heterocycloalkenyl group”, a “heterocycloalkynyl group,” and a “heterocycloalkylene group” refer to each cyclic compound of cycloalkyl, cycloalkenyl, cycloalkynyl, and cycloalkylene including at least one heteroatom of N, O, S, or P.

As used herein, when a definition is not otherwise provided, the term “combination” refers to mixing or copolymerization. Additionally, “copolymerization” refers to block copolymerization to random copolymerization, and “copolymer” refers to block copolymerization to random copolymerization.

As used herein, when a definition is not otherwise provided, hydrogen is bonded at the position when a chemical bond is not drawn where supposed to be given.

As used herein, when specific definition is not otherwise provided, “**” refers to a linking point with the same or different atom or chemical formula.

As used herein, when a definition is not otherwise provided, “particle diameter” may mean a diameter of a particle, and the diameter of the particle may be a Z-average value of the particle diameter measured through dynamic light scattering.

### (Photosensitive Resin Composition)

Some example embodiments provide a photosensitive resin composition including, e.g., (A) a colorant; (B) a photopolymerizable compound; (C) a photopolymerization initiator; (D) a binder resin; and (E) a solvent. In an implementation, the colorant may include, e.g., a pigment, a dispersant, and a dispersion aid represented by Chemical Formula 1.

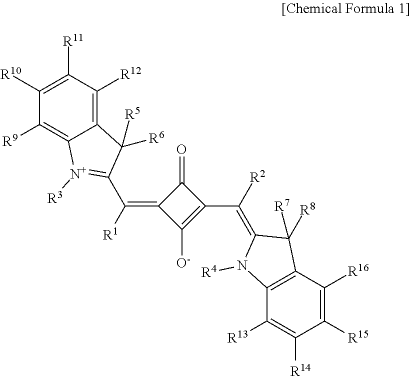

wherein, in Chemical Formula 1,
R¹ to R⁸ may each independently be a hydrogen atom or a substituted or unsubstituted C1 to C20 alkyl group; and
R⁹ to R¹⁶ may each independently be a hydrogen atom, a substituted or unsubstituted C1 to C20 alkyl, or a basic functional group, provided that at least one of R⁹ to R¹⁶ is a basic functional group.

### (A) Colorant

The photosensitive resin composition of some example embodiments may be a pigment-type photosensitive resin composition, and the colorant may include a pigment. A color filter manufactured by using a pigment-type photosensitive resin composition may have a limit in terms of luminance and a contrast ratio caused by a pigment particle size. Additionally, in order to be applied to image sensors, a resin composition made of smaller particles may be required to form fine patterns. In order to achieve this, a compound and a composition using the same that helps disperse the pigment and prevent re-agglomeration.

In an implementation, the colorant may include the dispersion aid represented by Chemical Formula 1.

The dispersion aid represented by Chemical Formula 1 may function as a dispersion aid and a colorant.

(1) First, the dispersion aid represented by Chemical Formula 1 may have a mother moiety in which both benzene rings of squarene (SQ) may each be substituted with an indole ring, and at least one of both indole rings may contain a basic functional group and may interact with the pigment, the dispersant, or both.

In an implementation, in the dispersion aid represented by Chemical Formula 1, the basic functional group may be covalently bonded with the dispersant or dispersion resin, and the mother moiety may be covalently bonded with the pigment, which may help the interaction between the pigment and the dispersant. As a result, it may be possible to provide a photosensitive resin composition that has high dispersibility and dispersion stability and has excellent coloring power and luminance even if the color filter is thinned.

(2) Second, in the dispersion aid represented by Chemical Formula 1, the mother moiety may express green color, so that the coloring power and luminance of the color filter may be further improved.

In an implementation, by using the photosensitive resin composition according to some example embodiments, a color filter and display device with excellent color reproducibility and luminance may be implemented.

A description of each substituent in Chemical Formula 1 is as follows.

R¹ to R⁸ may each independently be, e.g., a hydrogen atom or a substituted or unsubstituted C1 to C20 alkyl group.

In some example embodiments, both R¹ and R² may be, e.g., hydrogen atoms.

In some example embodiments, both R³ and R⁴ may be, e.g., hydrogen atoms.

In some example embodiments, R⁵ to R⁸ may each independently be, e.g., a substituted or unsubstituted C1 to C20 alkyl group. In an implementation, all of R⁵ to R⁸ may be, e.g., methyl.

In some example embodiments, one of R⁹ to R¹², and one of R¹³ and R¹⁶ may each independently be a basic functional group. In an implementation, R¹¹ and R¹⁵ may each independently be a basic functional group. In an implementation, the dispersion aid may be represented by the following chemical formula.

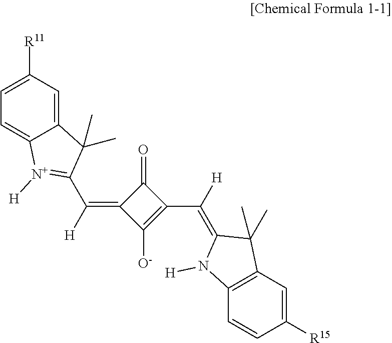

R¹¹ and R¹⁵ may each be independently a basic functional group.

In example embodiments, the basic functional group may be, e.g., secondary to quaternary amine groups. In an implementation, the basic functional group may be represented by one of the following chemical formulae.

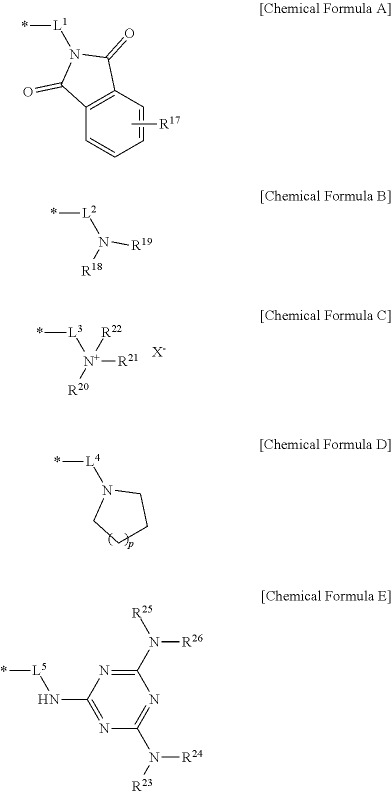

wherein, in Chemical Formulas A to E,
L¹ to L⁵ may each independently be, e.g., a single bond or a substituted or unsubstituted C1 to C20 alkylene group;
R¹⁷ to R²⁶ may each independently be, e.g., a hydrogen atom, a substituted or unsubstituted C1 to C20 alkyl group, or *-L⁶-N(R²⁷)(R²⁸);
L⁶ may be, e.g., a single bond or a substituted or unsubstituted C1 to C20 alkylene group,
R²⁷ and R²⁸ may each independently be, e.g., a hydrogen atom or a substituted or unsubstituted C1 to C20 alkyl;
X may be, e.g., a halogen element; and
p may be an, e.g., integer of 0 to 5.

In some example embodiments, L¹ to L⁵ may each independently be, e.g., a substituted or unsubstituted C1 to C20 alkylene group. In an implementation, all of L¹ to L⁵ may be methylene.

In some example embodiments, R¹⁷ may be, e.g., a hydrogen atom.

In some example embodiments, both R¹⁸ and R¹⁹ may be, e.g., hydrogen atoms.

In some example embodiments, R²⁰ to R²² may each independently be, e.g., a substituted or unsubstituted C1 to C20 alkyl group. In an implementation, R²⁰ to R²² may all be, e.g., methyl.

In some example embodiments, X may be, e.g., a fluorine atom, a bromine atom, a chlorine atom, or an iodine atom. In an implementation, X may be, e.g., an iodine atom.

In some example embodiments, p may be 1 or 2. In an implementation, p may be 2.

In some example embodiments, R²⁵ and R²⁶ may each independently be, e.g., a substituted or unsubstituted C1 to C20 alkyl group. In an implementation, both R²⁵ and R²⁶ may be, e.g., ethyl.

In some example embodiments, R²⁵ and R²⁶ may each independently be, e.g., *-L⁶-N(R²⁷)(R²⁸). In an implementation, L⁶ may be, e.g., a substituted or unsubstituted C1 to C20 alkylene group. In an implementation, L⁶ may be, e.g., methylene. Meanwhile, both R²⁷ and R²⁸ may be, e.g., a substituted or unsubstituted C1 to C20 alkyl group. In an implementation, L⁶ may be, e.g., methyl.

In some example embodiments, the basic functional group may be represented by one of the following chemical formulae.

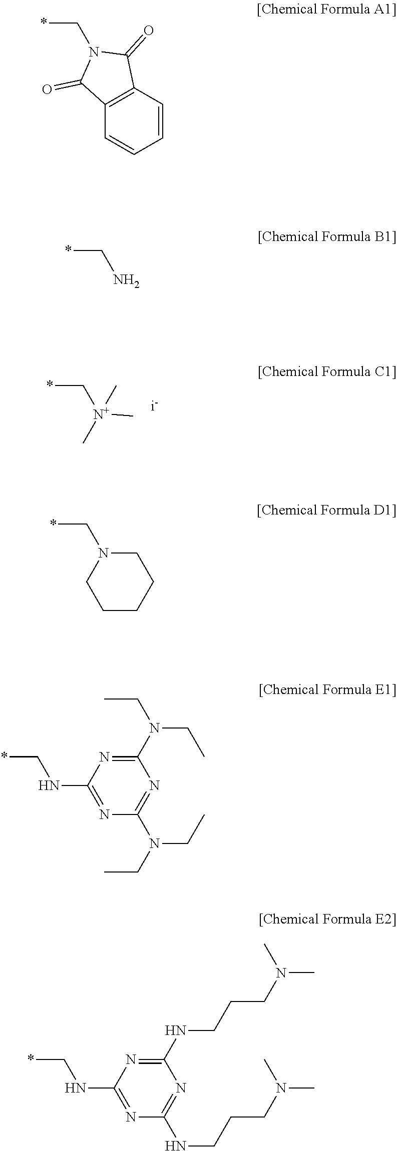

If the dispersion aid is represented by Chemical Formula 1, it may have a symmetric structure or an asymmetric structure. However, a symmetric structure may be advantageous over an asymmetric structure in that the synthesis step may be short and easy, thereby lowering the manufacturing cost.

In some example embodiments, the dispersion aid may be represented by one of the following chemical formulae.

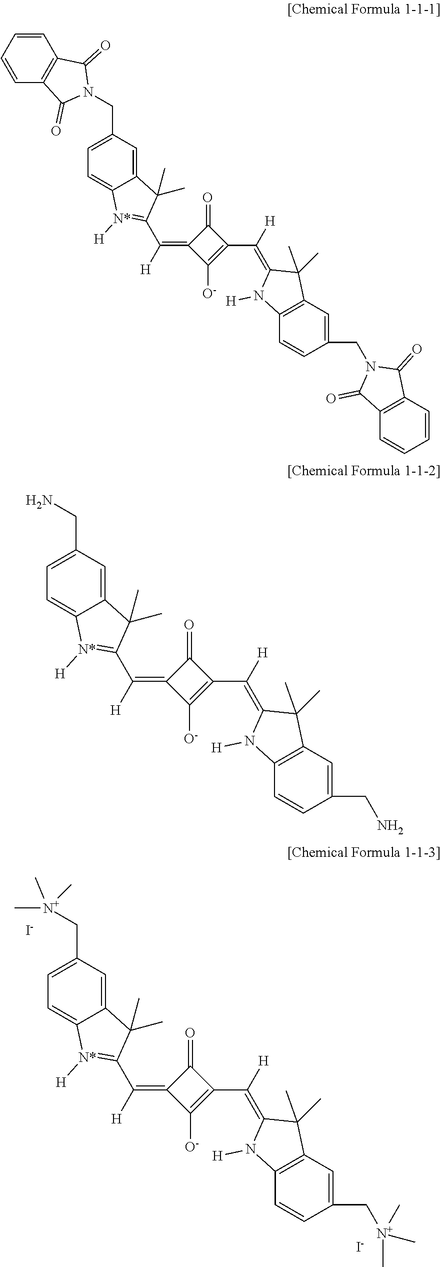

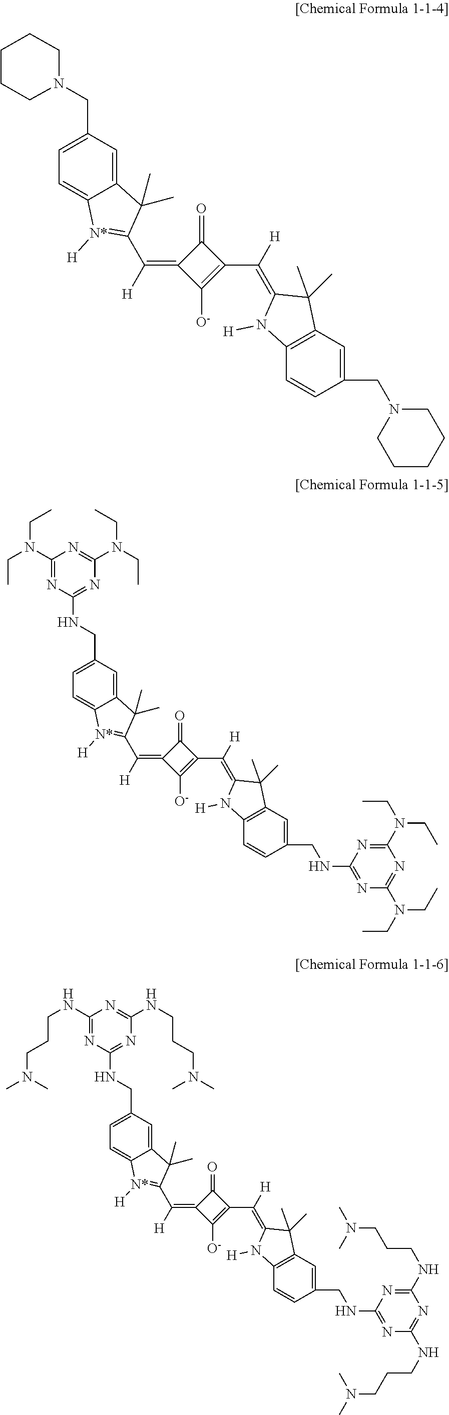

In some example embodiments, the dispersion aid may include the compound represented by Chemical Formula 1 as a core, and may further include a shell surrounding the core and represented by Chemical Formula 2.

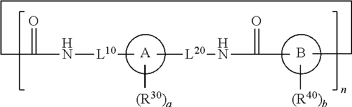

In Chemical Formula 2, A and B may each independently be or include, e.g., a benzene ring, a pyridine ring, or a furan ring. L¹⁰ and L²⁰ may each independently be or include, e.g., a single bond, or a substituted or unsubstituted C1 to C10 alkylene group. R³⁰ and R⁴⁰ may each independently be, e.g., a halogen. a and b may each independently be, e.g., an integer of 0 to 4. n may be, e.g., an integer of 2 to 10.

In some example embodiments, A may be, e.g., a benzene ring; and B may be, e.g., a benzene ring, a pyridine ring, or a furan ring.

In some example embodiments, L¹⁰ and L²⁰ may each independently be, e.g., a substituted or unsubstituted C1 to C10 alkylene group. In an implementation, both L¹⁰ and L²⁰ may be, e.g., methylene.

In some example embodiments, n may be, e.g., 2.

In some example embodiments, the shell may be represented by one of the following chemical formulae.

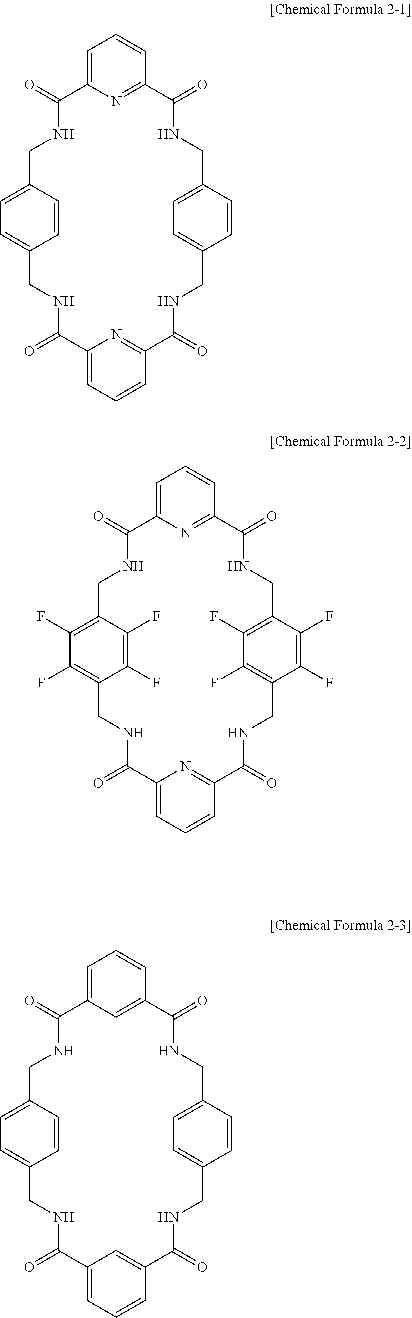 [SMILES: O=C1NCc2ccc(cc2)CNC(=O)c2cccc(n2)C(=O)NCc2ccc(cc2)CNC(=O)c2cccc1n2 ; O=C1NCc2c(F)c(F)c(c(F)c2F)CNC(=O)c2cccc(n2)C(=O)NCc2c(F)c(F)c(c(F)c2F)CNC(=O)c2cccc1n2 ; O=C1NCc2ccc(cc2)CNC(=O)c2cccc(c2)C(=O)NCc2ccc(cc2)CNC(=O)c2cccc1c2]

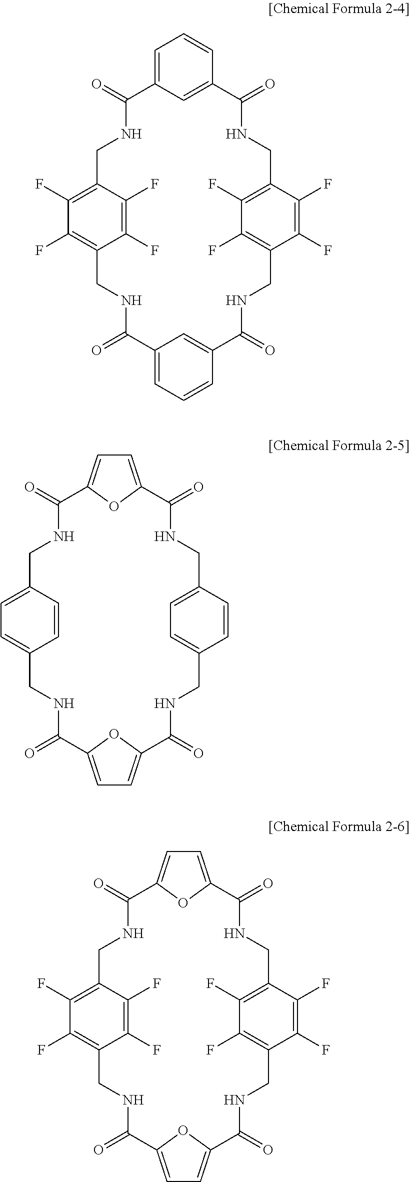 [SMILES: O=C1NCc2c(F)c(F)c(c(F)c2F)CNC(=O)c2cccc(c2)C(=O)NCc2c(F)c(F)c(c(F)c2F)CNC(=O)c2cccc1c2 ; O=C1NCc2ccc(cc2)CNC(=O)c2ccc(o2)C(=O)NCc2ccc(cc2)CNC(=O)c2ccc1o2 ; O=C1NCc2c(F)c(F)c(c(F)c2F)CNC(=O)c2ccc(o2)C(=O)NCc2c(F)c(F)c(c(F)c2F)CNC(=O)c2ccc1o2]

The dispersion aids having the core-shell structure are typically as follows:

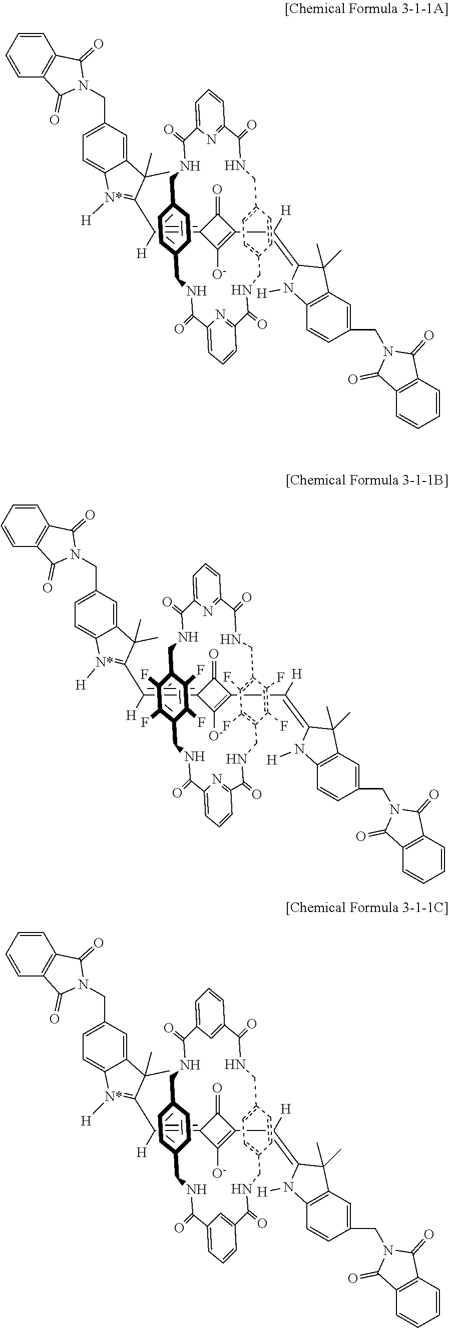

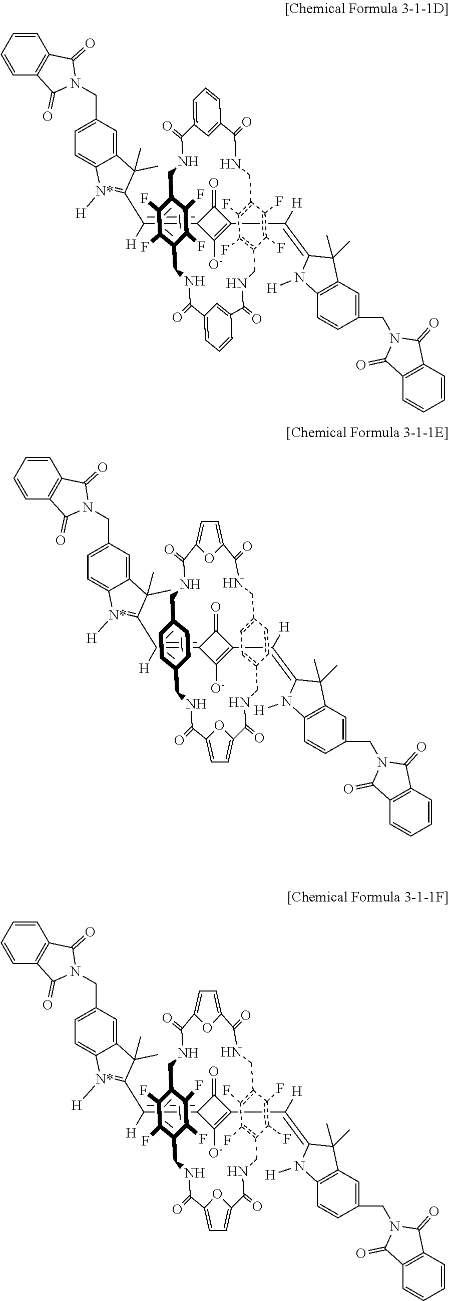

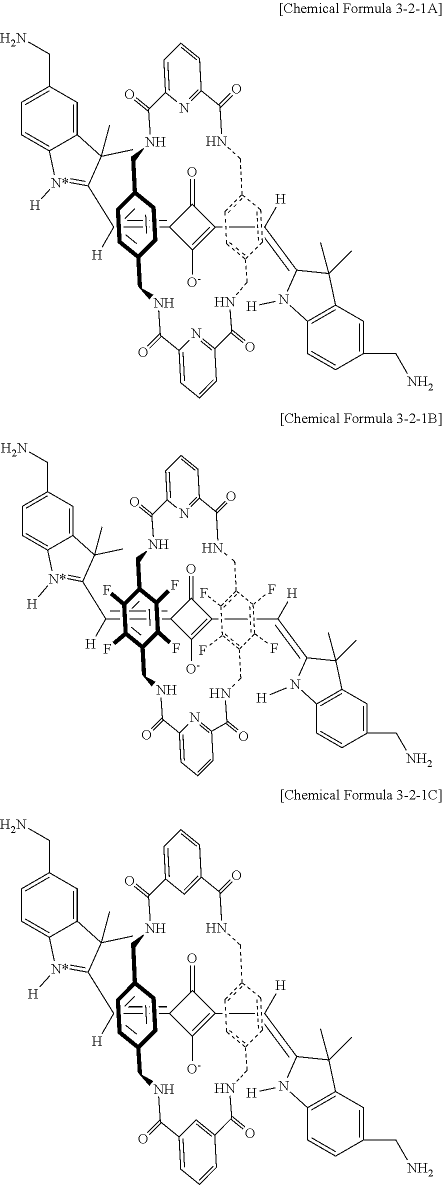

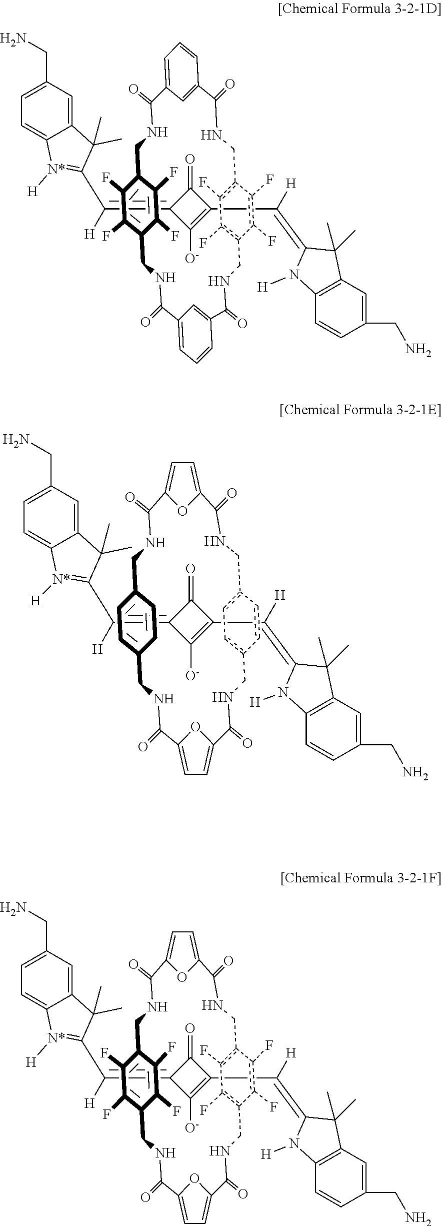

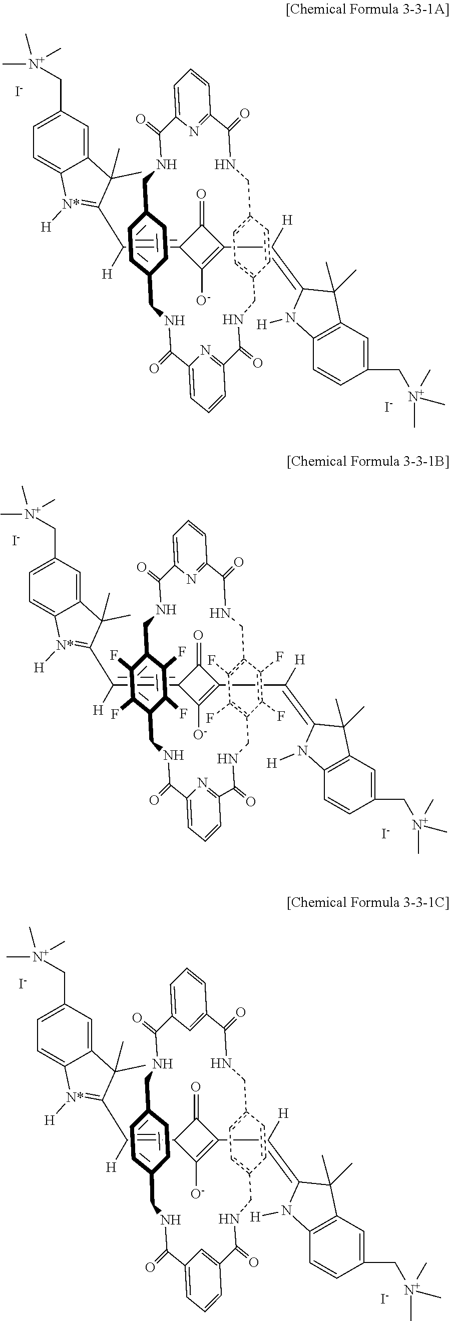

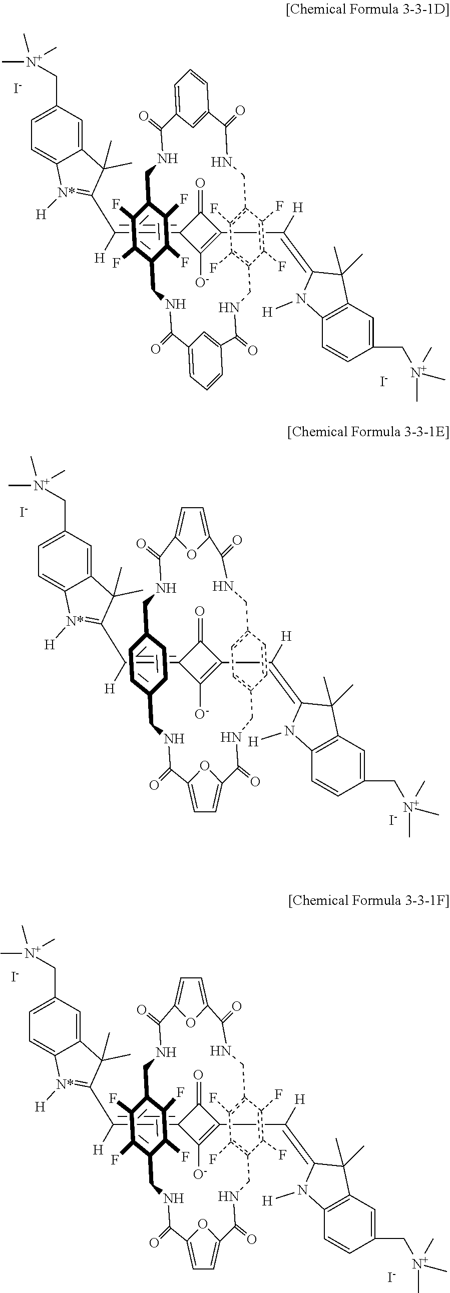

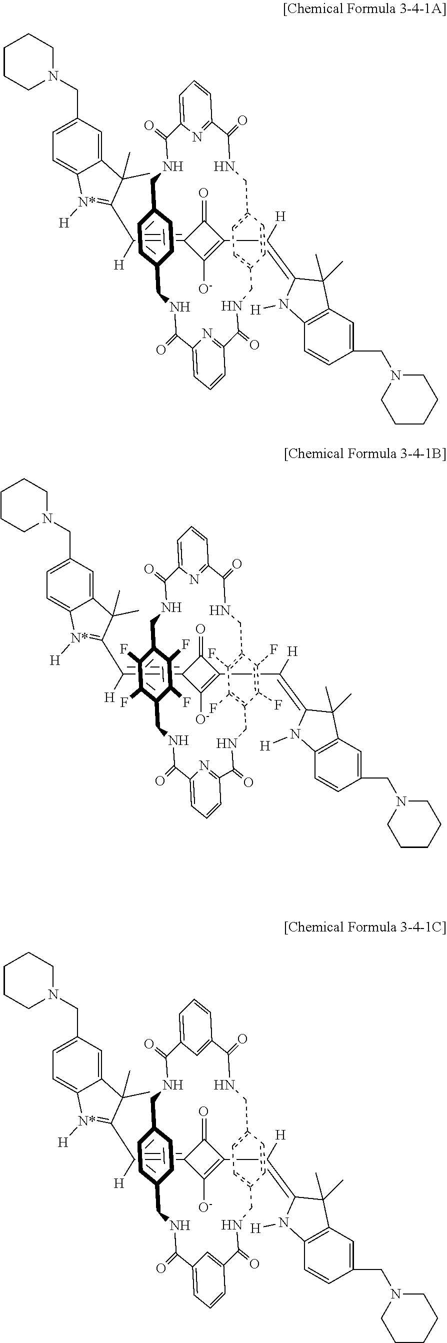

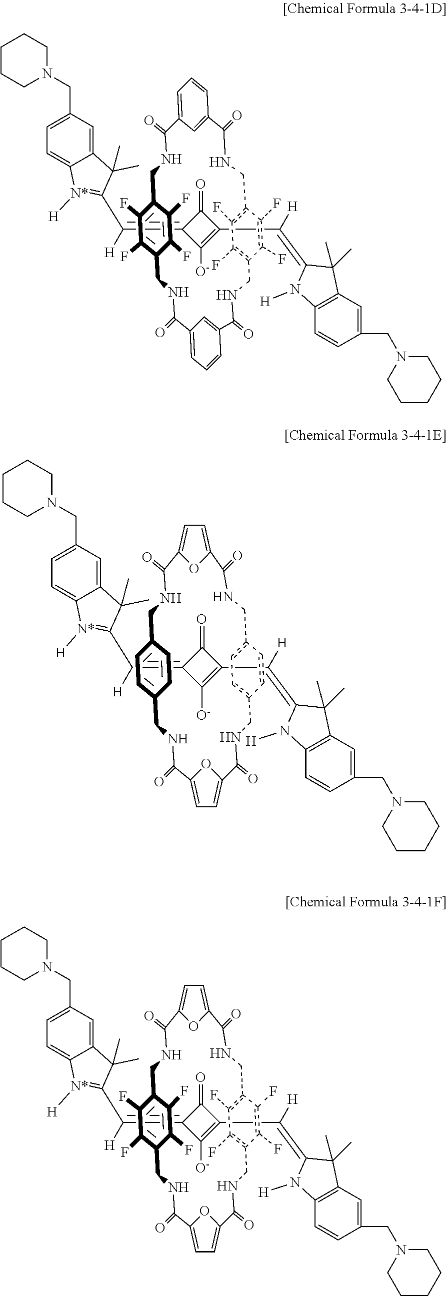

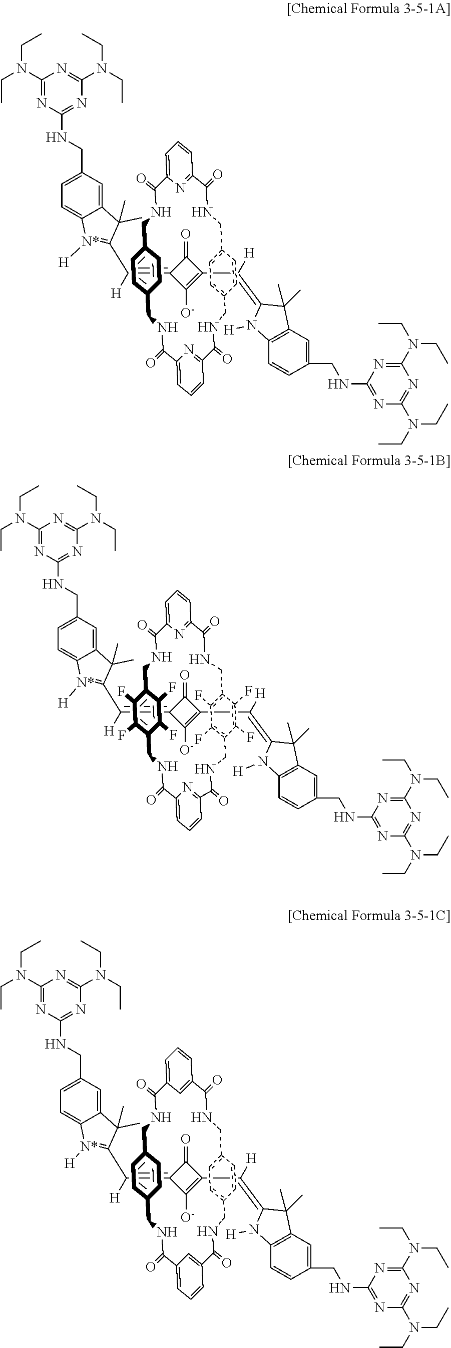

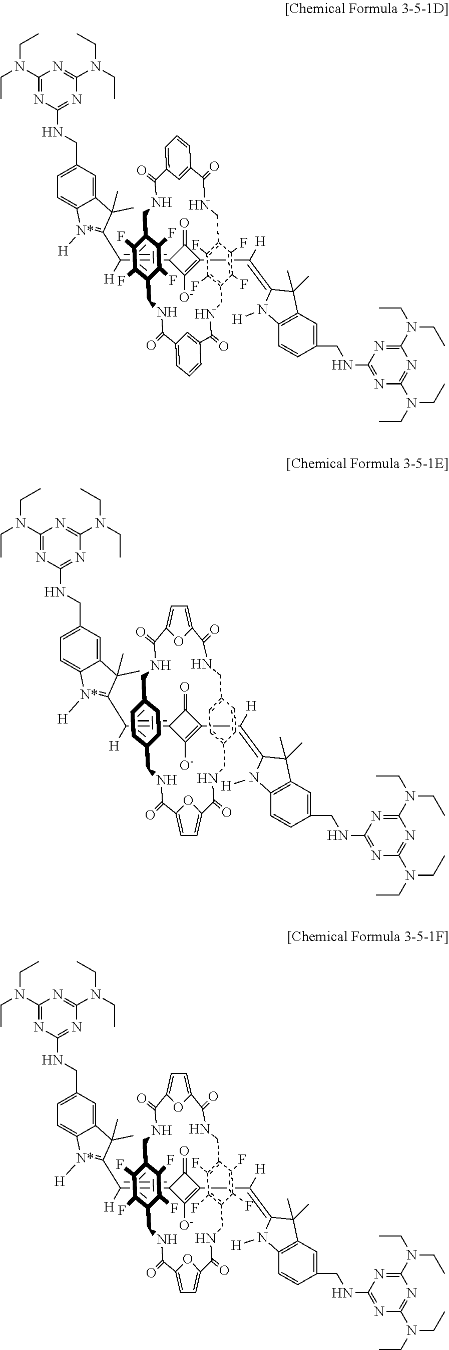

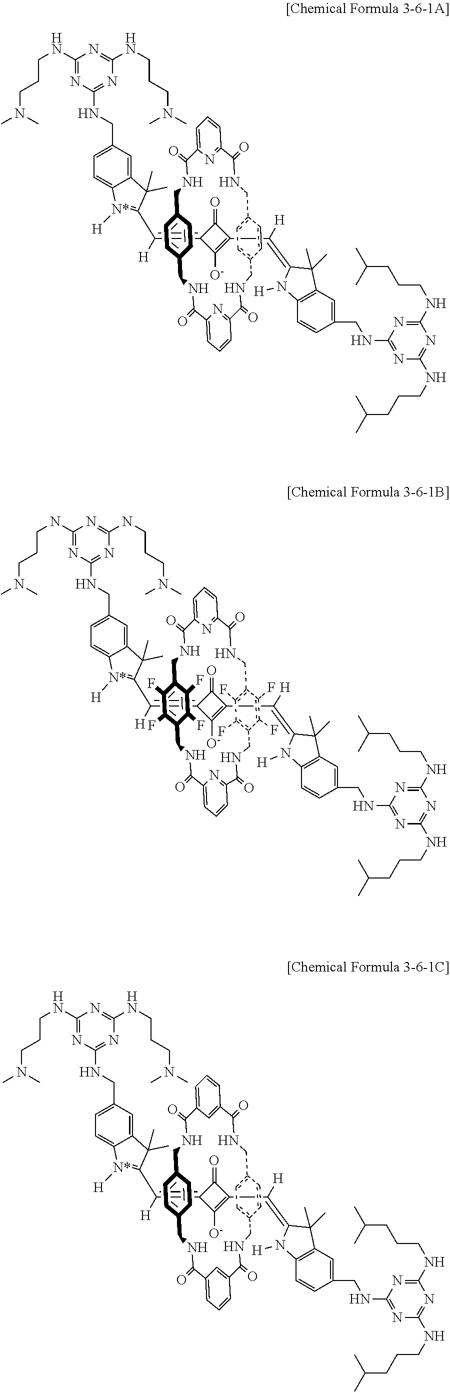

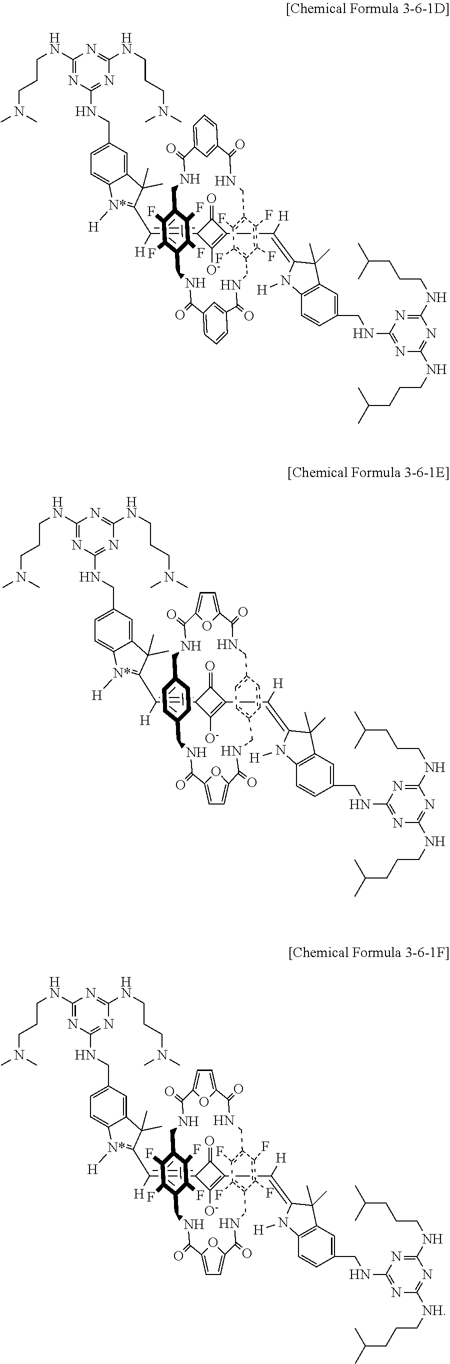

The length of the core represented by Chemical Formula 1 may be about 1 nm to about 3 nm, e.g., about 1.5 nm to about 2 nm. If the core represented by Chemical Formula 1 has a length within the above ranges, a core-shell structured compound may be easily formed. In other words, if the core represented by Chemical Formula 1 has a length within the above ranges, the shell of the macrocyclic compound may surround the core represented by Chemical Formula 1. If using a different core that does not fall within the above range, it could be difficult to expect improvement in durability because it could be difficult for the shell to form a structure surrounding the core.

A cage width in this disclosure refers to an internal distance of the shell, e.g., in a shell represented by Chemical Formula 2, a distance between two different phenylene groups in which both methylene groups are linked (refer to the FIGURE).

The wider the cage width of the shell, the more likely slip-off of the cage could occur, and the higher the possibility that the shell could come out of the dye, which in turn may reduce the durability of the dye. However, if the cage width of the shell were to be too small, synthesis itself could be impossible. Accordingly, the cage size of the shell may be appropriately set.

A cage width of the shell may range from about 6.5 Å to about 7.5 Å and a volume of the shell may range from about 10 Å to about 16 Å. If the shell has a cage width within the range, a core-shell dye having a structure surrounding the core represented by Chemical Formula 1 may be obtained, and thus a color filter having improved durability may be realized if the core-shell dye may be added to a photosensitive resin composition.

The shell represented by Chemical Formula 2 may include an amide bond (—CONH—). In an implementation, the hydrogen atom included in the amide bond of the shell represented by Chemical Formula 2 may form a non-covalent bond with the oxygen atom of the compound represented by Chemical Formula 1. In an implementation, the two atoms may form a hydrogen bond, which may help enhance the durability of the core-shell dye.

As described above, the dispersion aid may have a squarene-based mother moiety that expresses green color, and may further improve the green coloring power and luminance of the photosensitive resin composition.

In an implementation, the dispersion aid may have a maximum absorption wavelength (Δₘₐₓ) of about 530 to about 700 nm.

In an implementation, the core itself represented by Chemical Formula 1 may have a maximum absorption peak at a wavelength of about 530 nm to about 680 nm. However, the maximum absorption peak of the core-shell dye may vary depending on whether a halogen group is introduced into the shell represented by Chemical Formula 2. If the halogen group is introduced into the shell represented by Chemical Formula 2, the dispersion aid may have a maximum absorption peak at a wavelength of about 530 nm to about 700 nm, in an implementation, about 550 to about 700 nm.

That is, if the halogen group is introduced into the shell represented by Chemical Formula 2, compared to the case where a halogen group is not introduced, the maximum absorption peak of the core-shell compound may shift to a long wavelength region of about 20 nm, and excellent matching to the green wavelength band may be achieved.

If the dispersion aid is a compound of a core-shell structure, it may include a core containing the compound represented by Chemical Formula 1 and the shell at a molar ratio of about 1:1. If the core and shell are present in the above molar ratio, a coating layer (shell) surrounding the core containing the compound represented by Chemical Formula 1 may be well formed.

The dispersion aid may be included in an amount of about 0.5 wt % to about 6 wt %, e.g., about 1 wt % to about 5 wt %, about 2 wt % to about 3 wt %, based on a total weight of the photosensitive resin composition.

Additionally, a weight ratio of the dispersion aid and the pigment may be about 1:20 to about 1:70, in an implementation, about 1:30 to about 1:60, e.g., about 1:40 to about 1:50. Herein, the dispersion aid and the pigment are each solid.

Within the above ranges, dispersibility and dispersion stability of the photosensitive resin composition according to some example embodiments may be improved while the coloring power and luminance of the color filter may be improved.

The colorant may include a pigment, and the pigment may include a green pigment, a blue pigment, a red pigment, a violet pigment, a yellow pigment, and a black pigment.

The red pigment may include, e.g., C.I. Red Pigment 254, C.I. Red Pigment 255, C.I. Red Pigment 264, C.I. Red Pigment 270, C.I. Red Pigment 272, C.I. Red Pigment 177, C.I. Red Pigment 89, and the like in the color index, which may be used alone or in a mixture of two or more.

The violet pigment may include, e.g., C.I. Violet Pigment 23 (V.23), C.I. Violet Pigment 29, Dioxazine Violet, First Violet B, Methyl Violet Lake, Indanethrene Brilliant Violet, and the like in the color index, which may be used alone or in a mixture of two or more.

The green pigment may include, e.g., C.I. Green Pigment 7, C.I. Green Pigment 36, C.I. Green Pigment 58, C.I. Green Pigment 59 and the like in the color index, which may be used alone or in a mixture of two or more.

The blue pigment may include, e.g., copper phthalocyanine pigments such as C.I. Blue Pigment 15:6, C.I. Blue Pigment 15, C.I. Blue Pigment 15:1, C.I. Blue Pigment 15:2, C.I. Blue Pigment 15:3, C.I. Blue Pigment 15:4, C.I. Blue Pigment 15:5, C.I. Blue Pigment 15:6, C.I. Blue Pigment 16 in the color index, which may be used alone or in a mixture of two or more.

The yellow pigment may include, e.g., an isoindoline-based pigment such as C.I. Yellow Pigment 185, C.I. Yellow Pigment 139, and the like, a quinophthalone-based pigment such as C.I. Yellow Pigment 138, a nickel complex pigment such as C.I. Yellow Pigment 150 in the color index, which may be used alone or in a mixture of two or more.

The black pigment may include, e.g., aniline black, perylene black, titanium black, carbon black, and the like in the color index, which may be used alone or in a mixture of two or more.

The pigments may be used alone or in a mixture of two or more. In an implementation, the pigment may include, e.g., a green pigment, a yellow pigment, or a mixture thereof.

The dispersant may help the pigment to be uniformly dispersed in the dispersion, and nonionic, anionic or cationic dispersants may be used, respectively. In an implementation, polyalkylene glycol or its ester, polyoxy alkylene, a polyhydric alcohol ester alkylene oxide adduct, an alcohol alkylene oxide adduct, sulfonic acid ester, sulfonic acid salt, carboxylic acid ester, carboxylic acid salt, alkyl amide alkylene oxide adduct, an alkylamine, or the like may be used, and these may be used alone or in combination of two or more.

The pigment may be included in the photosensitive resin composition for a color filter in the form of a dispersion. This pigment dispersion may further include a dispersion solvent, a dispersion resin, or the like in addition to the pigment, the dispersant, and the dispersion aid. Solid pigment excluding the solvent may be included in an amount of about 5 wt % to about 20 wt %, e.g., about 8 wt % to about 15 wt %, based on a total weight of the pigment dispersion.

Solvents for the pigment dispersion may be ethylene glycol acetate, ethyl cellosolve, propylene glycol methyl ether acetate, ethyl lactate, polyethylene glycol, cyclohexanone, propylene glycol methyl ether, and the like, and desirably propylene glycol methyl ether acetate.

The dispersion resin may be an acrylic resin containing a carboxy group, which may improve stability of the pigment dispersion and may also improve pixel patternability.

The colorant may include the pigment and may further include a dye, and in this case, the resin composition of some example embodiments may be a hybrid type composition. In addition, the dye may include a metal complex dye.

The metal complex dye may be a compound having maximum absorbance in the wavelength range of 200 nm to 650 nm, and if the compound has absorbance in the above range in order to match the color coordinates to the combination of dyes, the metal complex dye of all colors that dissolves in an organic solvent may be used.

In an implementation, the metal complex dye may be a green dye having maximum absorbance in a wavelength range of 530 nm to 680 nm, a yellow dye having maximum absorbance in a wavelength range of 200 nm to 400 nm, an orange dye having a maximum absorbance in a wavelength range of 300 nm to 500 nm, a red dye having maximum absorbance in a wavelength range of 500 nm to 650 nm, or a combination thereof.

The metal complex dye may be a direct dye, an acidic dye, a basic dye, an acidic mordant dye, a sulfide dye, a reduction dye, an azoic dye, a dispersion dye, a reactive dye, an oxidation dye, an oil-soluble dye, an azo dye, an anthraquinone dye, an indigoid dye, a carbonium ion dye, a phthalocyanine dye, a nitro dye, a quinoline dye, a cyanine dye, a polymethine dye, or a combination thereof.

The metal complex dye may include at a metal ion, e.g., Mg, Ni, Cu, Co, Zn, Cr, Pt, Pd, or Fe. As used herein, the term “or” is not an exclusive term, e.g., “A or B” would include A, B, or A and B

The metal complex dye may be a complex selected from, e.g., C.I. Solvent Dye such as C.I. Solvent Green 1, 3, 4, 5, 7, 28, 29, 32, 33, 34, 35, or the like; C.I. Acid Dye such as C.I. Acid Green 1, 3, 5, 6, 7, 8, 9, 11, 13, 14, 15, 16, 22, 25, 27, 28, 41, 50, 50:1, 58, 63, 65, 80, 104, 105, 106, 109, or the like; C.I. Direct Dye such as C.I. Direct Green 25, 27, 31, 32, 34, 37, 63, 65, 66, 67, 68, 69, 72, 77, 79, 82, or the like; C.I. Basic Dye such as C.I. Basic Green 1, or the like; C.I. Mordant Dye such as C.I. Mordant Green 1, 3, 4, 5, 10, 13, 15, 19, 21, 23, 26, 29, 31, 33, 34, 35, 41, 43, 53, or the like; C.I. Green pigments such as Pigment Green 7, 36, 58, or the like; Solvent Yellow 19, Solvent Yellow 21, Solvent Yellow 25, Solvent Yellow 79, Solvent Yellow 82, Solvent Yellow 88, Solvent Orange 45, Solvent Orange 54, Solvent Orange 62, Solvent Orange 99, Solvent Red 8, Solvent Red 32, Solvent Red 109, Solvent Red 112, Solvent Red 119, Solvent Red 124, Solvent Red 160, Solvent Red 132, or Solvent Red 218, and the metal ion.

The metal complex dye may have a solubility of greater than or equal to about 5, in an implementation about 5 to about 10, in a solvent used in the photosensitive resin composition according to some embodiments, that is, a solvent to be described later. The solubility may be obtained by an amount (g) of the dye dissolved in 100 g of the solvent. If the solubility of the metal complex dye is within the above range, compatibility with other components constituting the photosensitive resin composition according to some embodiments and coloring power may be secured, and precipitation of the dye may be prevented.

The solvent may be, e.g., propylene glycol monomethyl ether acetate (PGMEA), ethyl lactate (EL), ethylene glycol ethyl acetate (EGA), cyclohexanone, 3-methoxy-1-butanol, or a combination thereof.

If it has the above range, it may be usefully used for color filters such as LCDs and LEDs that express high luminance and high contrast ratio in a desired color coordinate.

The metal complex dye may be included in an amount of about 0.01 wt % to about 1 wt %, e.g., about 0.01 wt % to about 0.5 wt % based on a total weight of the photosensitive resin composition. If the metal complex dye is used in the above range, high luminance and contrast ratio may be exhibited in a desired color coordinate.

If the dye and the pigment are mixed and used, they may be mixed in a weight ratio of about 0.1:99.9 to about 99.9:0.1, in an implementation about 1:9 to about 9:1. If mixed in the above weight ratio range, chemical resistance and maximum absorption wavelength may be controlled within an appropriate range, and high luminance and contrast ratio may be exhibited in a desired color coordinate.

The colorant may be included in an amount of about 5 wt % to about 50 wt %, in an implementation about 6 wt % to about 40 wt %, e.g., about 7 wt % to about 30 wt % based on a total solid content of the photosensitive resin composition. If the colorant is included within the above range, a coloring effect and developability may be improved.

### (B) Photopolymerizable Compound

The photopolymerizable compound may be a mono-functional or multi-functional ester of (meth)acrylic acid including at least one ethylenic unsaturated double bond.

The photopolymerizable compound may cause sufficient polymerization during exposure in a pattern-forming process and form a pattern having excellent heat resistance, light resistance, and chemical resistance due to the ethylenic unsaturated double bond.

In an implementation the photopolymerizable compound may be ethylene glycol di(meth)acrylate, diethylene glycol di(meth)acrylate, triethylene glycol di(meth)acrylate, propylene glycol di(meth)acrylate, neopentyl glycol di(meth)acrylate, 1,4-butanediol di(meth)acrylate, 1,6-hexanediol di(meth)acrylate, bisphenol A di(meth)acrylate, pentaerythritol di(meth)acrylate, pentaerythritol tri(meth)acrylate, pentaerythritol tetra(meth)acrylate, pentaerythritol hexa(meth)acrylate, dipentaerythritol di(meth)acrylate, dipentaerythritol tri(meth)acrylate, dipentaerythritol penta(meth)acrylate, dipentaerythritol hexa(meth)acrylate, bisphenol A epoxy(meth)acrylate, ethylene glycol monomethylether (meth)acrylate, trimethylol propane tri(meth)acrylate, tris(meth)acryloyloxyethyl phosphate, novolacepoxy (meth)acrylate, and the like.

Commercially available examples of the photopolymerizable compound may be as follows. The mono-functional (meth)acrylic acid ester may include Aronix M-101®, Aronix M-111®, Aronix M-114® (Toagosei Chemistry Industry Co., Ltd.); KAYARAD TC-110S®, KAYARAD TC-120S® (Nippon Kayaku Co., Ltd.); V-158®, V-2311® (Osaka Organic Chemical Ind., Ltd.), and the like. In an implementation, a difunctional (meth)acrylic acid ester may include Aronix M-210®, Aronix M-240®, Aronix M-6200® (Toagosei Chemistry Industry Co., Ltd.), KAYARAD HDDA®, KAYARAD HX-220®, KAYARAD R-604® (Nippon Kayaku Co., Ltd.), V-260®, V-312®, V-335 HP® (Osaka Organic Chemical Ind., Ltd.), and the like. In an implementation, a tri-functional (meth)acrylic acid ester may include Aronix M-309®, Aronix M-400®, Aronix M-405®, Aronix M-450®, Aronix M-7100®, Aronix M-8030®, Aronix M-8060 ® (Toagosei Chemistry Industry Co., Ltd.); KAYARAD TMPTA®, KAYARAD DPCA-20®, KAYARAD DPCA-30®, KAYARAD DPCA-60®, KAYARAD DPCA-120® (Nippon Kayaku Co., Ltd.); V-295®, V-300®, V-360®, V-GPT®, V-3PA®, V-400® (Osaka Yuki Kayaku Kogyo Co. Ltd.), and the like. These may be used alone or as a mixture of two or more.

The photopolymerizable compound may be used by treating it with an acid anhydride to provide better developability.

The photopolymerizable compound may be included in an amount of about 0.1 wt % to about 20 wt %, in an implementation about 1 wt % to about 15 wt %, e.g., about 2 wt % to about 13 wt %, based on a total weight of the photosensitive resin composition. If the photopolymerizable compound is included within the above range, sufficient curing may occur during exposure to light in the pattern formation process, resulting in excellent reliability and excellent developability in an alkaline developer.

### (C) Photopolymerization Initiator

The photopolymerization initiator may be an initiator commonly used in photosensitive resin compositions, e.g., an acetophenone-based compound, a benzophenone-based compound, a thioxanthone-based compound, a benzoin-based compound, a triazine-based compound, an oxime-based compound, or a combination thereof.

In an implementation, the acetophenone-based compound may be 2,2′-diethoxy acetophenone, 2,2′-dibutoxy acetophenone, 2-hydroxy-2-methylpropinophenone, p-t-butyltrichloro acetophenone, p-t-butyldichloro acetophenone, 4-chloro acetophenone, 2,2′-dichloro-4-phenoxy acetophenone, 2-methyl-1-(4-(methylthio)phenyl)-2-morpholinopropan-1-one, 2-benzyl-2-dimethylamino-1-(4-morpholinophenyl)-butan-1-one, and the like.

In an implementation, the benzophenone-based compound may be benzophenone, benzoyl benzoate, benzoyl methyl benzoate, 4-phenyl benzophenone, hydroxy benzophenone, acrylated benzophenone, 4,4′-bis(dimethyl amino)benzophenone, 4,4′-bis(diethylamino)benzophenone, 4,4′-dimethylaminobenzophenone, 4,4′-dichlorobenzophenone, 3,3′-dimethyl-2-methoxybenzophenone, and the like.

In an implementation, the thioxanthone-based compound may be thioxanthone, 2-methylthioxanthone, isopropyl thioxanthone, 2,4-diethyl thioxanthone, 2,4-diisopropyl thioxanthone, 2-chlorothioxanthone, and the like.

In an implementation, benzoin-based compound may be benzoin, benzoin methyl ether, benzoin ethyl ether, benzoin isopropyl ether, benzoin isobutyl ether, benzyldimethylketal, and the like.

In an implementation, the triazine-based compound may be 2,4,6-trichloro-s-triazine, 2-phenyl 4,6-bis(trichloromethyl)-s-triazine, 2-(3′, 4′-dimethoxystyryl)-4,6-bis(trichloromethyl)-s-triazine, 2-(4′-methoxynaphthyl)-4,6-bis(trichloromethyl)-s-triazine, 2-(p-methoxyphenyl)-4,6-bis(trichloromethyl)-s-triazine, 2-(p-tolyl)-4,6-bis(trichloro methyl)-s-triazine, 2-biphenyl 4,6-bis(trichloro methyl)-s-triazine, bis(trichloromethyl)-6-styryl-s-triazine, 2-(naphthol-yl)-4,6-bis(trichloromethyl)-s-triazine, 2-(4-methoxynaphthol-yl)-4,6-bis(trichloromethyl)-s-triazine, 2-4-bis(trichloromethyl)-6-piperonyl-s-triazine, 2-4-bis(trichloromethyl)-6-(4-methoxystyryl)-s-triazine, and the like.

In an implementation, the oxime-based compound may be an O-acyloxime-based compound, 2-(o-benzoyloxime)-1-[4-(phenylthio)phenyl]-1,2-octanedione, 1-(o-acetyloxime)-1-[9-ethyl-6-(2-methylbenzoyl)-9H-carbazol-3-yl]ethanone, O-ethoxycarbonyl-α-oxyamino-1-phenylpropan-1-one, and the like. In an implementation, of the O-acyloxime-based compound may be 1,2-octanedione, 2-dimethylamino-2-(4-methylbenzyl)-1-(4-morpholin-4-yl-phenyl)-butan-1-one, 1-(4-phenylsulfanyl phenyl)-butane-1,2-dione2-oxime-O-benzoate, 1-(4-phenylsulfanyl phenyl)-octane-1,2-dione2-oxime-O-benzoate, 1-(4-phenylsulfanyl phenyl)-octan-1-oneoxime-O-acetate and 1-(4-phenylsulfanyl phenyl)-butan-1-oneoxime-O-acetate, and the like.

In addition to the above compounds, the photopolymerization initiator may include a carbazole-based compound, a diketone-based compound, a sulfonium borate-based compound, a diazo-based compound, an imidazole-based compound, a biimidazole-based compound, and a fluorene-based compound.

The photopolymerization initiator may be used with a photosensitizer capable of causing a chemical reaction by absorbing light and becoming excited and then, transferring its energy.

In an implementation, the photosensitizer may be tetraethylene glycol bis-3-mercapto propionate, pentaerythritol tetrakis-3-mercapto propionate, dipentaerythritol tetrakis-3-mercapto propionate, and the like.

The photopolymerization initiator may be included in an amount of about 0.1 wt % to about 5 wt %, e.g., about 1 wt % to about 3 wt % based on a total weight of the photosensitive resin composition. If the photopolymerization initiator is included within the ranges, sufficient photopolymerization may occur during exposure in a pattern-forming process, excellent reliability may be realized, heat resistance, light resistance, and chemical resistance of patterns, resolution and close contacting properties may be improved, and decrease of transmittance due to a non-reaction initiator may be prevented.

### (D) Binder Resin

The binder resin may include an acrylic binder resin.

The acrylic resin may be a copolymer of a first ethylenic unsaturated monomer and a second ethylenic unsaturated monomer that is copolymerizable therewith, and may be a resin including at least one acryl-based repeating unit.

The first ethylenic unsaturated monomer may be an ethylenic unsaturated monomer including at least one carboxyl group and in an implementation the monomer may include acrylic acid, methacrylic acid, maleic acid, itaconic acid, fumaric acid, or a combination thereof.

The first ethylenic unsaturated monomer may be included in an amount of about 5 wt % to about 50 wt %, e.g., about 10 wt % to about 40 wt % based on a total weight of the acrylic binder resin.

The second ethylenic unsaturated monomer may be an aromatic vinyl compound such as styrene, α-methylstyrene, vinyl toluene, vinylbenzylmethylether and the like; an unsaturated carboxylate ester compound such as methyl(meth)acrylate, ethyl(meth)acrylate, butyl(meth)acrylate, 2-hydroxyethyl(meth)acrylate, 2-hydroxy butyl(meth)acrylate, benzyl(meth)acrylate, cyclohexyl(meth)acrylate, phenyl(meth)acrylate, and the like; an unsaturated amino alkyl carboxylate ester compound such as 2-aminoethyl(meth)acrylate, 2-dimethylaminoethyl(meth)acrylate, and the like; a carboxylic acid vinyl ester compound such as vinyl acetate, vinyl benzoate, and the like; an unsaturated glycidyl carboxylate ester compound such as glycidyl(meth)acrylate, and the like; a vinyl cyanide compound such as (meth)acrylonitrile and the like; an unsaturated amide compound such as (meth)acrylamide, and the like; and the like, and may be used alone or as a mixture of two or more.

In an implementation, the acrylic resin may be a (meth)acrylic acid/benzylmethacrylate copolymer, a (meth)acrylic acid/benzylmethacrylate copolymer, a (meth)acrylic acid/benzylmethacrylate/styrene copolymer, a (meth)acrylic acid/benzylmethacrylate/2-hydroxyethylmethacrylate copolymer, a (meth)acrylic acid/benzylmethacrylate/styrene/2-hydroxyethylmethacrylate copolymer, and the like, and these may be used alone or as a mixture of two or more.

The binder resin may include an epoxy-based binder resin.

The binder resin may improve heat resistance by further including an epoxy-based binder resin. The epoxy-based binder resin may be, e.g., a phenol novolac epoxy resin, a tetramethyl biphenyl epoxy resin, a bisphenol A epoxy resin, a bisphenol F epoxy resin, an alicyclic epoxy resin, or a combination thereof.

Furthermore, the binder resin including the epoxy-based binder resin may secure dispersion stability of a colorant such as a pigment, which will be described later, and may help to form a pixel having a desired resolution during a developing process.

The epoxy-based binder resin may be included in an amount of about 1 wt % to about 10 wt %, e.g., about 5 wt % to about 10 wt % based on a total weight of the binder resin. If the epoxy-based binder resin is included in the above range, film residue ratio and chemical resistance may be greatly improved.

An epoxy equivalent weight of the epoxy-based resin may be about 150 g/eq to about 200 g/eq. If an epoxy-based binder resin having an epoxy equivalent within the above range is included in the binder resin, there may be an advantageous effect in improving a curing degree of the formed pattern and fixing the colorant in the structure in which the pattern is formed.

The binder resin may be dissolved in a solvent to be described later in a solid form to form a photosensitive resin composition. In this case, the binder resin in the solid form may be about 0.1 wt % to about 30 wt %, e.g., about 20 wt % to about 30 wt % based on a total weight of the binder resin solution dissolved in the solvent.

The binder resin may be included in an amount of about 0.1 wt % to about 20 wt %, in an implementation about 0.5 wt % to about 15 wt %, e.g., about 1 wt % to about 10 wt % based on a total solid content of the photosensitive resin composition. If the binder resin is included within the above range, it may be possible to obtain excellent surface smoothness due to excellent developability and improved crosslinking property during manufacture of the color filter.

### (E) Solvent

The solvent may be a material having compatibility with the colorant, the binder resin, the photopolymerizable compound, and the photopolymerization initiator but not reacting therewith.

In an implementation, the solvent may include alcohols such as methanol, ethanol, and the like; ethers such as dichloroethyl ether, n-butyl ether, diisoamyl ether, methylphenyl ether, tetrahydrofuran, and the like; glycol ethers such as ethylene glycol monomethylether, ethylene glycol monoethylether, and the like; cellosolve acetates such as methyl cellosolve acetate, ethyl cellosolve acetate, diethyl cellosolve acetate, and the like; carbitols such as methylethyl carbitol, diethyl carbitol, diethylene glycol monomethylether, diethylene glycol monoethylether, diethylene glycol dimethylether, diethylene glycol methylethylether, diethylene glycol diethylether, and the like; propylene glycol alkylether acetates such as propylene glycol monomethylether acetate, propylene glycol propylether acetate, and the like; aromatic hydrocarbons such as toluene, xylene and the like; ketones such as methylethylketone, cyclohexanone, 4-hydroxy-4-methyl-2-pentanone, methyl-n-propylketone, methyl-n-butylketone, methyl-n-amylketone, 2-heptanone, and the like; saturated aliphatic monocarboxylic acid alkyl esters such as ethyl acetate, n-butyl acetate, isobutyl acetate, and the like; lactate esters such as methyl lactate, ethyl lactate, and the like; oxy acetic acid alkyl esters such as oxy methyl acetate, oxy ethyl acetate, butyl oxyacetate, and the like; alkoxy acetic acid alkyl esters such as methoxy methyl acetate, methoxy ethyl acetate, methoxy butyl acetate, ethoxy methyl acetate, ethoxy ethyl acetate, and the like; 3-oxy propionic acid alkyl esters such as 3-oxy methyl propionate, 3-oxy ethyl propionate, and the like; 3-alkoxy propionic acid alkyl esters such as 3-methoxy methyl propionate, 3-methoxy ethyl propionate, 3-ethoxy ethyl propionate, 3-ethoxy methyl propionate, and the like; 2-oxy propionic acid alkyl esters such as 2-oxy methyl propionate, 2-oxy ethyl propionate, 2-oxy propyl propionate, and the like; 2-alkoxy propionic acid alkyl esters such as 2-methoxy methyl propionate, 2-methoxy ethyl propionate, 2-ethoxy ethyl propionate, 2-ethoxy methyl propionate, and the like; 2-oxy-2-methyl propionic acid esters such 2-oxy-2-methyl methyl propionate, 2-oxy-2-methyl ethyl propionate, and the like, monooxy monocarboxylic acid alkyl esters of 2-alkoxy-2-methyl alkyl propionates such as 2-methoxy-2-methyl methyl propionate, 2-ethoxy-2-methyl ethyl propionate, and the like; esters such as 2-hydroxy ethyl propionate, 2-hydroxy-2-methyl ethyl propionate, hydroxy ethyl acetate, 2-hydroxy-3-methyl methyl butanoate, and the like; ketonate esters such as ethyl pyruvate, and the like. Additionally, high boiling point solvent such as N-methylformamide, N,N-dimethylformamide, N-methylformanilide, N-methylacetamide, N,N-dimethylacetamide, N-methylpyrrolidone, dimethylsulfoxide, benzylethylether, dihexylether, acetylacetone, isophorone, caproic acid, caprylic acid, 1-octanol, 1-nonanol, benzylalcohol, benzyl acetate, ethyl benzoate, diethyl oxalate, diethyl maleate, γ-butyrolactone, ethylene carbonate, propylene carbonate, phenyl cellosolve acetate, and the like may be also used.

Among these, considering compatibility and reactivity, the solvents may include propylene glycol monomethyl ether acetate (PGMEA), n-butyl acetate (n-BA), and ethylene glycol dimethyl ether, or a combination thereof.

The solvent may be included in a balance amount, in an implementation, about 70 wt % to about 90 wt %, e.g., about 80 wt % to about 90 wt %, based on a total weight of the photosensitive resin composition. If the solvent is contained within the above range, the photosensitive resin composition may have excellent applicability and a coating film with excellent flatness may be obtained.

### (F) Other Additives

The photosensitive resin composition may further include an additive, e.g., malonic acid; 3-amino-1,2-propanediol; a coupling agent containing a vinyl group or a (meth)acryloxy group; and a radical polymerization initiator, in order to prevent stains or spots during the coating, to improve leveling performance, and to prevent the generation of undeveloped residues.

The additives may be easily adjusted according to desired physical properties.

The coupling agent may be a silane-based coupling agent, and in an implementation the silane-based coupling agent may include trimethoxysilyl benzoic acid, γ methacryl oxypropyl trimethoxysilane, vinyl triacetoxysilane, vinyl trimethoxysilane, γ isocyanate propyl triethoxysilane, γ glycidoxy propyl trimethoxysilane, β epoxycyclohexyl) ethyltrimethoxysilane, which can be used alone or in mixture of 2 or more types.

The silane-based coupling agent may be, in an implementation, used in an amount of 0.01 part by weight to 1 part by weight based on 100 parts by weight of the photosensitive resin composition.

In addition, the photosensitive resin composition for a color filter may further include a surfactant, e.g., a fluorine-based surfactant, if necessary.

In an implementation, the fluorine-based surfactant may include F-482, F-484, and F-478 of DIC Co., Ltd.

The surfactant may be desirably included in an amount of 0.01 wt % to 5 wt % and more desirably in an amount of 0.01 wt % to 2 wt % based on a total weight of the photosensitive resin composition. Within these ranges, generation of foreign substances after development may be reduced or prevented.

In addition, a certain amount of other additives such as an antioxidant, a stabilizer, and the like may be added to the photosensitive resin composition within a range that does not impair physical properties.

### (Photosensitive Resin Layer, Color Filter, and Display Device)

Some example embodiments provide a photosensitive resin layer manufactured using the photosensitive resin composition according to some example embodiments.

The photosensitive resin layer of some example embodiments may be largely divided into a color positive photoresist composition and a color negative photoresist composition.

The photosensitive resin layer of some example embodiments may be a color negative photoresist. This may have the advantage that coloring caused by the photoresist may not occur and that light sensitivity may be relatively higher than that of positive photoresist.

Some embodiments provide a color filter manufactured using the aforementioned photosensitive resin composition.

A method of manufacturing the color filter is as follows.

The aforementioned photosensitive resin composition may be coated to form a photosensitive resin composition layer with a thickness of 0.5 um to 10 um on a glass substrate in an appropriate method such as spin coating, roller coating, spray coating, and the like.

Subsequently, the substrate having the photosensitive resin composition layer may be radiated by light to form a pattern required for a color filter. The radiation may be performed by using UV, an electron beam or an X-ray as a light source, and the UV may be radiated, e.g., in a region of 190 nm to 450 nm and, e.g., 200 nm to 400 nm. The radiation may be performed by further using a photoresist mask. After performing the radiation process in this way, the photosensitive resin composition layer exposed to the light source may be treated with a developer. Herein, a non-exposed region in the photosensitive resin composition layer may be dissolved and may form the pattern for a color filter. This process may be repeated as many times as the number of desired colors, obtaining a color filter having a desired pattern. In addition, if the image pattern obtained through development in the above process is cured by reheating or radiating an actinic ray thereinto, crack resistance, solvent resistance, and the like may be improved.

According to some example embodiments, a display device including the aforementioned color filter may be provided.

The display device may be a liquid crystal display device, a CMOS image sensor, or the like.

The following Examples and Comparative Examples are provided in order to highlight characteristics of one or more embodiments, but it will be understood that the Examples and Comparative Examples are not to be construed as limiting the scope of the embodiments, nor are the Comparative Examples to be construed as being outside the scope of the embodiments. Further, it will be understood that the embodiments are not limited to the particular details described in the Examples and Comparative Examples.

### Synthesis Example 1: Compound Represented by Chemical Formula 3-1-1A

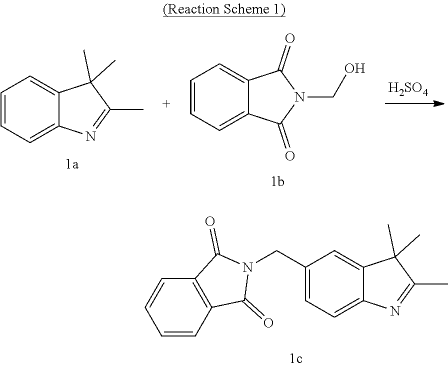

To a mixture of 20.0 g of the above compound 1a and 20.2 g of the above compound 1b, 110 mL of sulfuric acid was added and then, stirred at ambient temperature for 72 hours. After cooling in an ice bath, a 10% NaOH (aq) solution was slowly added thereto to produce precipitates. The precipitates were vacuum-filtered to obtain a solid, and the solid was washed with distilled water. The corresponding solid was recrystallized with n-hexane and dried in a 40° C. vacuum oven overnight to obtain 34 g of the above compound 1c.

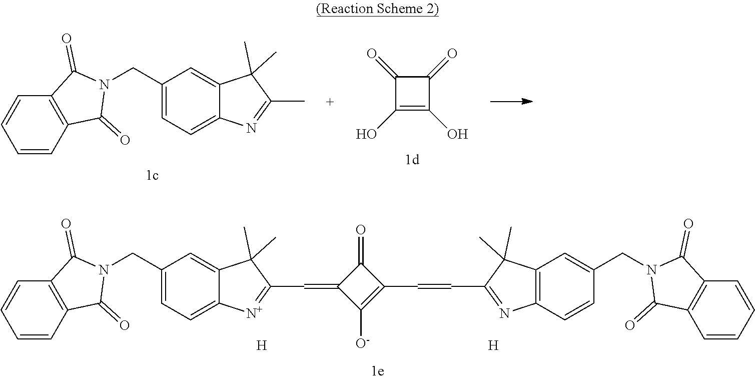

5.00 g of the above compound 1c and 895 mg of the above compound 1d were dissolved in a mixed solution of n-butanol/toluene (1/1) at ambient temperature and then, heated to 120° C. for a reaction overnight. After removing the solvent under a reduced pressure, n-hexane was added to the residual reaction mixture and then, stirred at 0° C. for 15 minutes. 2.24 g of the above compound 1e was obtained through column chromatography (eluent: DCM-EtOAc) after obtaining a solid therefrom through filtration under the reduced pressure.

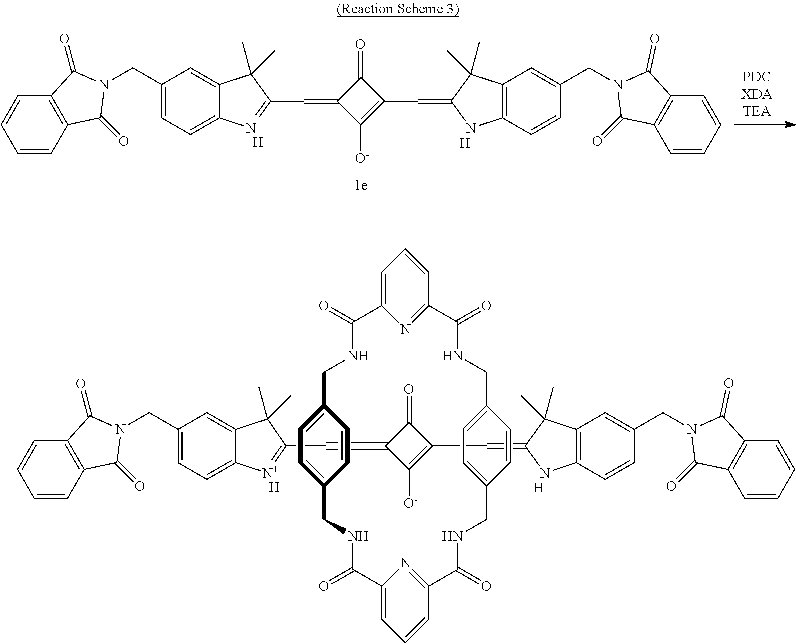

After dissolving 1.1 g of the compound 1e in chloroform and cooling the solution to 0° C., two types of solutions were prepared: (i) one solution prepared by dissolving 0.80 g of p-xylxylenediamine (XDA) and 1.2 g of triethylamine in chloroform and (ii) the other solution prepared by dissolving 1.2 g of pyridine-2,6-dicarbonyl dichloride (PDC) in chloroform. These two solutions in the order of (i) and (ii) were slowly added to the solution of the compound 1e and then, stirred at ambient temperature for 2 hours. After removing the solvent under the reduced pressure condition, the residue was redissolved in ethyl acetate to precipitate polymer by-products. After removing the by-products through filtration under the reduced pressure, the solvent was removed under the reduced pressure condition. After redissolving a product obtained therefrom in chloroform, the above step was repeated two more times. Subsequently, 0.17 g of a material corresponding to Chemical Formula 3-1-1A was obtained by purification through column chromatography (eluent: DCM-EtOAc).

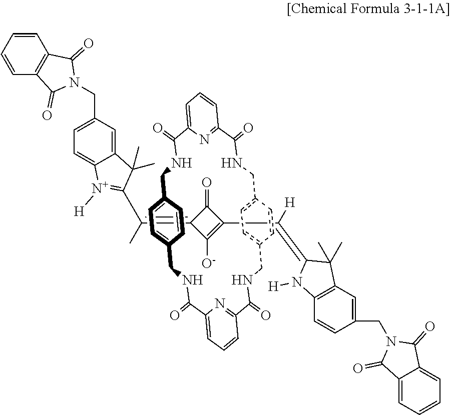

The material of Chemical Formula 3-1-1A exhibited the following MALDI-TOF analysis result.

m/z calcd for C₇₄H₆₁N₁₀O₁₀, 1249.45; found, 1249.45.

### Synthesis Example 2: Compound Represented by Chemical Formula 3-1-1B

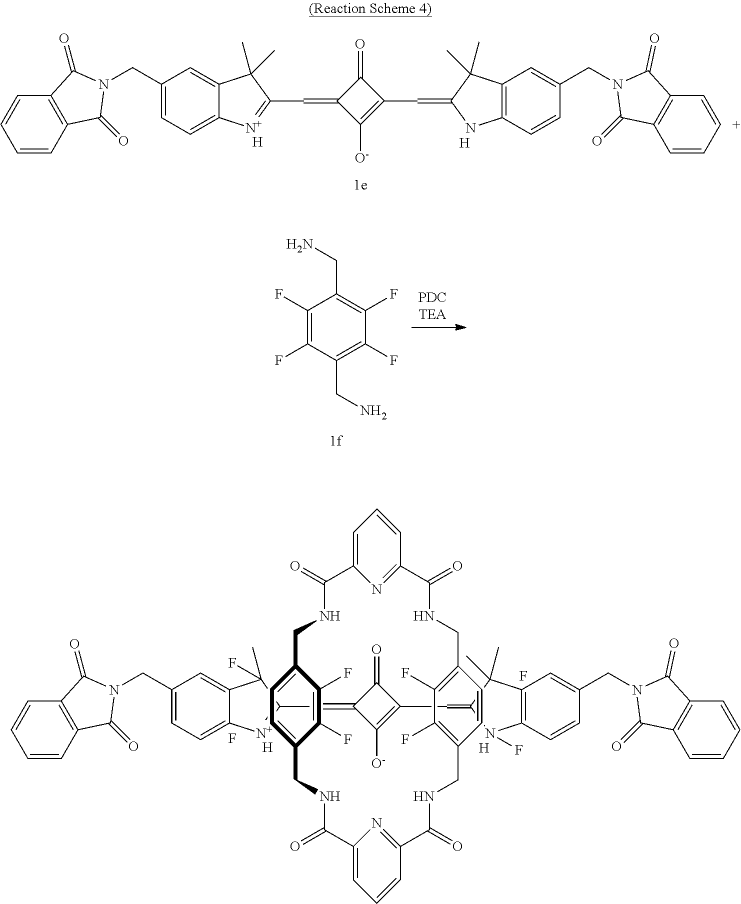

Chemical Formula 3-1-1B was obtained in a similar synthesis manner as Chemical Formula 3-1-1A except that the above compound 1f was used instead of the XDA.

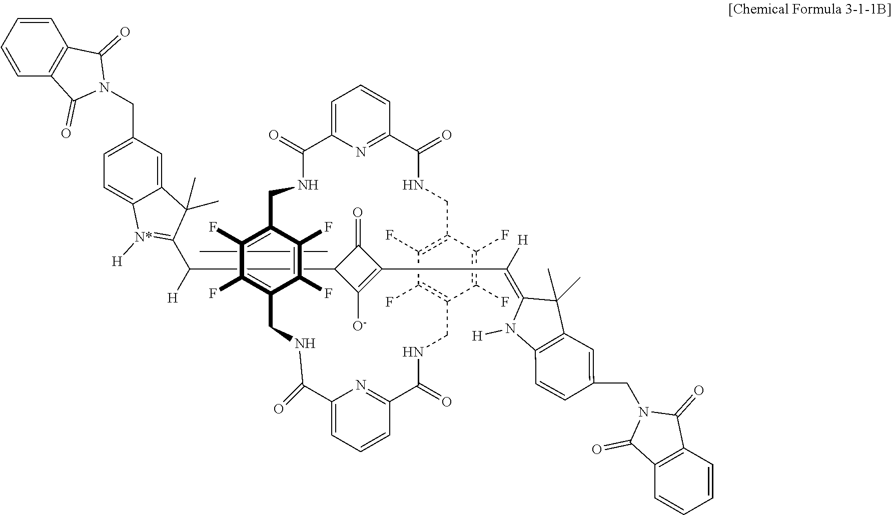

Chemical Formula 3-1-1B exhibited the following MALDI-TOF analysis result.

m/z calcd for C₇₄H₅₃F₈N₁₀O₁₀, 1393.38; found, 1393.38.

### Synthesis Example 3: Compound Represented by Chemical Formula 3-1-1C

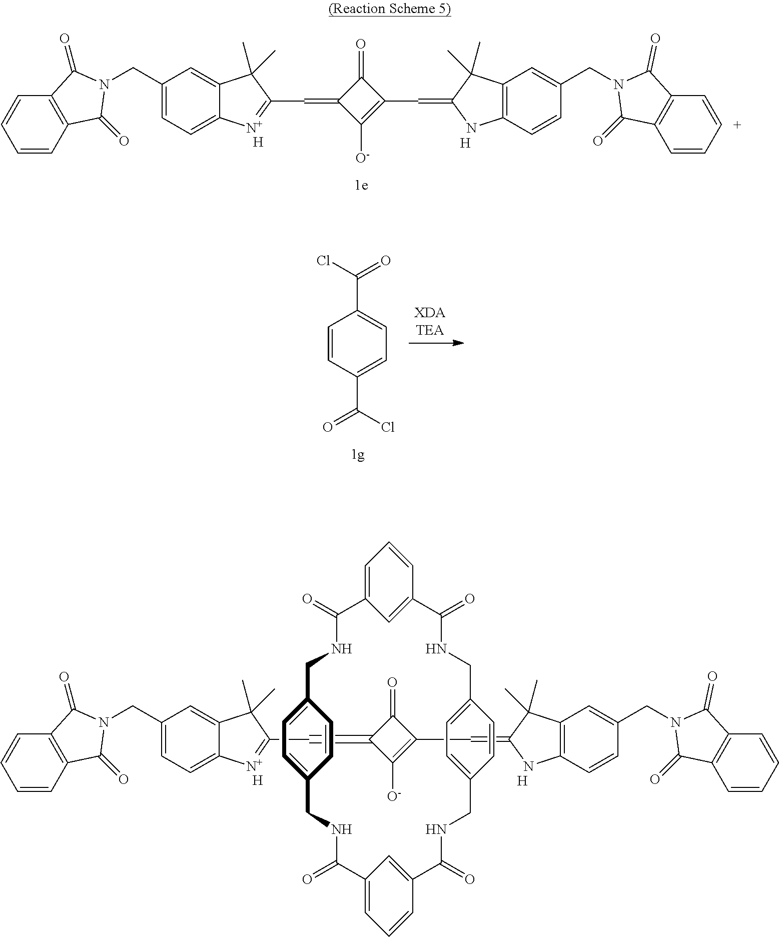

Chemical Formula 3-1-1C was obtained in a similar synthesis manner as Chemical Formula 3-1-1A except that the above compound 1g was used instead of the PDC.

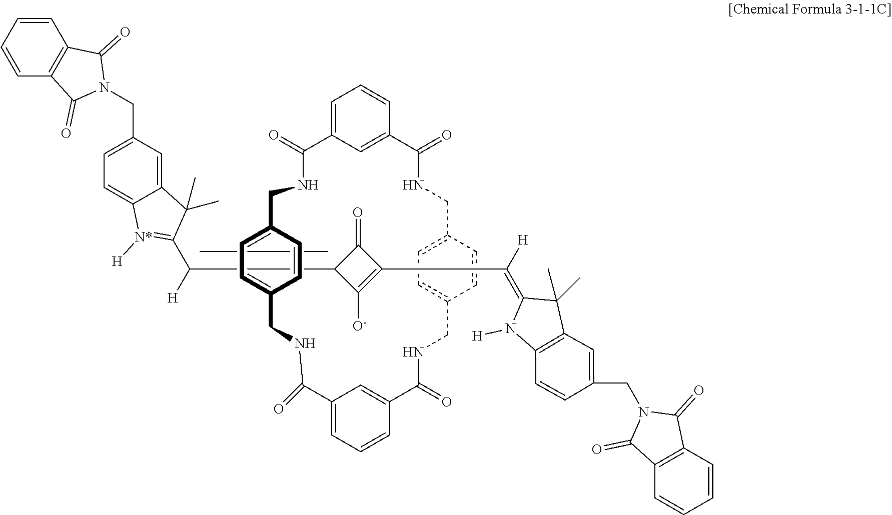

Chemical Formula 3-1-1C exhibited the following MALDI-TOF analysis result.

m/z calcd for C₇₆H₆₃N₈O₁₀, 1247.46; found, 1247.46.

### Synthesis Example 4: Compound Represented by Chemical Formula 3-1-1D

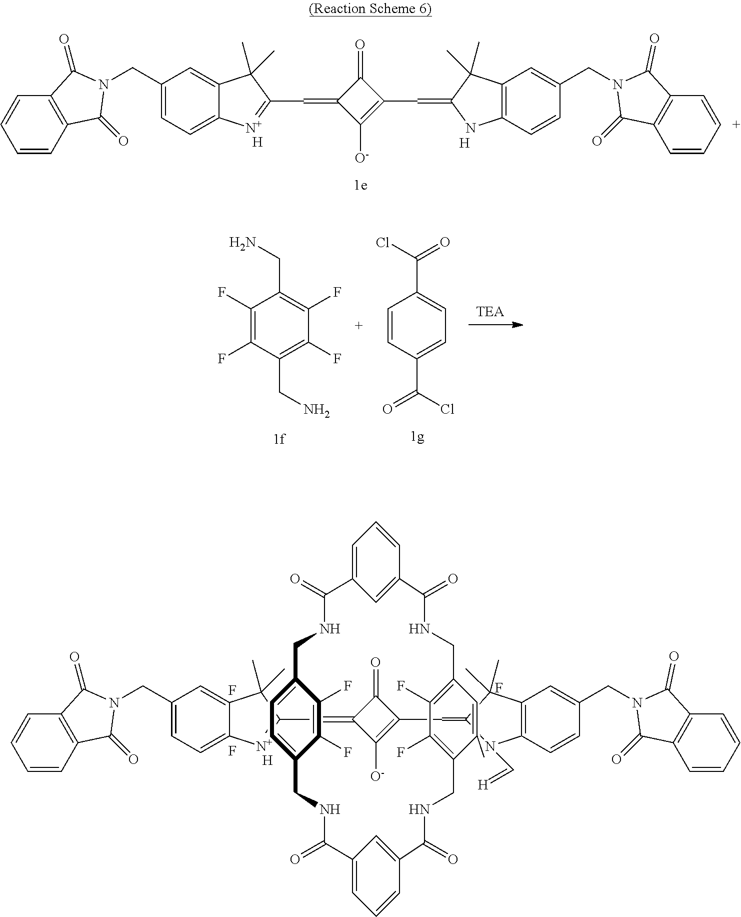

Chemical Formula 3-1-1D was obtained in a similar synthesis manner as Chemical Formula 3-1-1A except that the above compound 1g instead of the PDC and the above compound 1f instead of XDA were used.

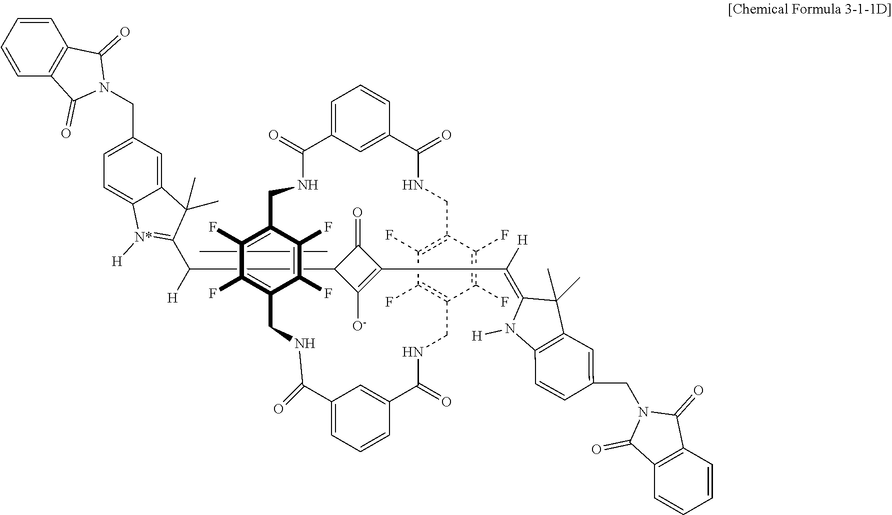

Chemical Formula 3-1-1D exhibited the following MALDI-TOF analysis result.

m/z calcd for C₇₆H₅₅F₈N₈O₁₀, 1391.39; found, 1391.39.

### Synthesis Example 5: Compound Represented by Chemical Formula 3-1-1E

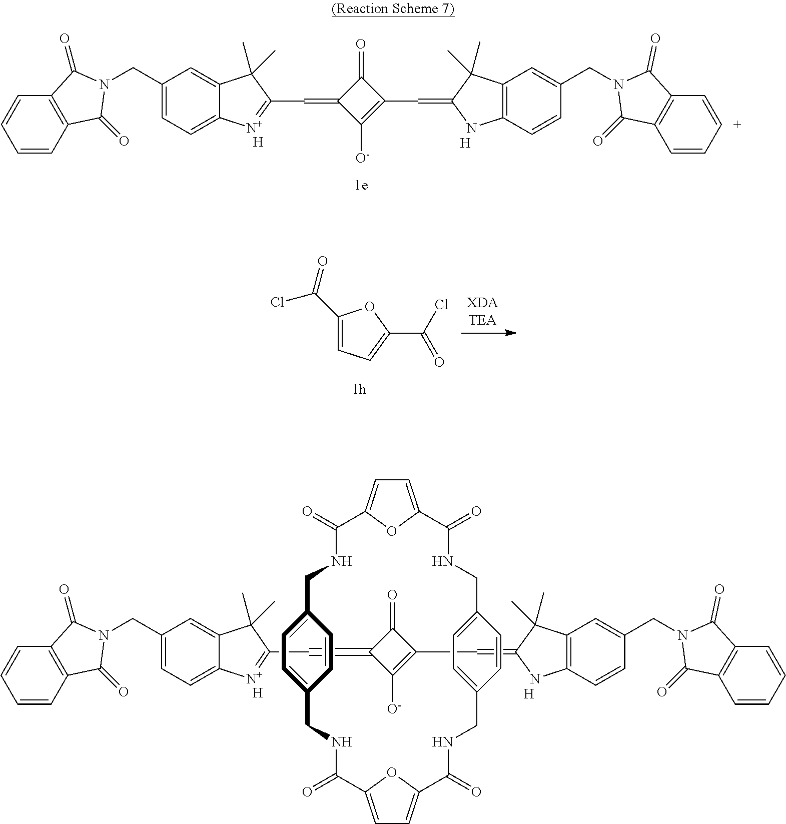

Chemical Formula 3-1-1E was obtained in a similar synthesis manner as Chemical Formula 3-1-1A except that the above compound 1h instead of the PDC and the above compound 1f instead of XDA were used.

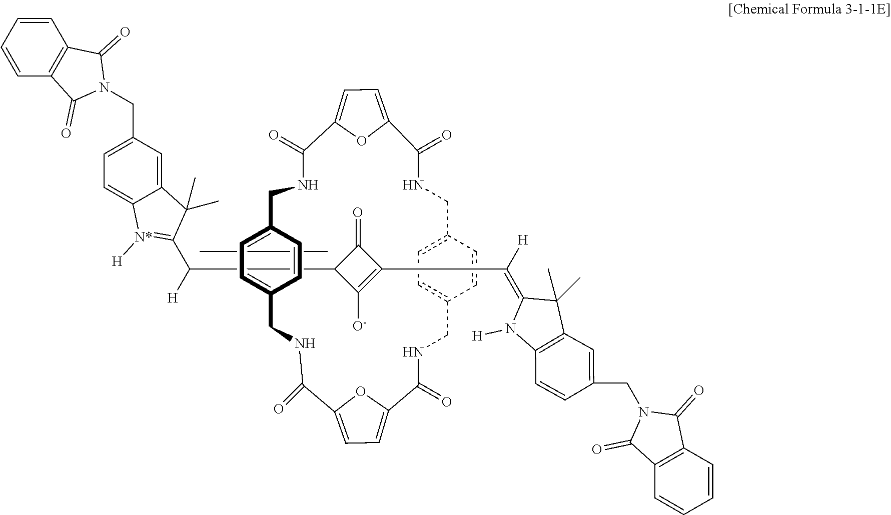

Chemical Formula 3-1-1E exhibited the following MALDI-TOF analysis result.

m/z calcd for C₇₂H₅₉N₈O₁₂, 1227.42; found, 1227.42.

### Synthesis Example 6: Compound Represented by Chemical Formula 3-1-1F

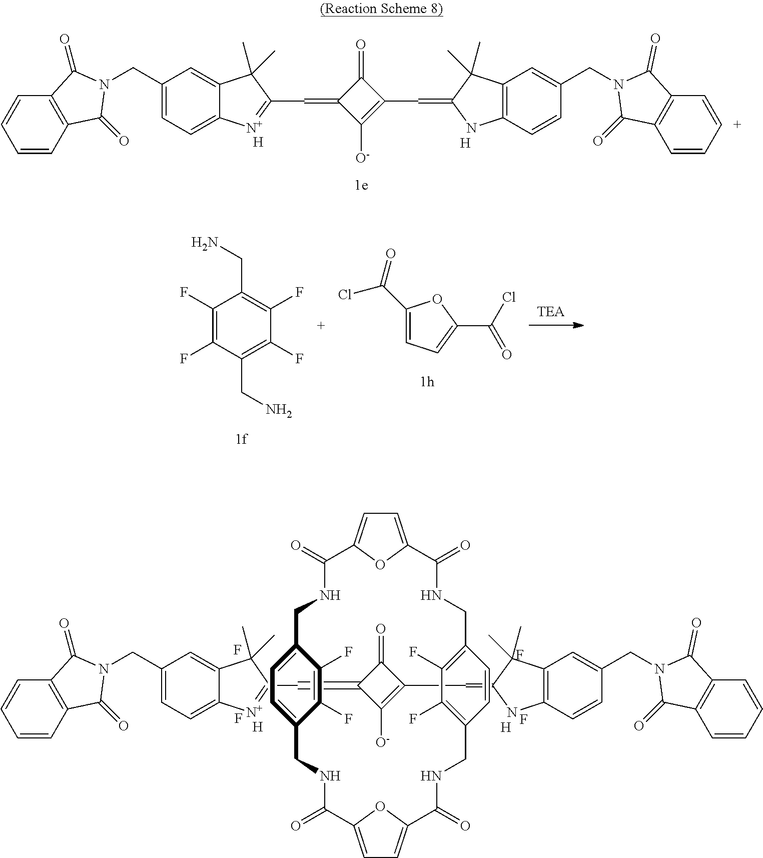

Chemical Formula 3-1-1F was obtained in a similar synthesis manner as Chemical Formula 3-1-1A except that the above compound 1f instead of XDA and the above compound 1h instead of the PDC were used.

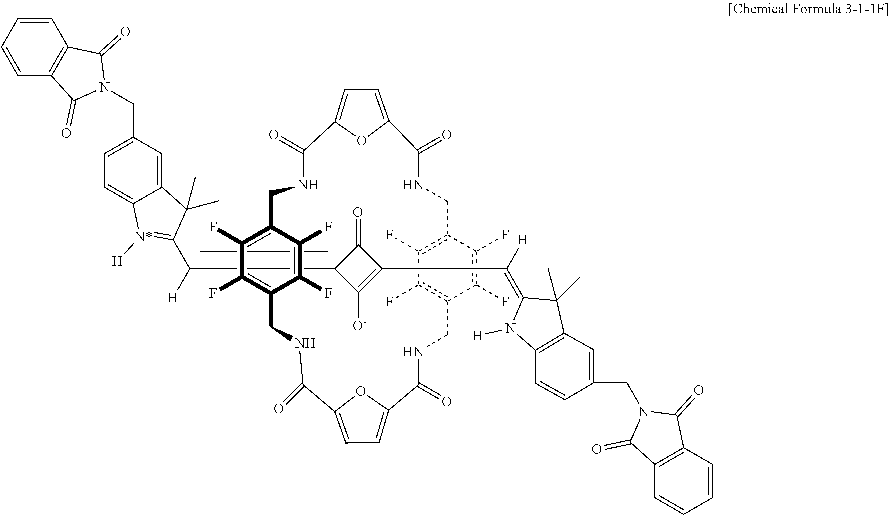

Chemical Formula 3-1-1F exhibited the following MALDI-TOF analysis result.

m/z calcd for C₇₂H₅₁F₈N₈O₁₂, 1371.35; found, 1371.35.

### Synthesis Example 7: Compound Represented by Chemical Formula 3-2-1A

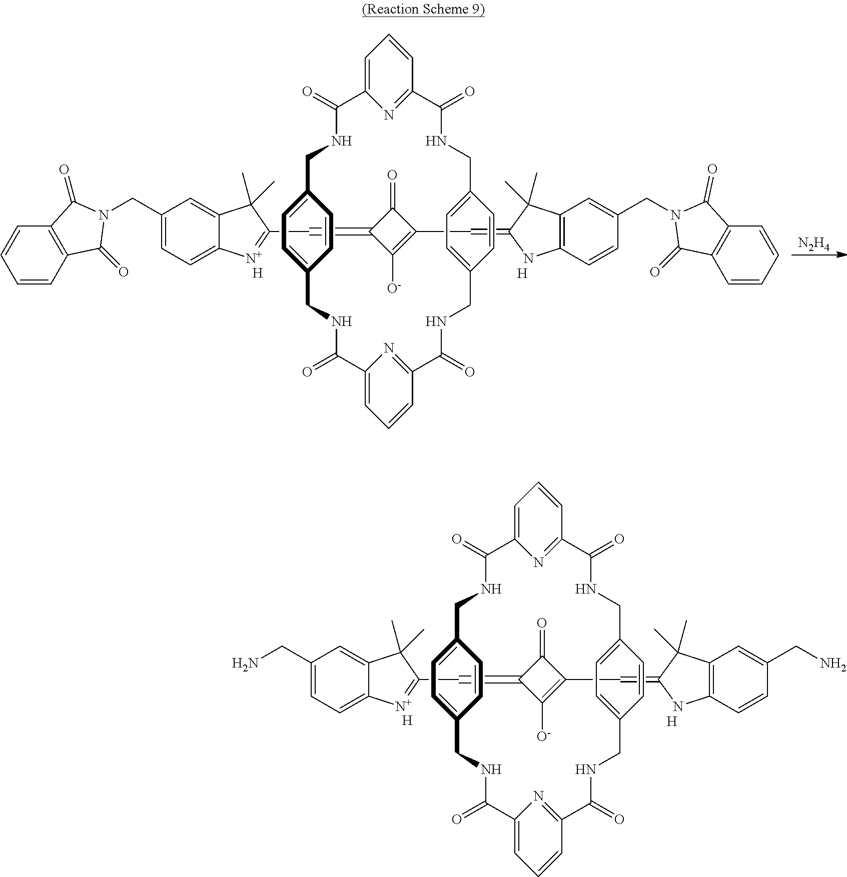

2.00 g of Chemical Formula 3-1-1A and 801 mg of hydrazine hydrate were added to 10 mL of ethanol and then, stirred at ambient temperature for 1 hour. Precipitates produced therein were removed through filtration under a reduced pressure. A filtrate therefrom was concentrated under the reduced pressure condition to obtain 1.50 g of Chemical Formula 3-2-1A.

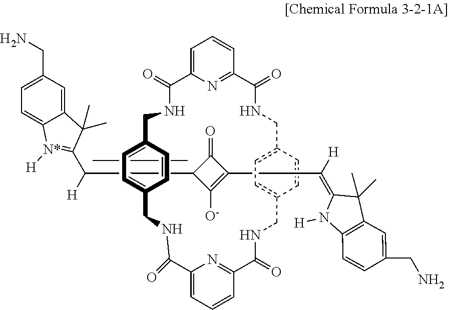

Chemical Formula 3-2-1A exhibited the following MALDI-TOF analysis result.

m/z calcd for C₅₈H₅₇N₁₀O₆, 989.45; found, 989.44.

### Synthesis Example 8: Compound Represented by Chemical Formula 3-3-1A

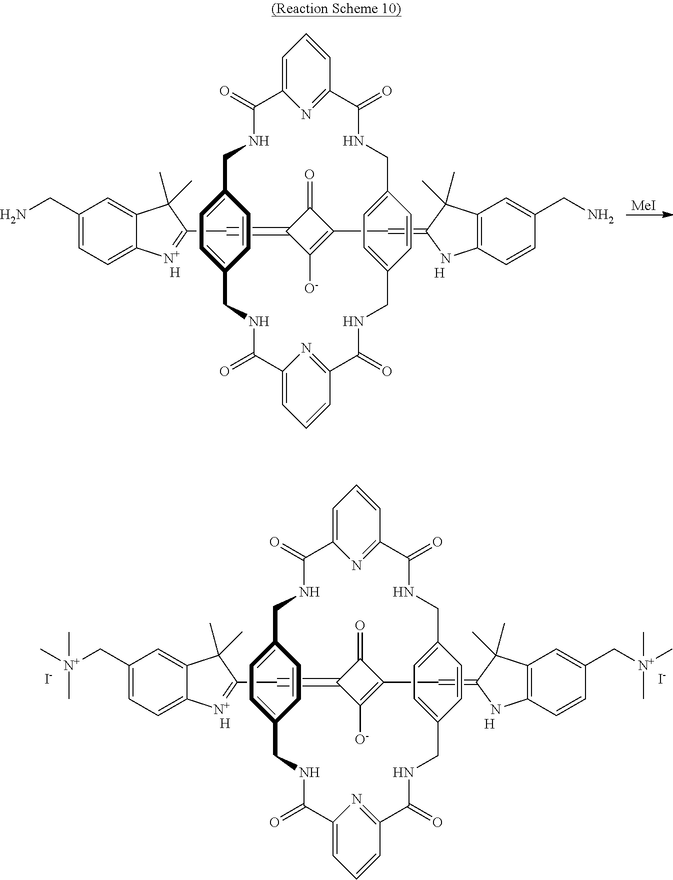

2.00 g of Chemical Formula 3-2-1A was added to a solution prepared by dissolving 1.26 mL of methyl iodide in 10 mL of ethanol and then, heated to 40° C. for a reaction overnight. All volatile components were removed therefrom under the reduced pressure condition to obtain 2.42 g of Chemical Formula 3-3-1A.

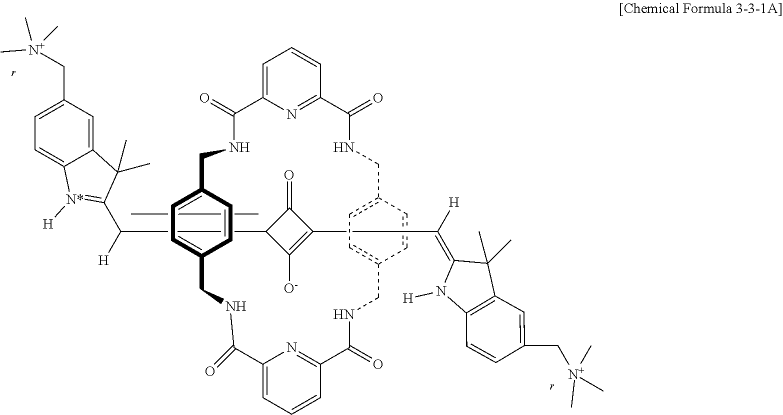

Chemical Formula 3-3-1A exhibited the following MALDI-TOF analysis result.

m/z calcd for C₆₄H₇₀N₁₀O₆, 1074.55; found, 1074.55.

### Synthesis Example 9: Compound Represented by Chemical Formula 3-4-1A

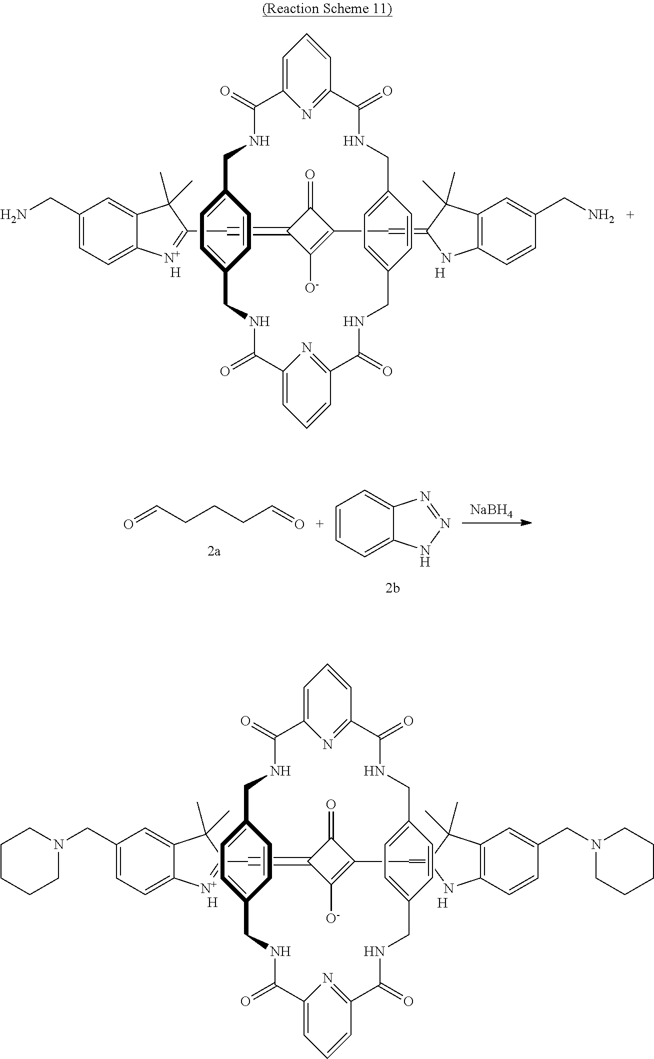

After dissolving Chemical Formula 3-2-1A and the above compound 2b in ethanol, the above compound 2a was slowly added thereto. After stirring at ambient temperature for 2 hours, a solid produced therein was filtered under the reduced pressure and washed with distilled water. The solid was redissolved in THF and then, added to sodium borohydrite (NaBH₄) and then, stirred at ambient temperature overnight. Subsequently, distilled water was added thereto to stop the reaction and then, extracted with dichloromethane. An organic layer therefrom was passed through MgSO₄, dried, and concentrated to obtain Chemical Formula 3-4-1A.

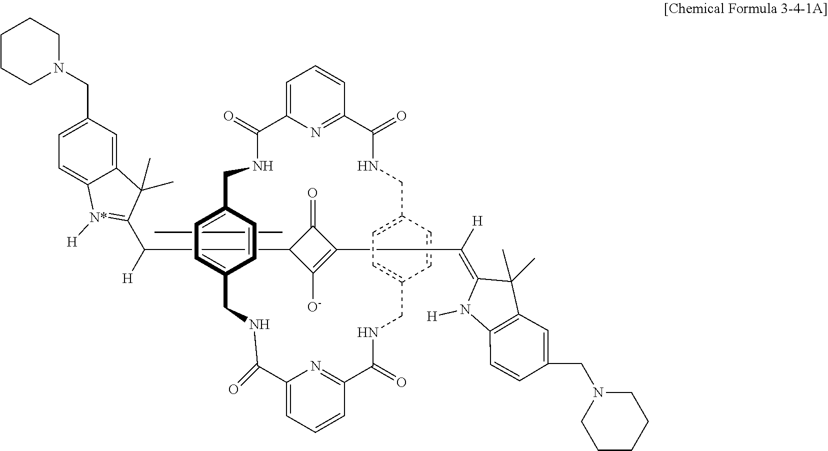

Chemical Formula 3-4-1A exhibited the following MALDI-TOF analysis result.

m/z calcd for C₆₈H₇₃N₁₀O₆, 1125.57; found, 1125.57.

### Synthesis Example 10: Compound Represented by Chemical Formula 3-5-1A

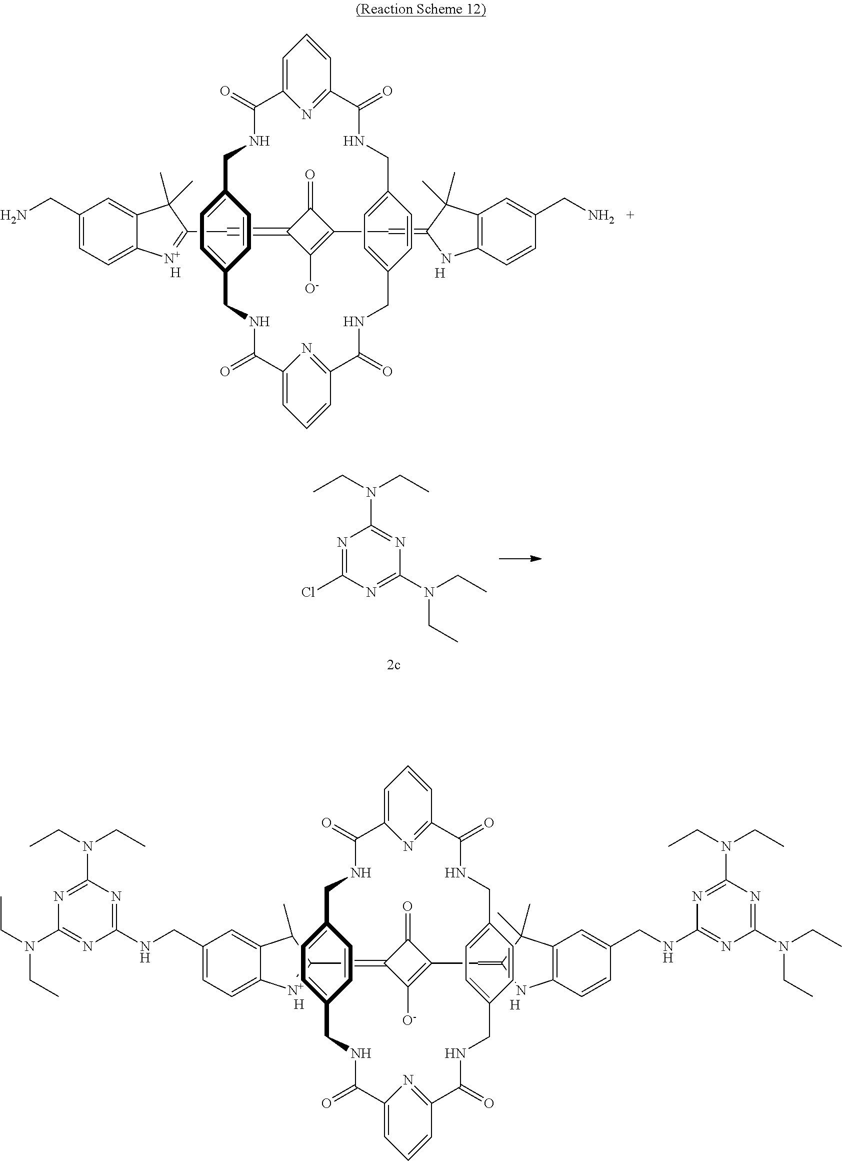

2.00 g of Chemical Formula 3-2-1A and 5.21 g of the above compound 2c were dissolved in N-methyl pyrrolidone, and 7.04 mL of diisopropylethylamine (DIPEA) was added thereto. The obtained mixture was heated to 120° C. and then, proceeded with a reaction overnight. The reaction mixture was cooled to ambient temperature, and diethylether was added thereto to produce a solid, and the solid was separated by filtration under the reduced pressure. The solid was washed with diethylether and dried in a 40° C. vacuum oven overnight to obtain 1.97 g of Chemical Formula 3-5-1A.

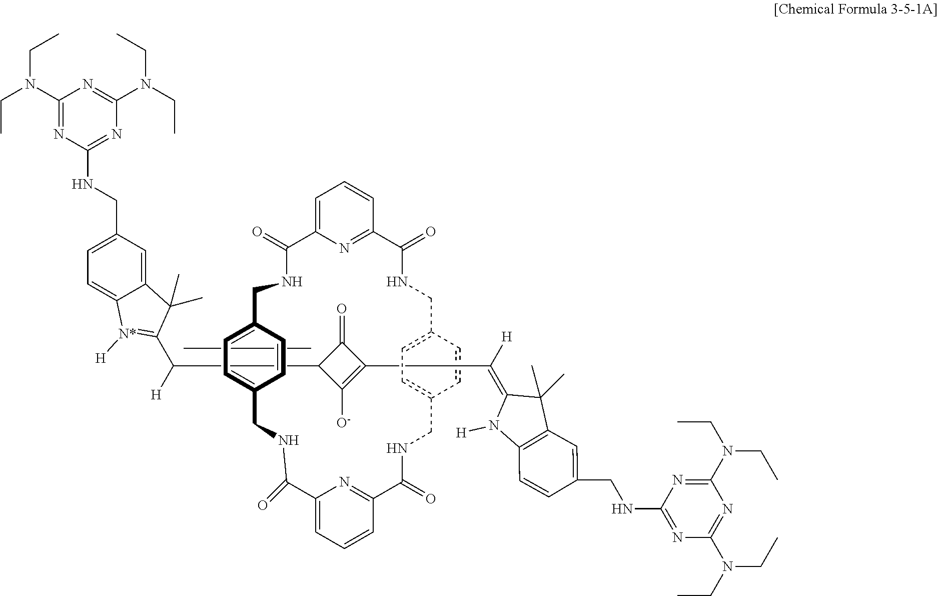

Chemical Formula 3-5-1A exhibited the following MALDI-TOF analysis result.

m/z calcd for C₈₀H₉₅N₂₀O₆, 1431.77; found, 1431.77.

### Synthesis Example 11: Compound Represented by Chemical Formula 3-6-1A

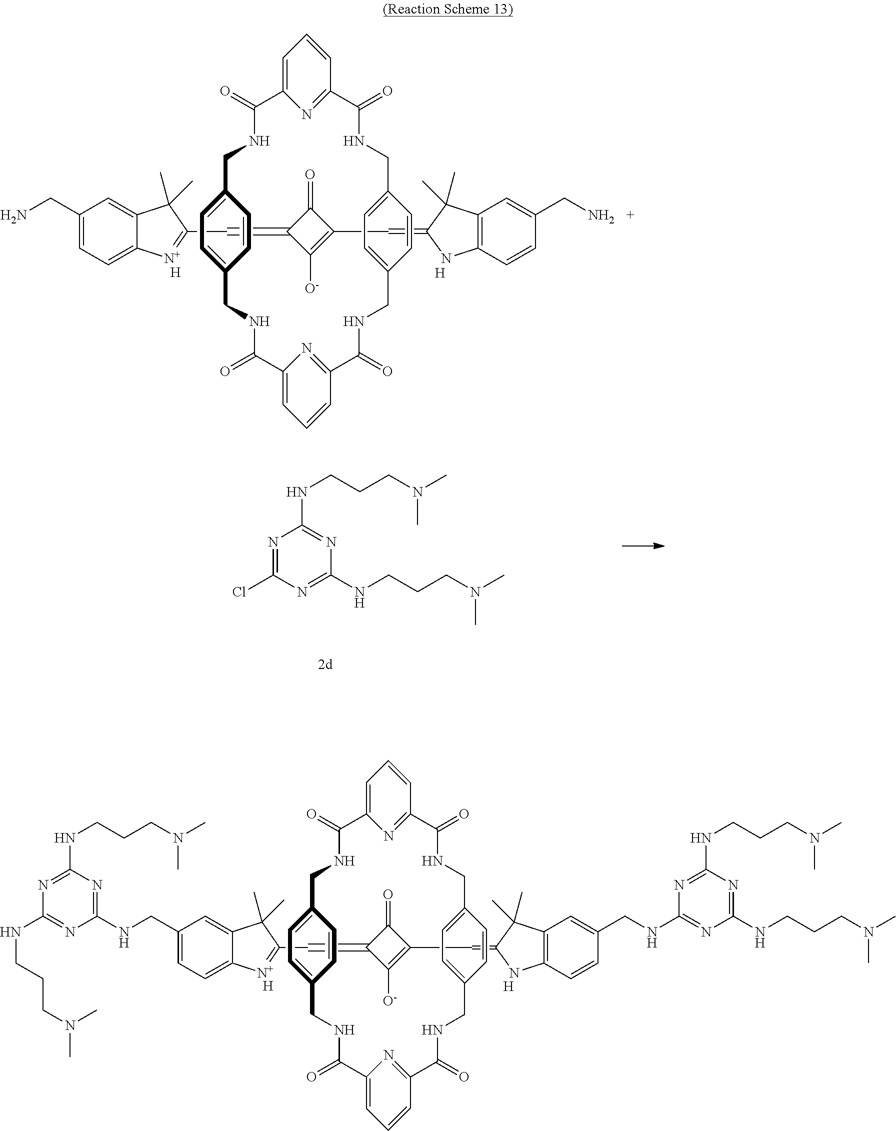

Chemical Formula 3-6-1A was obtained in a similar synthesis manner as Chemical Formula 3-5-1A.

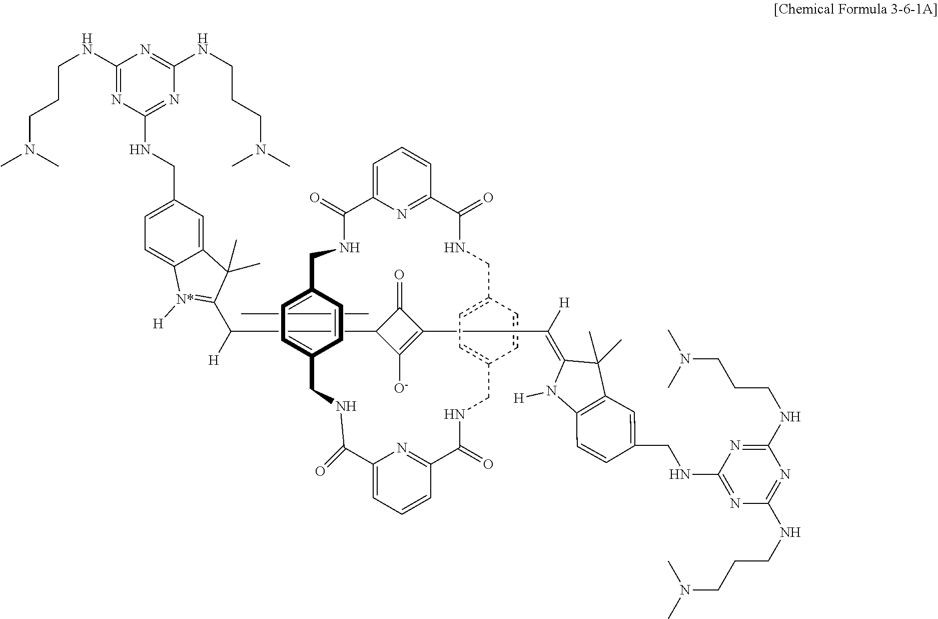

Chemical Formula 3-6-1A exhibited the following MALDI-TOF analysis result.

m/z calcd for C₈₄H₁₀₇N₂₄O₆, 1547.88; found, 1547.88.

### Comparative Synthesis Example 1: Compound Represented by Chemical Formula X

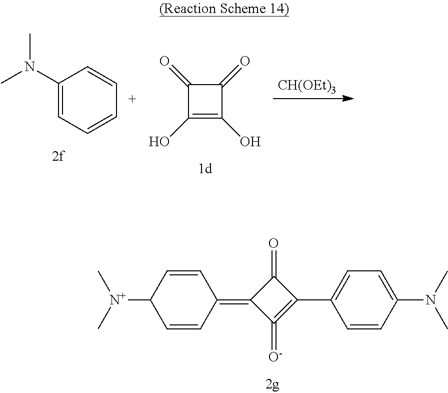

2.93 g of the above compound 2f and 12.1 mL of triethyl orthofomate were dissolved in n-amyl alcohol, and 1.93 g of the above compound 1d was added thereto at ambient temperature. The corresponding solution was stirred at 90° C. for 4 hours, and a reaction progress was checked through TLC. After completely removing the solvent under the reduced pressure condition, the residue was dispersed in n-hexane. The reaction mixture was cooled at 0° C. for 15 minutes to precipitate solid products. The precipitates were separated from the mixture through vacuum filtration and washed with n-hexane. 5.64 g of the above compound 2g obtained therefrom was used in the following reaction step without additional purification.

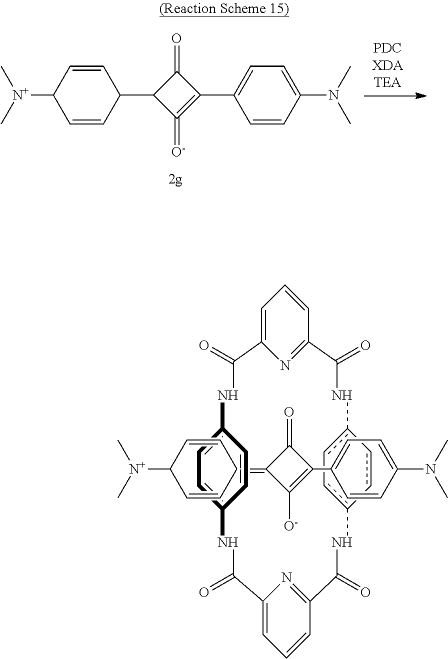

Chemical Formula X was obtained in a similar manner as Chemical Formula 3-1-1A.

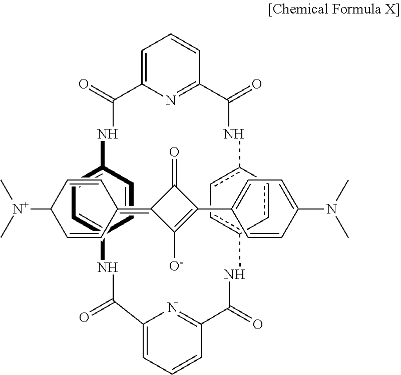

Chemical Formula X exhibited the following MALDI-TOF analysis result.

m/z calcd for C₅₀H₄₇N₈O₆, 855.36; found, 855.36.

### Comparative Synthesis Example 2: Compound Represented by Chemical Formula Y

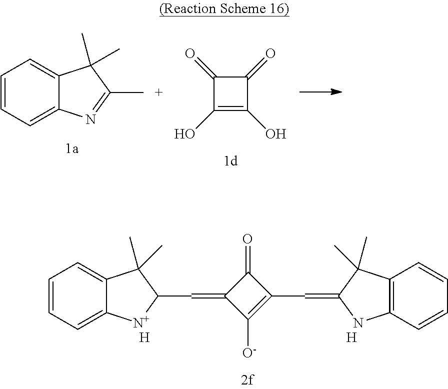

The compound 2f was obtained in a similar synthesis manner as the compound 1e.

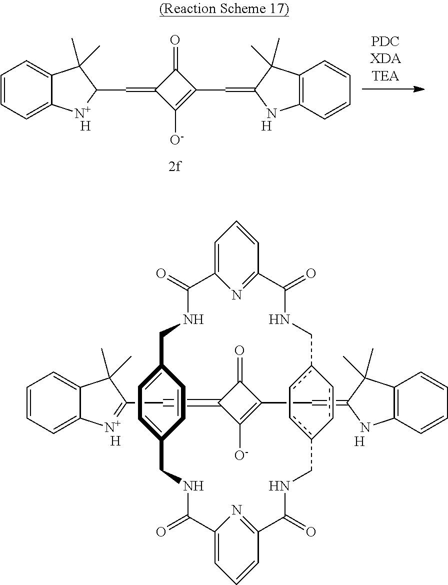

Chemical Formula Y was obtained in a similar synthesis manner as Chemical Formula 3-1-1A.

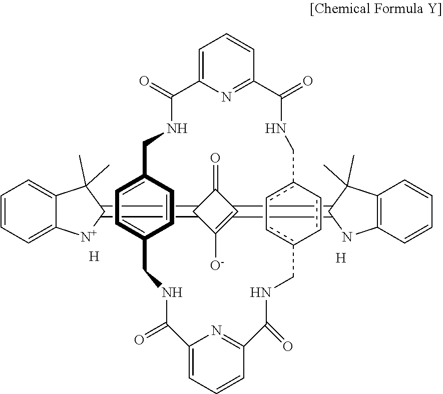

Chemical Formula Y exhibited the following MALDI-TOF analysis result.

m/z calcd for C₅₆H₅₁N₈O₆, 931.39; found, 931.39.

### Preparation of Green Pigment Dispersion

Each green pigment dispersion of Preparation Examples 1 to 16 and Preparation Comparative Examples 1 to 3 was prepared to have a composition shown in Tables 1 to 4.

The green pigment dispersion was obtained by mixing a green pigment, a dispersant, a dispersion aid, and a solvent and pouring 300 parts by weight of zirconia beads (diameter: 0.4 μm) based 100 parts by weight of the mixture thereinto, dispersing them by shaking with a paint shaker for 3 hours, and removing the zirconia beads through filtration.

TABLE 1
(unit: wt %)

| | | Preparation | Preparation | Preparation | Preparation | Preparation | Preparation |
|---|---|---|---|---|---|---|---|
| | | Example 1 | Example 2 | Example 3 | Example 4 | Example 5 | Example 6 |
| Green pigment | | 12.0 | 12.0 | 12.0 | 12.0 | 12.0 | 12.0 |
| Dispersant | | 2.5 | 2.5 | 2.5 | 2.5 | 2.5 | 2.5 |
| Dispersion | Synthesis | 0.5 | — | — | — | — | — |
| aid | Example 1 | | | | | | |
| | Synthesis | — | 0.5 | — | — | — | — |
| | Example 2 | | | | | | |
| | Synthesis | — | — | 0.5 | — | — | — |
| | Example 3 | | | | | | |
| | Synthesis | — | — | — | 0.5 | — | — |
| | Example 4 | | | | | | |
| | Synthesis | — | — | — | — | 0.5 | — |
| | Example 5 | | | | | | |
| | Synthesis | — | — | — | — | — | 0.5 |
| | Example 6 | | | | | | |

| | | | | | | |
|---|---|---|---|---|---|---|
| Solvent | 85.0 | 85.0 | 85.0 | 85.0 | 85.0 | 85.0 |

TABLE 2
(unit: wt %)

| | | Preparation | Preparation | Preparation | Preparation | Preparation |
|---|---|---|---|---|---|---|
| | | Example 7 | Example 8 | Example 9 | Example 10 | Example 11 |
| Green pigment | | 12.0 | 12.0 | 12.0 | 12.0 | 12.0 |
| Dispersant | | 2.5 | 2.5 | 2.5 | 2.5 | 2.5 |
| Dispersion | Synthesis | 0.5 | — | — | — | — |
| aid | Example 7 | | | | | |
| | Synthesis | — | 0.5 | — | — | — |
| | Example 8 | | | | | |
| | Synthesis | — | — | 0.5 | — | — |
| | Example 9 | | | | | |
| | Synthesis | — | — | — | 0.5 | — |
| | Example 10 | | | | | |
| | Synthesis | — | — | — | — | 0.5 |
| | Example 11 | | | | | |

| | | | | | |
|---|---|---|---|---|---|
| Solvent | 85.0 | 85.0 | 85.0 | 85.0 | 85.0 |

TABLE 3

| | | | | Preparation | | |
|---|---|---|---|---|---|---|
| | | | | Example 14 | | |
| | | Preparation | Preparation | (=Preparation | Preparation | Preparation |
| | | Example 12 | Example 13 | Example 1) | Example 15 | Example 16 |
| Green pigment | | 12.0 | 12.0 | 12.0 | 12.0 | 12.0 |
| Dispersant | | 2.5 | 2.5 | 2.5 | 2.5 | 2.5 |
| Dispersion | Synthesis | 0.3 | 0.4 | 0.5 | 0.6 | 1.0 |
| aid | Example 1 | | | | | |

| | | | | | |
|---|---|---|---|---|---|
| Solvent | 85.2 | 85.1 | 85.0 | 84.9 | 84.5 |

TABLE 4
(unit: wt %)

| | | Comparative | Comparative | Comparative |
|---|---|---|---|---|
| | | Preparation | Preparation | Preparation |
| | | Example 1 | Example 2 | Example 3 |
| Green pigment | | 12.0 | 12.0 | 12.0 |
| Dispersant | | 2.5 | 2.5 | 2.5 |
| Dispersion | Comparative | — | 0.5 | — |
| aid | Synthesis | | | |
| | Example 1 | | | |
| | Comparative | — | — | 0.5 |
| | Synthesis | | | |
| | Example 2 | | | |

| | | | |
|---|---|---|---|
| Solvent (PGMEA) | 85.5 | 85.0 | 85.0 |

The materials used in Tables 1 to 3 are as follows.
Green pigment: C.I. PIGMENT Green 58 G58
Dispersant: BYK-LPN6919 (Manufacturer: BYK)
Dispersing aid: each compound of Synthesis Examples 1 to 11 and Comparative Synthesis Examples 1 and 2
Solvent: propylene glycol monomethylether acetate (PGMEA)
Preparation Example 17: Preparation of Yellow Pigment Dispersion
Yellow pigment dispersion was obtained by mixing 12.0 parts by weight of a yellow pigment (C.I. PIGMENT Yellow 138), 3.0 parts by weight of a dispersant (BYK-LPN6919, Manufacturer: BYK), and 85.0 parts by weight of a solvent (propylene glycol monomethylether acetate, PGMEA), pouring 300 parts by weight of zirconia beads (diameter: 0.4 μm) based on 100 parts by weight of this mixture thereinto, dispersing them by shaking with a paint shaker for 3 hours, and removing the zirconia beads through filtration.

### Preparation of Photosensitive Resin Composition

The photosensitive resin compositions of Examples 1 to 16 and Comparative Examples 1 to 3 were prepared by mixing the compositions shown in Tables 5 to 8.

Specifically, each photosensitive colored resin composition was prepared by mixing the green pigment dispersion, the yellow pigment dispersion, the photopolymerizable monomer, the photopolymerization initiator, the binder resin, and the solvent.

TABLE 5

| | | | Example 1 | Example 2 | Example 3 | Example 4 | Example 5 | Example 6 |
|---|---|---|---|---|---|---|---|---|
| (A) | Green | Preparation | 20.0 | — | — | — | — | — |
| Colorant | pigment | Example 1 | | | | | | |
| | dispersion | Preparation | — | 20.0 | — | — | — | — |
| | | Example 2 | | | | | | |
| | | Preparation | — | — | 20.0 | — | — | — |
| | | Example 3 | | | | | | |
| | | Preparation | — | — | — | 20.0 | — | — |
| | | Example 4 | | | | | | |
| | | Preparation | — | — | — | — | 20.0 | — |
| | | Example 5 | | | | | | |
| | | Preparation | — | — | — | — | — | 20.0 |
| | | Example 6 | | | | | | |

| | | | | | | |
|---|---|---|---|---|---|---|
| Yellow pigment dispersion | 15.0 | 15.0 | 15.0 | 15.0 | 15.0 | 15.0 |

| (B) | DPHA | 5.0 | 5.0 | 5.0 | 5.0 | 5.0 | 5.0 |
|---|---|---|---|---|---|---|---|
| Photopolymerizable | | | | | | | |
| monomer | | | | | | | |
| (C) | C-1 | 1.0 | 1.0 | 1.0 | 1.0 | 1.0 | 1.0 |
| Photopolymerization | C-2 | 0.5 | 0.5 | 0.5 | 0.5 | 0.5 | 0.5 |
| initiator | | | | | | | |
| (D) Binder resin | | 3.5 | 3.5 | 3.5 | 3.5 | 3.5 | |
| (E) Solvent | PGMEA | 56.0 | 56.0 | 56.0 | 56.0 | 56.0 | 56.0 |

TABLE 6

| | | | Example 7 | Example 8 | Example 9 | Example 10 | Example 11 |
|---|---|---|---|---|---|---|---|
| (A) | Green | Preparation | 20.0 | — | — | — | — |
| Colorant | pigment | Example 7 | | | | | |
| | dispersion | Preparation | — | 20.0 | — | — | — |
| | | Example 8 | | | | | |
| | | Preparation | — | — | 20.0 | — | — |
| | | Example 9 | | | | | |
| | | Preparation | — | — | — | 20.0 | — |
| | | Example 10 | | | | | |
| | | Preparation | — | — | — | — | 20.0 |
| | | Example 11 | | | | | |

| | | | | | |
|---|---|---|---|---|---|
| Yellow pigment dispersion | 15.0 | 15.0 | 15.0 | 15.0 | 15.0 |

| (B) | DPHA | 5.0 | 5.0 | 5.0 | 5.0 | 5.0 |
|---|---|---|---|---|---|---|
| Photopolymerizable | | | | | | |
| monomer | | | | | | |
| (C) | C-1 | 1.0 | 1.0 | 1.0 | 1.0 | 1.0 |
| Photopolymerization | C-2 | 0.5 | 0.5 | 0.5 | 0.5 | 0.5 |
| initiator | | | | | | |
| (D) Binder resin | | 3.5 | 3.5 | 3.5 | 3.5 | 3.5 |
| (E) Solvent | PGMEA | 56.0 | 56.0 | 56.0 | 56.0 | 56.0 |

TABLE 7

| | | | Example 12 | Example 13 | Example 14 | Example 15 | Example 16 |
|---|---|---|---|---|---|---|---|
| (A) | Green | Preparation | 20.0 | — | — | — | — |
| Colorant | pigment | Example 12 | | | | | |
| | dispersion | Preparation | — | 20.0 | — | — | — |
| | | Example 13 | | | | | |
| | | Preparation | — | — | 20.0 | — | — |
| | | Example 14 | | | | | |
| | | Preparation | — | — | — | 20.0 | — |
| | | Example 15 | | | | | |
| | | Preparation | — | — | — | — | 20.0 |
| | | Example 16 | | | | | |

| | | | | | |
|---|---|---|---|---|---|
| Yellow pigment dispersion | 15.0 | 15.0 | 15.0 | 15.0 | 15.0 |

| (B) | DPHA | 5.0 | 5.0 | 5.0 | 5.0 | 5.0 |
|---|---|---|---|---|---|---|
| Photopolymerizable | | | | | | |
| monomer | | | | | | |
| (C) | C-1 | 1.0 | 1.0 | 1.0 | 1.0 | 1.0 |
| Photopolymerization | C-2 | 0.5 | 0.5 | 0.5 | 0.5 | 0.5 |
| initiator | | | | | | |
| (D) Binder resin | | 3.5 | 3.5 | 3.5 | 3.5 | 3.5 |
| (E) Solvent | PGMEA | 56.0 | 56.0 | 56.0 | 56.0 | 56.0 |

TABLE 8

| | | | Comparative | Comparative | Comparative |
|---|---|---|---|---|---|
| | | | Example 1 | Example 2 | Example 3 |
| (A) | Green | Comparative Preparation | 20.0 | — | — |
| Colorant | pigment | Example 1 | | | |
| | dispersion | Comparative Preparation | — | 20.0 | — |
| | | Example 2 | | | |
| | | Comparative Preparation | — | — | 20.0 |
| | | Example 3 | | | |

| | | | |
|---|---|---|---|
| Yellow pigment dispersion | 15.0 | 15.0 | 15.0 |

| (B) | DPHA | 5.0 | 5.0 | 5.0 |
|---|---|---|---|---|
| Photopolymerizable | | | | |
| monomer | | | | |
| (C) | C-1 | 1.0 | 1.0 | 1.0 |
| Photopolymerization | C-2 | 0.5 | 0.5 | 0.5 |
| initiator | | | | |
| (D) Binder resin | | 3.5 | 3.5 | 3.5 |
| (E) Solvent | PGMEA | 56.0 | 56.0 | 56.0 |

The materials used in Tables 5 to 8 are as follows.

### (A) Colorant

Green pigment dispersion: Each green pigment dispersion of Preparation Examples 1 to 16 and Comparative Preparation Examples 1 to 3
Yellow pigment dispersion: Yellow pigment dispersion of Preparation Example 17

### (B) Photopolymerizable Monomer

Dipentaerythritolhexaacrylate (DPHA, manufacturer: Nippon Kayaku Co., Ltd.)
   (C) Photopolymerization initiator
(C-1) 1,2-octanedione
(C-2) 2-dimethylamino-2-(4-methyl-benzyl)-1-(4-morpholin-4-yl-phenyl)-butan-1-one
   (D) Binder resin
Resin copolymerized with benzyl methacrylate and methacrylic acid at 85:15 (Mw=22,000)

### (E) Solvent

Propylene glycol monomethylether acetate (PGMEA)

### Evaluation Example 1 Dispersibility and Dispersion Stability

Each photosensitive resin composition of Examples 1 to 16 and Comparative Examples 1 to 3 was measured with respect to a solid particle diameter by using a dynamic light scattering) analyzer, and the results are shown in Table 9.

In addition, each photosensitive resin composition of Examples 1 to 16 and Comparative Examples 1 to 3 was measured with respect to viscosity before and after stored at 23° C. for 1 week at 5 rpm (rpm where Torque value became 50% to 100%) by using Brookfield DV-II Pro viscometer and CPE-52 Spindle at 25° C., and the results are shown in Table 9.

TABLE 9

| | Solid particle diameter (nm) | | | Viscosity (cPs) | | |
|---|---|---|---|---|---|---|
| | After | After | | After | After | |
| | preparation | 1 week | Difference | preparation | 1 week | Difference |
| Example 1 | 45 | 46 | 1 | 4.55 | 4.47 | 0.08 |
| Example 2 | 44 | 44 | 0 | 4.42 | 4.55 | 0.13 |
| Example 3 | 45 | 46 | 1 | 4.64 | 4.58 | 0.06 |
| Example 4 | 44 | 44 | 0 | 5.11 | 5.04 | 0.07 |
| Example 5 | 43 | 44 | 1 | 4.44 | 4.58 | 0.14 |
| Example 6 | 42 | 44 | 2 | 4.64 | 4.77 | 0.13 |
| Example 7 | 46 | 45 | 0 | 4.15 | 4.32 | 0.17 |
| Example 8 | 47 | 48 | 1 | 4.55 | 4.71 | 0.16 |
| Example 9 | 45 | 46 | 1 | 4.45 | 4.68 | 0.23 |
| Example 10 | 44 | 44 | 0 | 4.27 | 4.42 | 0.15 |
| Example 11 | 46 | 46 | 0 | 4.37 | 4.55 | 0.18 |
| Example 12 | 44 | 44 | 0 | 4.87 | 4.91 | 0.04 |
| Example 13 | 45 | 45 | 0 | 4.11 | 4.18 | 0.07 |
| Example 14 | 45 | 46 | 1 | 4.55 | 4.47 | 0.08 |
| (=Example 1) | | | | | | |
| Example 15 | 48 | 49 | 1 | 4.24 | 4.24 | 0.00 |
| Example 16 | 45 | 44 | 1 | 5.04 | 5.08 | 0.04 |
| Comparative | 51 | 64 | 13 | 5.11 | 5.88 | 0.78 |
| Example 1 | | | | | | |
| Comparative | 50 | 55 | 5 | 4.48 | 6.02 | 1.54 |
| Example 2 | | | | | | |
| Comparative | 47 | 51 | 4 | 4.94 | 6.11 | 1.17 |
| Example 3 | | | | | | |

*In Table 9, when the solid particle diameter and the viscosity had a change within 10%, it was judged to be “satisfactory.”

Referring to Table 9, the photosensitive resin compositions of Examples 1 to 16, compared with the photosensitive resin compositions of Comparative Examples 1 to 3, exhibited small differences in the viscosity as well as in the solid particle diameter before and after stored for one week.

### Evaluation Example 2: Coloring Power and Luminance

Each photosensitive resin composition of Examples 1 to 16 and Comparative Examples 1 to 3 was coated to be 0.6 μm thick on a 1 mm-thick glass substrate, which was degreased and washed, and then, dried on a hot plate at 90° C. for 2 minutes to obtain a film. The film was exposed to light by using a high-pressure mercury lamp having a main wavelength of 365 nm and then, dried in a 200° C. forced convection drying furnace for 5 minutes to obtain a color filter specimen.

In order to evaluate it as a pixel layer, the color filter specimen was measured with respect to a color coordinate (x, y), luminance (Y), and a thickness by using a spectrophotometer (MCPD3000, Otsuka Electronics Co., Ltd.), and the results are shown in Table 10.

TABLE 10

| | x | y | Y | THICK (μm) |
|---|---|---|---|---|
| Example 1 | 0.348 | 0.573 | 72.9 | 6,121 |
| Example 2 | 0.348 | 0.572 | 73.0 | 6,088 |
| Example 3 | 0.350 | 0.564 | 75.0 | 6,014 |
| Example 4 | 0.348 | 0.573 | 73.0 | 6,012 |
| Example 5 | 0.348 | 0.572 | 72.8 | 5,999 |
| Example 6 | 0.348 | 0.572 | 72.6 | 6,018 |
| Example 7 | 0.348 | 0.571. | 72.9 | 6,104 |
| Example 8 | 0.348 | 0.571 | 73.0 | 6,111 |
| Example 9 | 0.348 | 0.572 | 73.2 | 6,001 |
| Example 10 | 0.348 | 0.574 | 73.0 | 6,074 |
| Example 11 | 0.348 | 0.575 | 72.8 | 6,104 |
| Example 12 | 0.348 | 0.576 | 72.8 | 6,111 |
| Example 13 | 0.348 | 0.574 | 73.0 | 6,004 |
| Example 14 (=Example 1) | 0.348 | 0.573 | 72.9 | 6,121 |
| Example 15 | 0.348 | 0.574 | 72.9 | 6,110 |
| Example 16 | 0.348 | 0.574 | 73.2 | 6,018 |
| Comparative Example 1 | 0.351 | 0.558 | 72.4 | 6,649 |
| Comparative Example 2 | 0.352 | 0.556 | 72.1 | 6,717 |
| Comparative Example 3 | 0.352 | 0.554 | 71.4 | 6,627 |

* In Table 10, the higher y & Y and the thinner, the more excellent characteristics.

Referring to Table 10, the color filter specimens of Examples 1 to 16, compared with the color filter specimens of Comparative Examples 1 to 3, exhibited improved coloring power and luminance.

In summary, when the dispersion aid represented by Chemical Formula 1 was used, a photosensitive resin composition exhibiting excellent coloring power and luminance, even though a color filter was thinned, as well as having high dispersibility and dispersion stability of pigments was realized.

By way of summation and review, the liquid crystal display device may include a lower substrate on which a black matrix, a color filter, and an ITO pixel electrode may be formed, and an upper substrate on which an active circuit portion including a liquid crystal layer, a thin film transistor, and a capacitor layer and an ITO pixel electrode may be formed.

Color filters may be formed in a pixel region by sequentially stacking a plurality of color filters (in general, formed of three primary colors such as red (R), green (G), and blue (B)) in a predetermined order to form each pixel, and a black matrix layer may be disposed in a predetermined pattern on a transparent substrate to form a boundary between the pixels.

The pigment dispersion method that is one of methods of forming a color filter may provide a colored thin film by repeating a series of processes such as coating a photopolymerizable composition including a colorant on a transparent substrate including a black matrix, exposing a formed pattern to light, removing a non-exposed part with a solvent, and thermally curing the same.

The photosensitive resin composition (pigment-type photosensitive resin composition) used to manufacture a color filter according to the pigment dispersion method may generally consist of an alkali-soluble resin, a photopolymerizable monomer, a photopolymerization initiator, an epoxy resin, a solvent, and other additives. The pigment dispersion method having the above characteristics is actively used to manufacture LCDs for mobile phones, laptops, monitors, TVs, or the like.

However, even in color filters manufactured using a pigment dispersion method, not only excellent pattern characteristics but also luminance characteristics along with high color reproduction may be required.

Some example embodiments provide a photosensitive resin composition that has high dispersibility and dispersion stability and has excellent coloring power and luminance even when the color filter is thinned.

Some example embodiments provide a photosensitive resin layer manufactured using the photosensitive resin composition.

Some example embodiments provide a color filter including the photosensitive resin layer.

The photosensitive resin composition according to some example embodiments may have high dispersibility and dispersion stability, and may provide excellent coloring power and luminance even when the color filter is thinned. In an implementation, excellent color filters and display devices may be implemented by using the photosensitive resin composition according to some example embodiments.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A photosensitive resin composition, comprising:
a colorant;
a photopolymerizable compound;
a photopolymerization initiator;
a binder resin; and
a solvent,
wherein:
the colorant includes a pigment, a dispersant, and a dispersion aid represented by Chemical Formula 1, 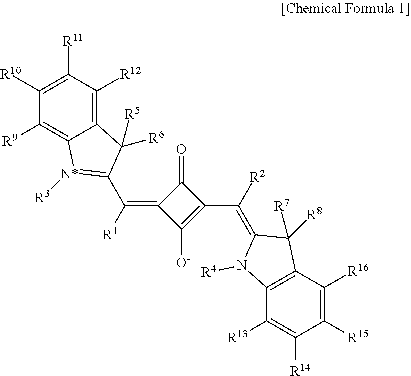
in Chemical Formula 1,
R¹ to R⁸ are each independently a hydrogen atom or a substituted or unsubstituted C1 to C20 alkyl group, and
R⁹ to R¹⁶ are each independently a hydrogen atom, a substituted or unsubstituted C1 to C20 alkyl group, or a substituted or unsubstituted basic functional group, provided that at least one of R⁹ to R¹⁶ is a basic functional group.

2. The photosensitive resin composition as claimed in claim 1, wherein both R¹ and R² are hydrogen atoms.

3. The photosensitive resin composition as claimed in claim 1, wherein both R³ and R⁴ are hydrogen atoms.

4. The photosensitive resin composition as claimed in claim 1, wherein R⁵ to R⁸ are a substituted or unsubstituted methyl group.

5. The photosensitive resin composition as claimed in claim 1, wherein one of R⁹ to R¹², and one of R¹³ and R¹⁶ are each independently a substituted or unsubstituted basic functional group.

6. The photosensitive resin composition as claimed in claim 5, wherein:
the dispersion aid is represented by Chemical Formula 1-1, and 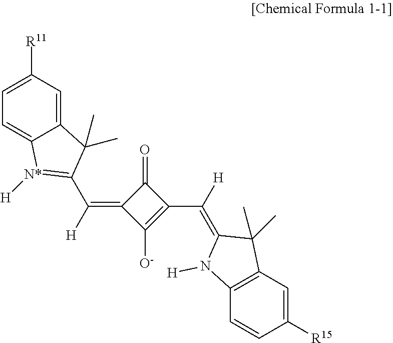
R¹¹ and R¹⁵ are each independently a substituted or unsubstituted basic functional group.

7. The photosensitive resin composition as claimed in claim 6, wherein the substituted or unsubstituted basic functional group is a secondary anime group, a tertiary amine group, or a quaternary amine group.

8. The photosensitive resin composition as claimed in claim 7, wherein the substituted or unsubstituted basic functional group is represented by one of the following Chemical Formulae A to E: 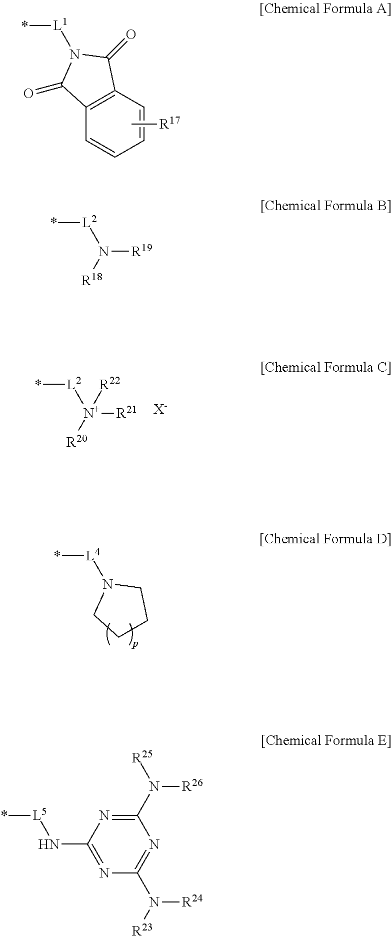
in Chemical Formulae A to E,
L¹ to L⁵ are each independently a single bond or a substituted or unsubstituted C1 to C20 alkylene group,
R¹⁷ to R²⁶ are each independently a hydrogen atom, a substituted or unsubstituted C1 to C20 alkyl group, or *-L⁶-N(R²⁷)(R²⁸),
L⁶ is a single bond or a substituted or unsubstituted C1 to C20 alkylene group,
R²⁷ and R²⁸ are each independently a hydrogen atom or a substituted or unsubstituted C1 to C20 alkyl group,
X is a halogen element, and
p is an integer from 0 to 5.

9. The photosensitive resin composition as claimed in claim 8, wherein the dispersion aid is represented by one of the following chemical formulae:

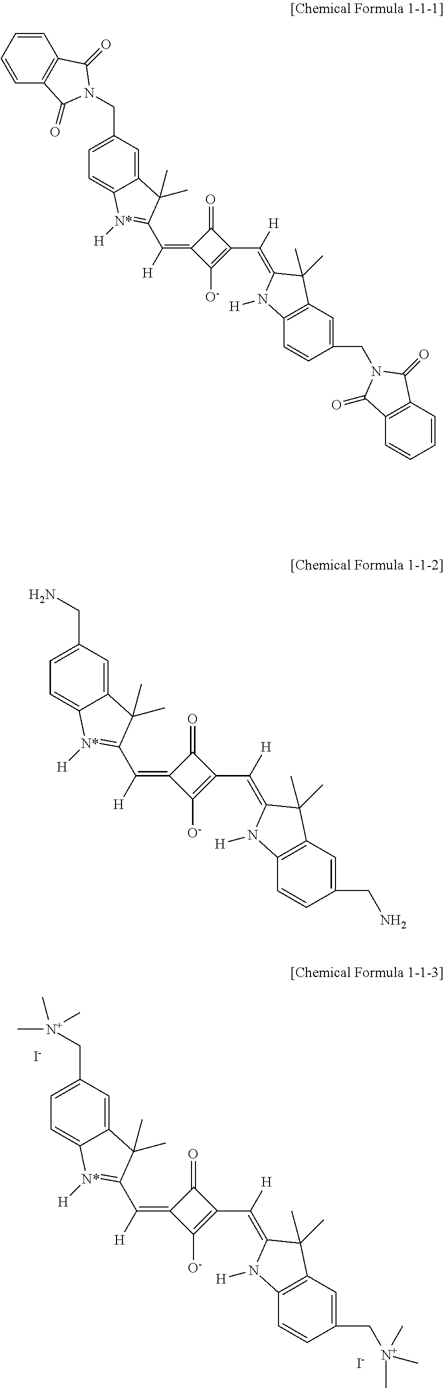

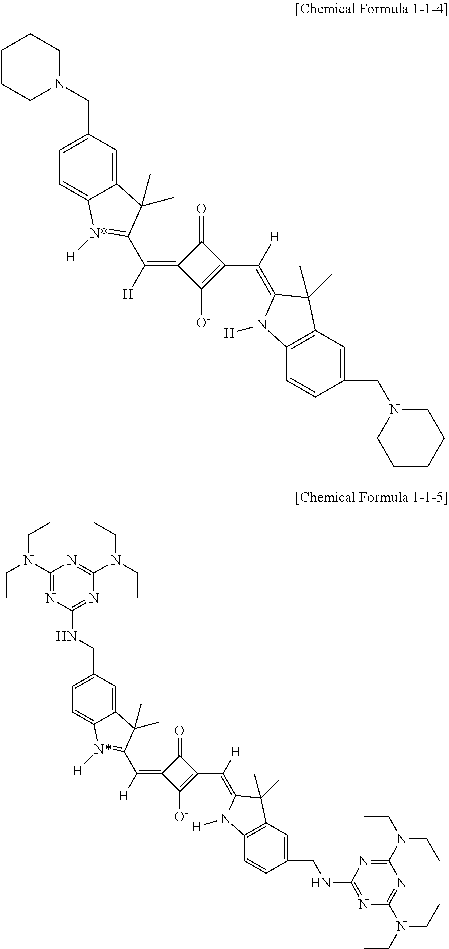

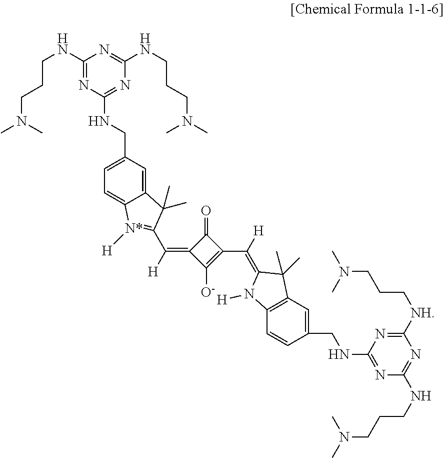

10. The photosensitive resin composition as claimed in claim 1, wherein:
the dispersion aid includes the compound represented by Chemical Formula 1 as a core,
a shell surrounding the core, the shell being represented by Chemical Formula 2, 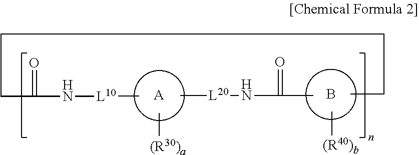
in Chemical Formula 2,
A and B are each independently a benzene ring, a pyridine ring, or a furan ring,
L¹⁰ and L²⁰ are each independently a single bond, or a substituted or unsubstituted C1 to C10 alkylene group,
R³⁰ and R⁴⁰ are each independently a halogen atom,
a and b are each independently an integer of 0 to 4, and
n is an integer of 2 to 10.

11. The photosensitive resin composition as claimed in claim 10, wherein the shell is represented by one of the following chemical formulae:

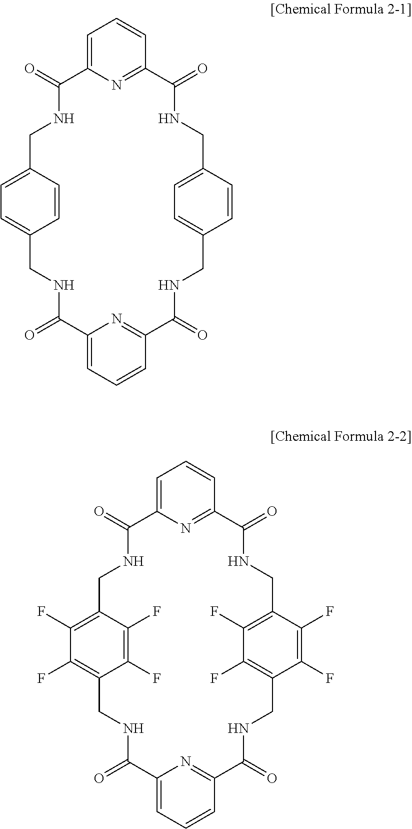 [SMILES: O=C1NCc2ccc(cc2)CNC(=O)c2cccc(n2)C(=O)NCc2ccc(cc2)CNC(=O)c2cccc1n2 ; O=C1NCc2c(F)c(F)c(c(F)c2F)CNC(=O)c2cccc(n2)C(=O)NCc2c(F)c(F)c(c(F)c2F)CNC(=O)c2cccc1n2]

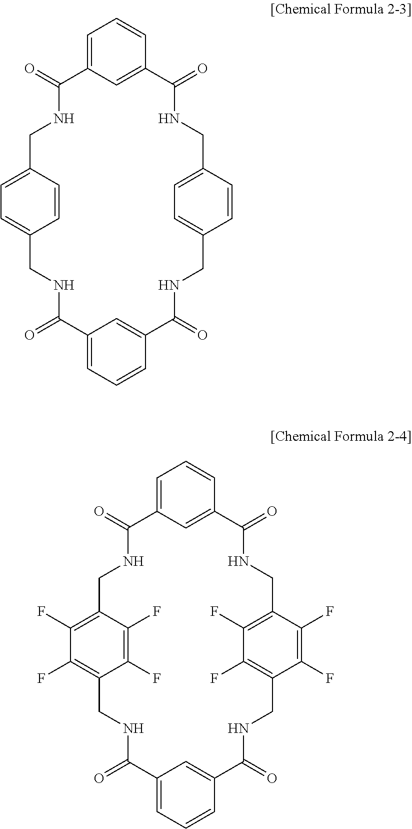 [SMILES: O=C1NCc2ccc(cc2)CNC(=O)c2cccc(c2)C(=O)NCc2ccc(cc2)CNC(=O)c2cccc1c2 ; O=C1NCc2c(F)c(F)c(c(F)c2F)CNC(=O)c2cccc(c2)C(=O)NCc2c(F)c(F)c(c(F)c2F)CNC(=O)c2cccc1c2]

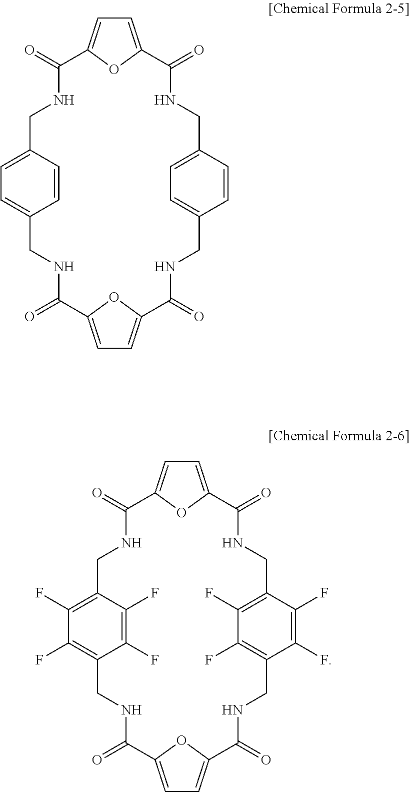 [SMILES: O=C1NCc2ccc(cc2)CNC(=O)c2ccc(o2)C(=O)NCc2ccc(cc2)CNC(=O)c2ccc1o2 ; O=C1NCc2c(F)c(F)c(c(F)c2F)CNC(=O)c2ccc(o2)C(=O)NCc2c(F)c(F)c(c(F)c2F)CNC(=O)c2ccc1o2]

12. The photosensitive resin composition as claimed in claim 1, wherein the dispersion aid is represented by one of the following chemical formulae:

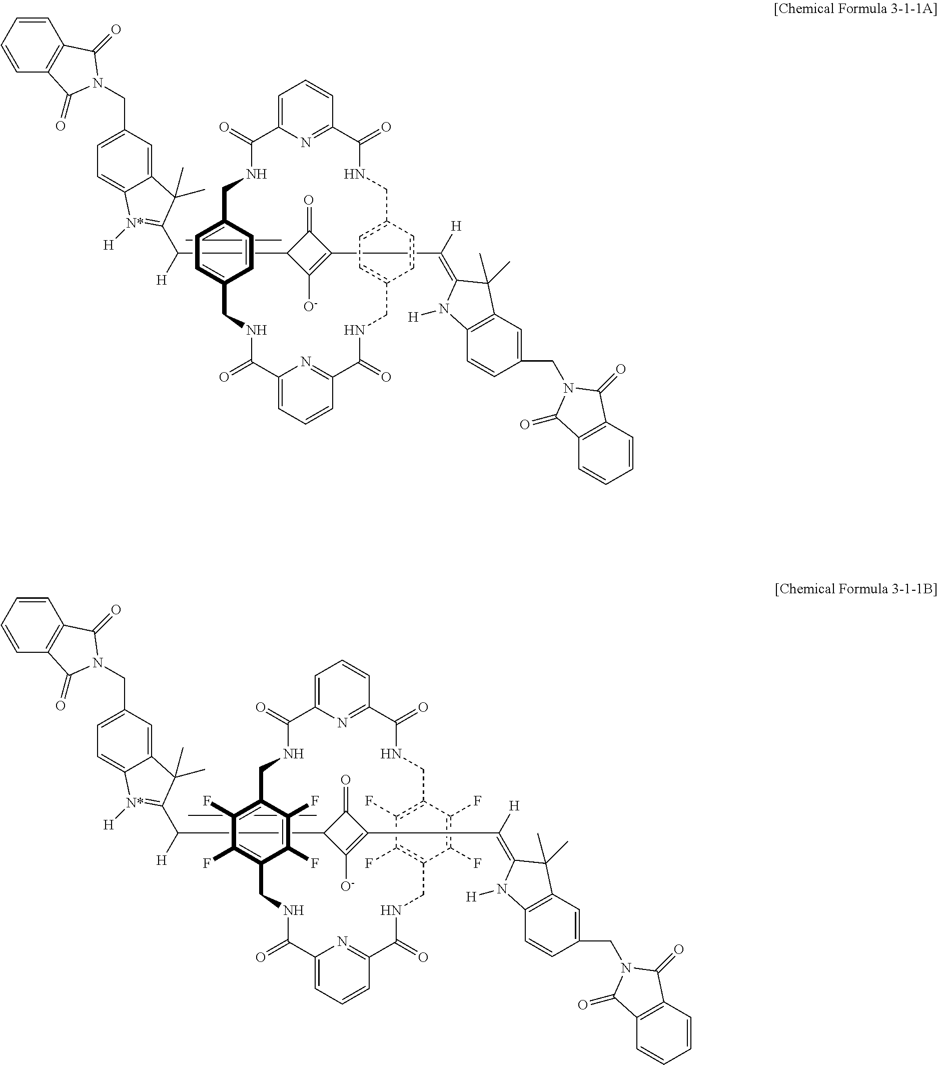

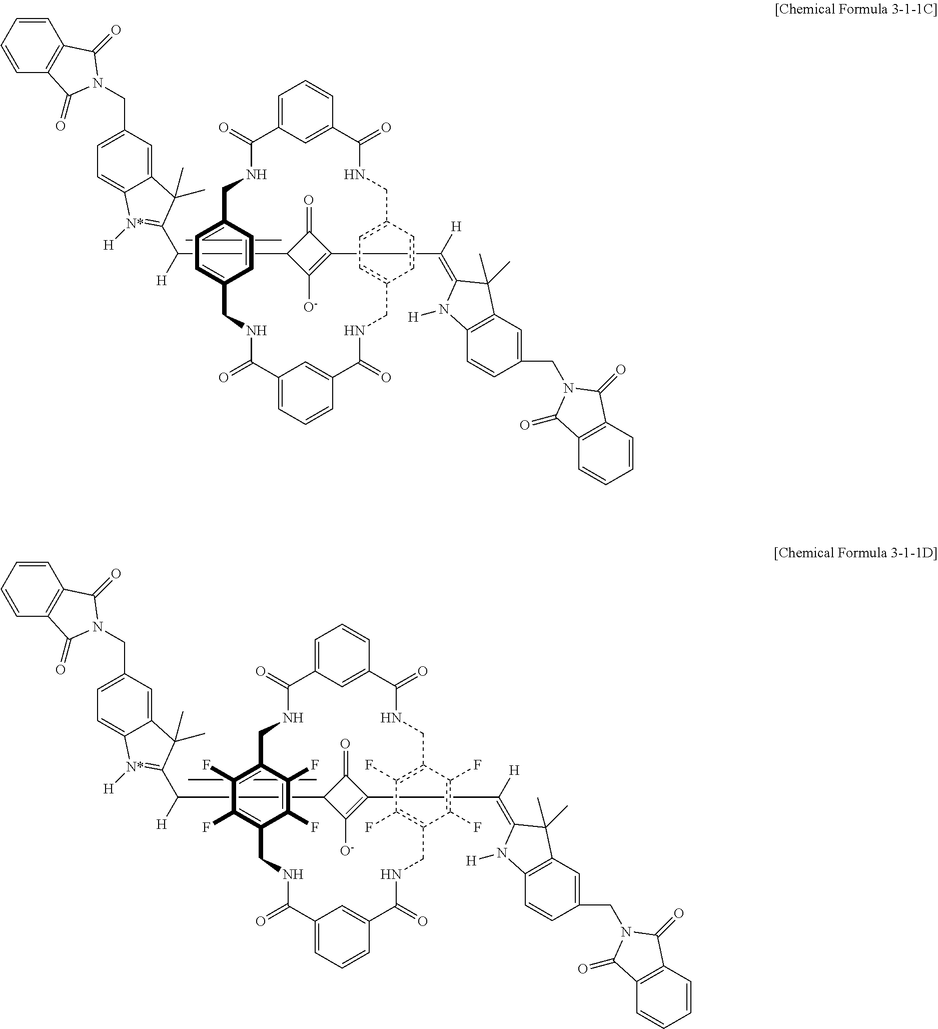

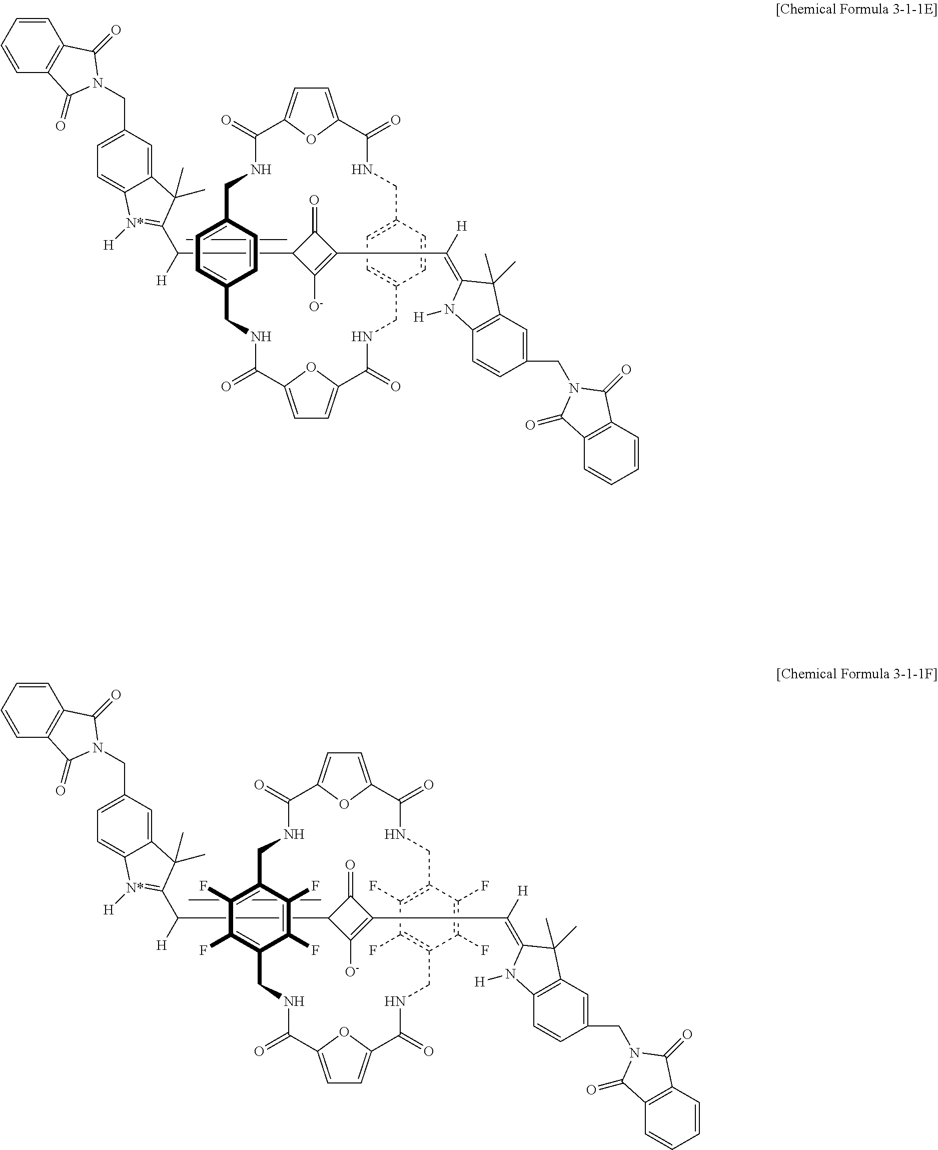

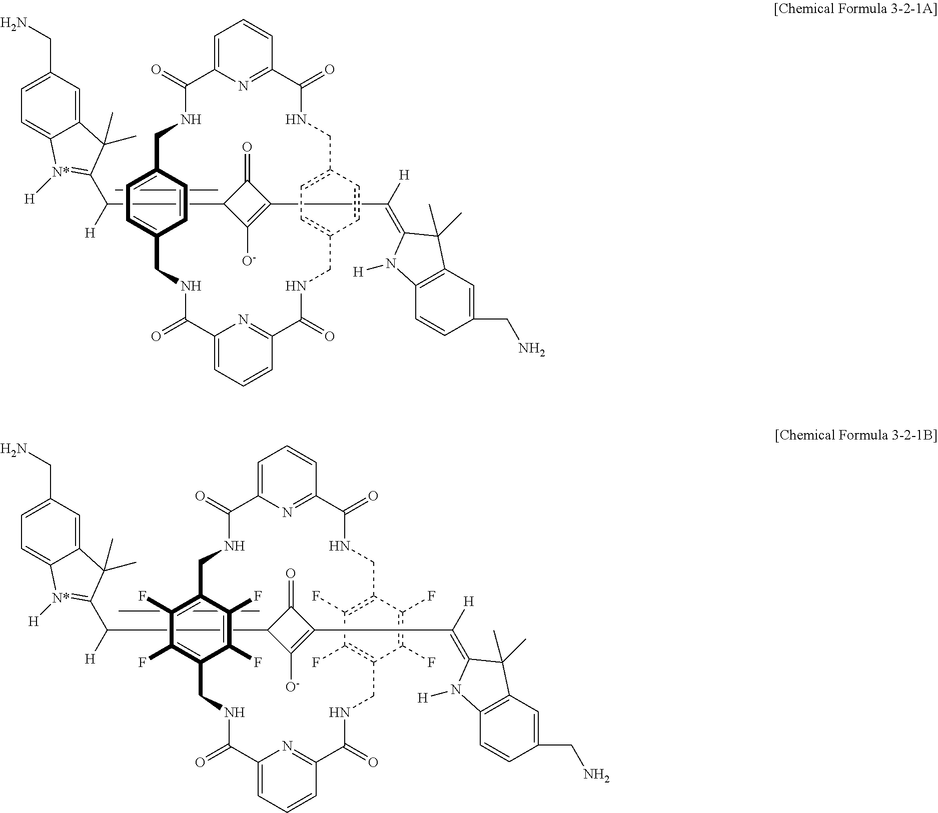

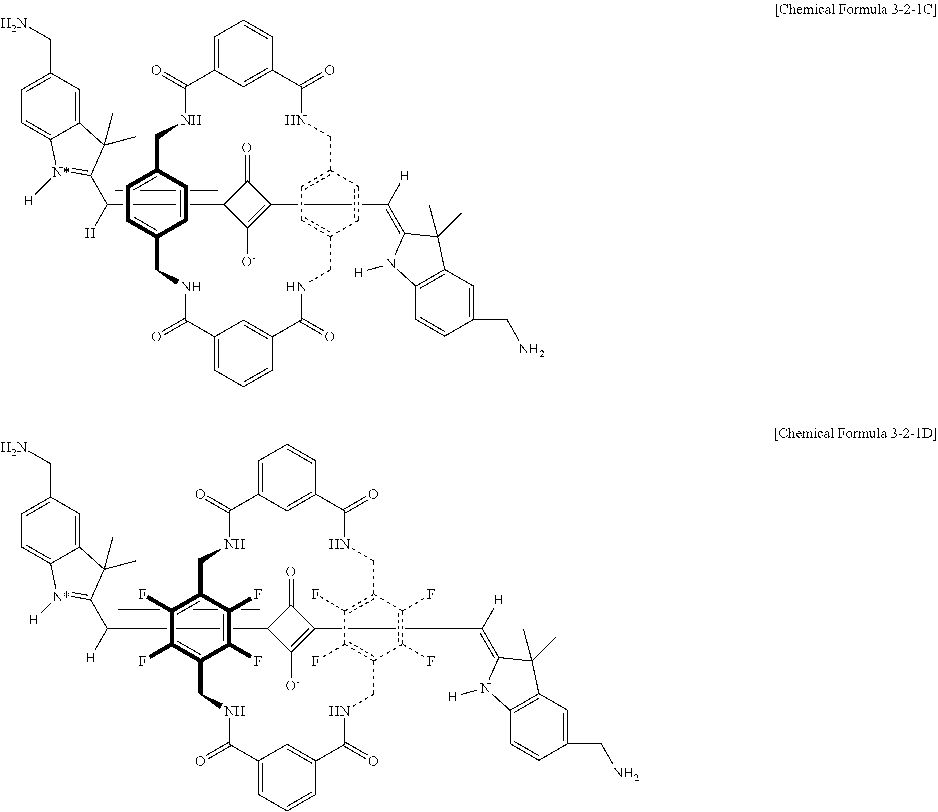

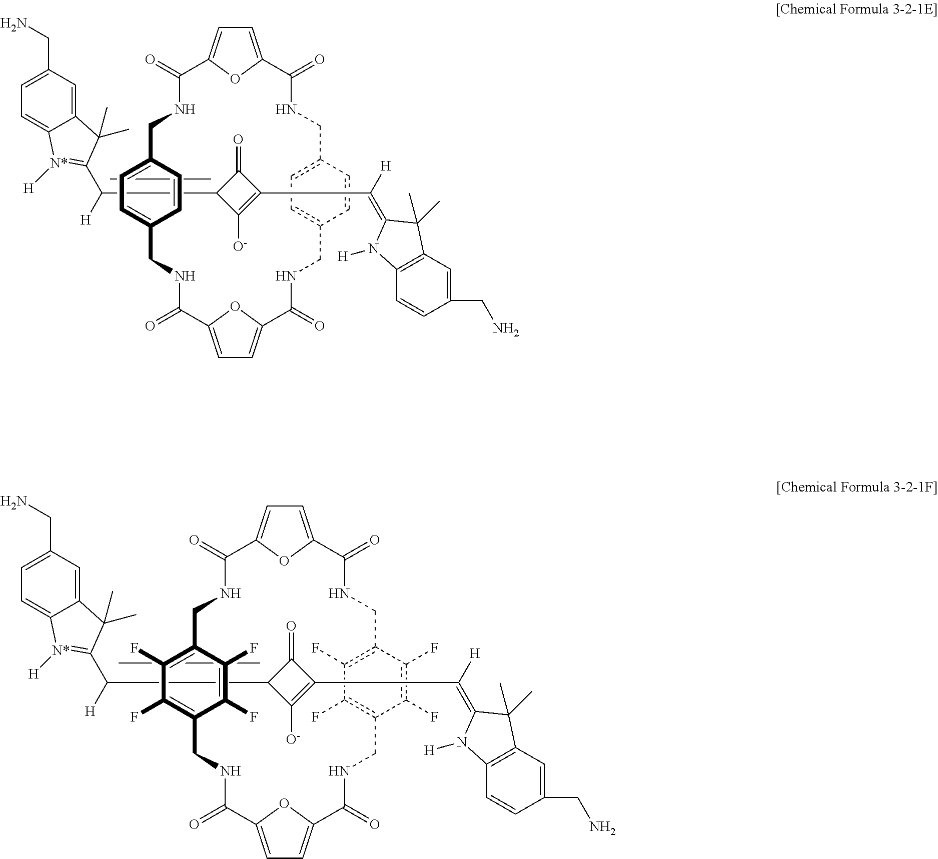

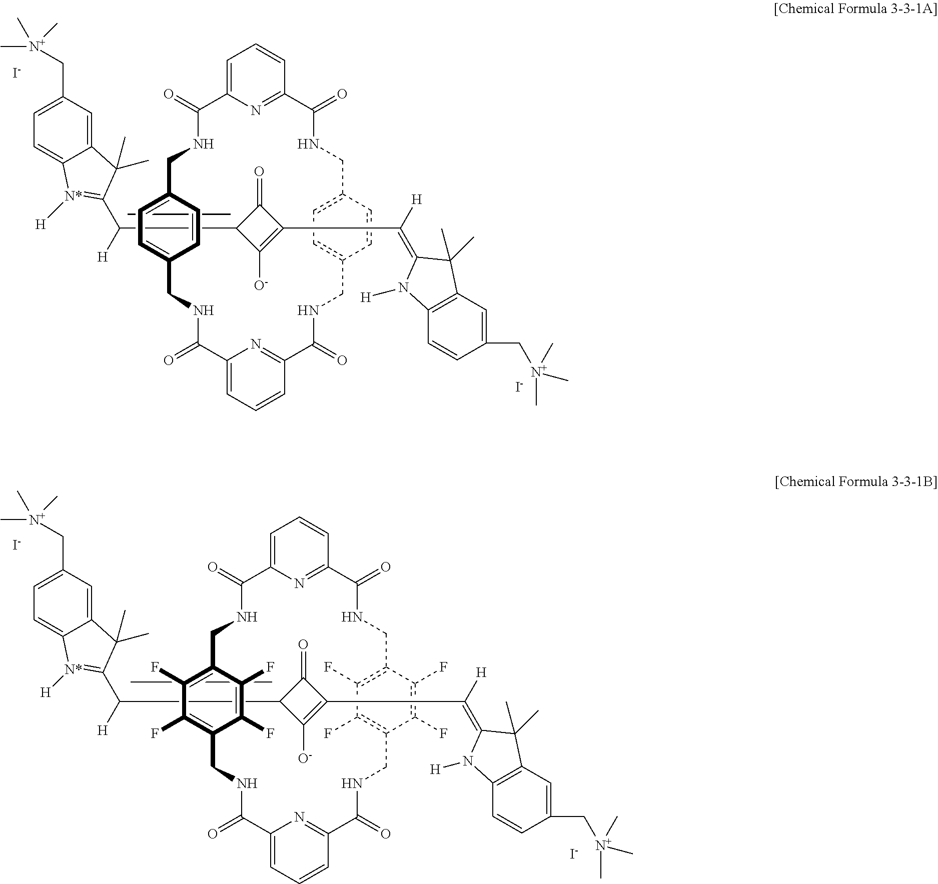

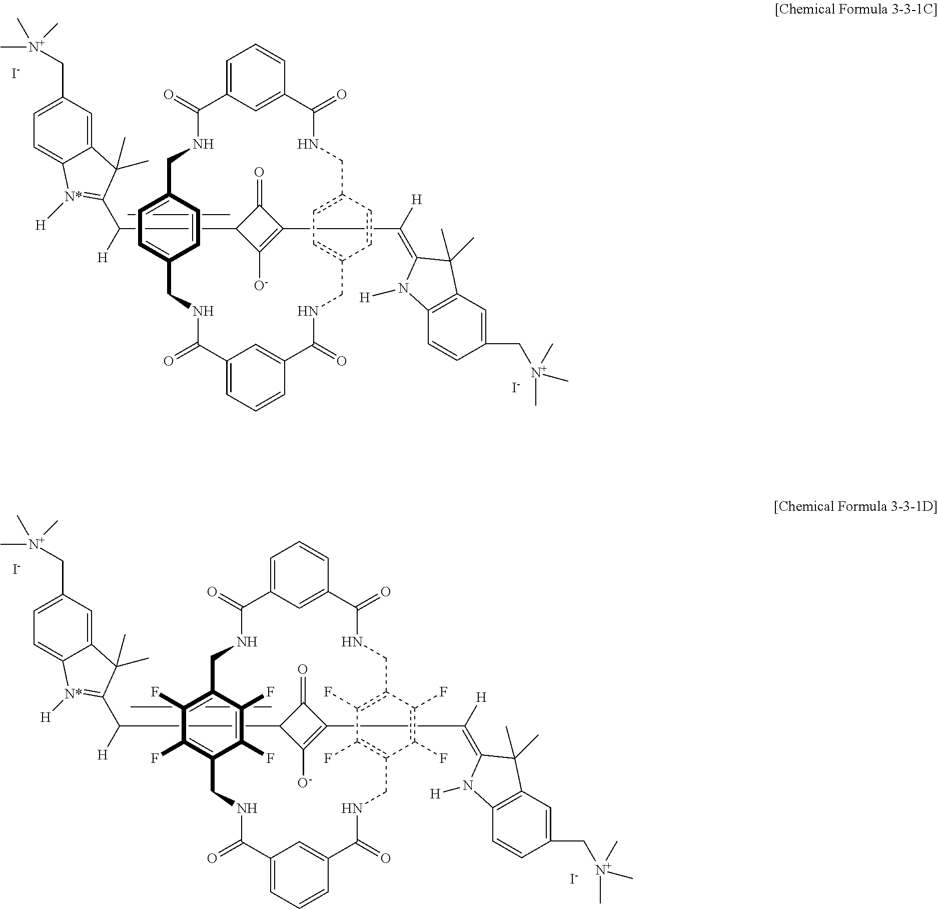

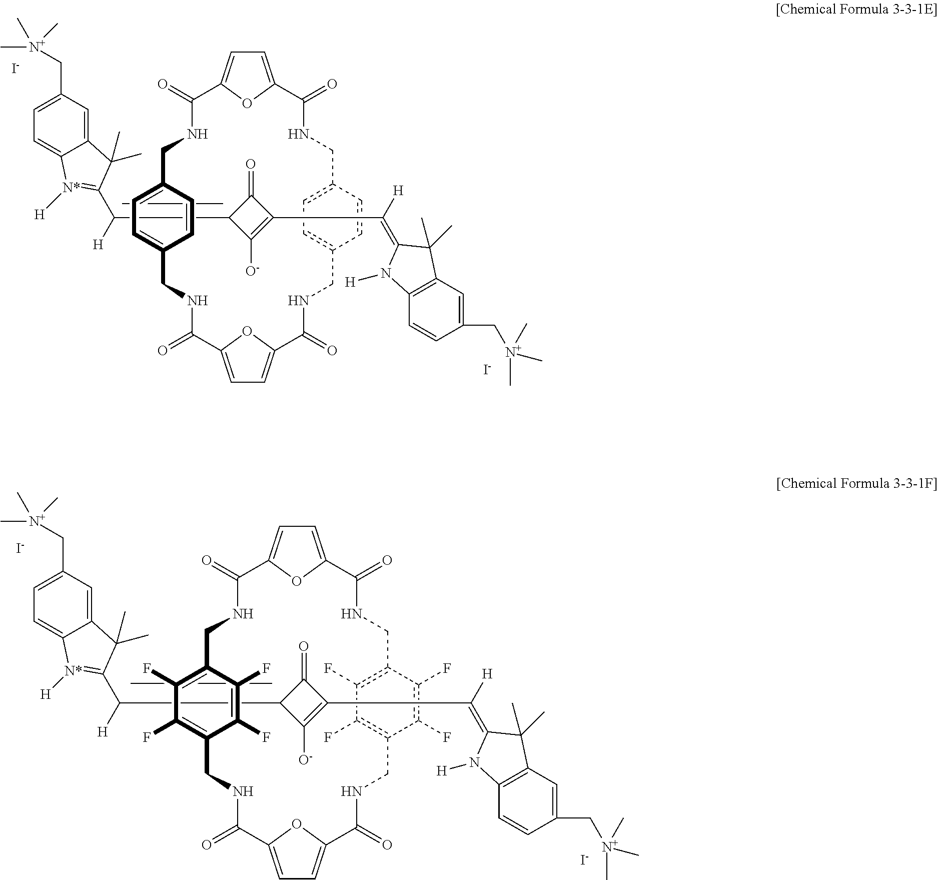

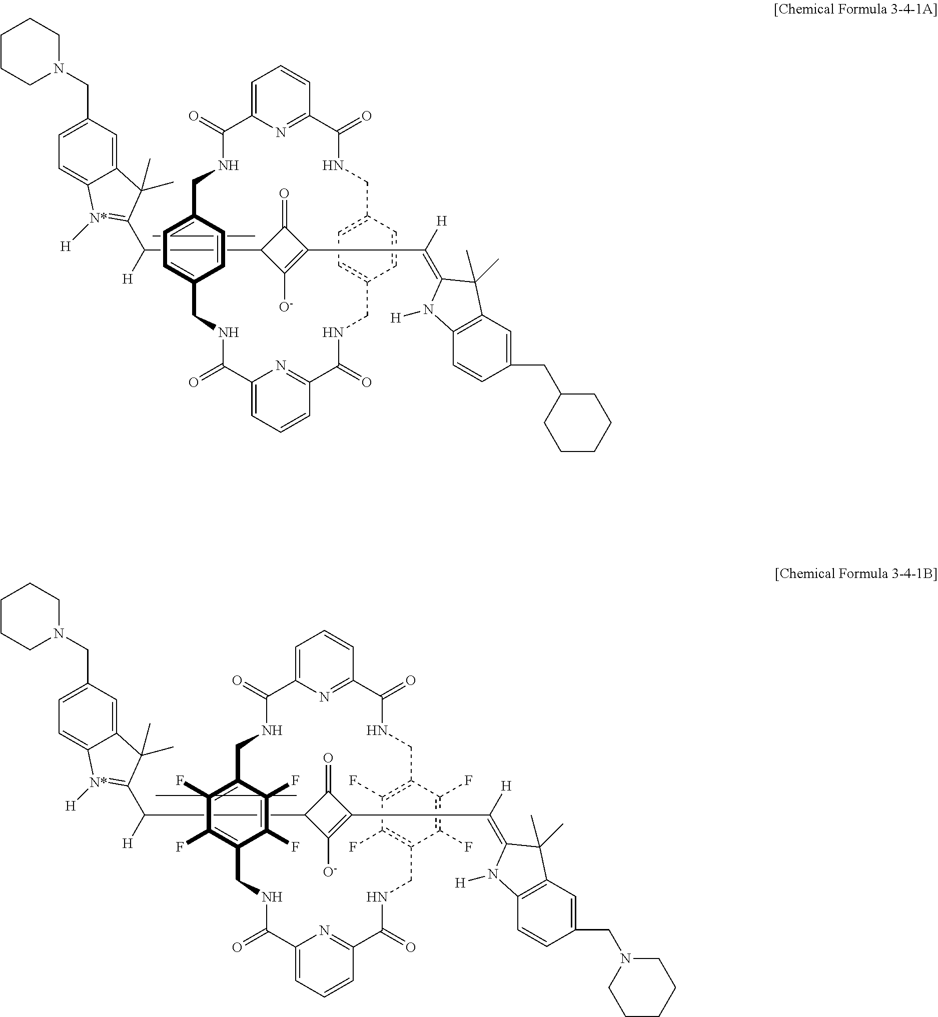

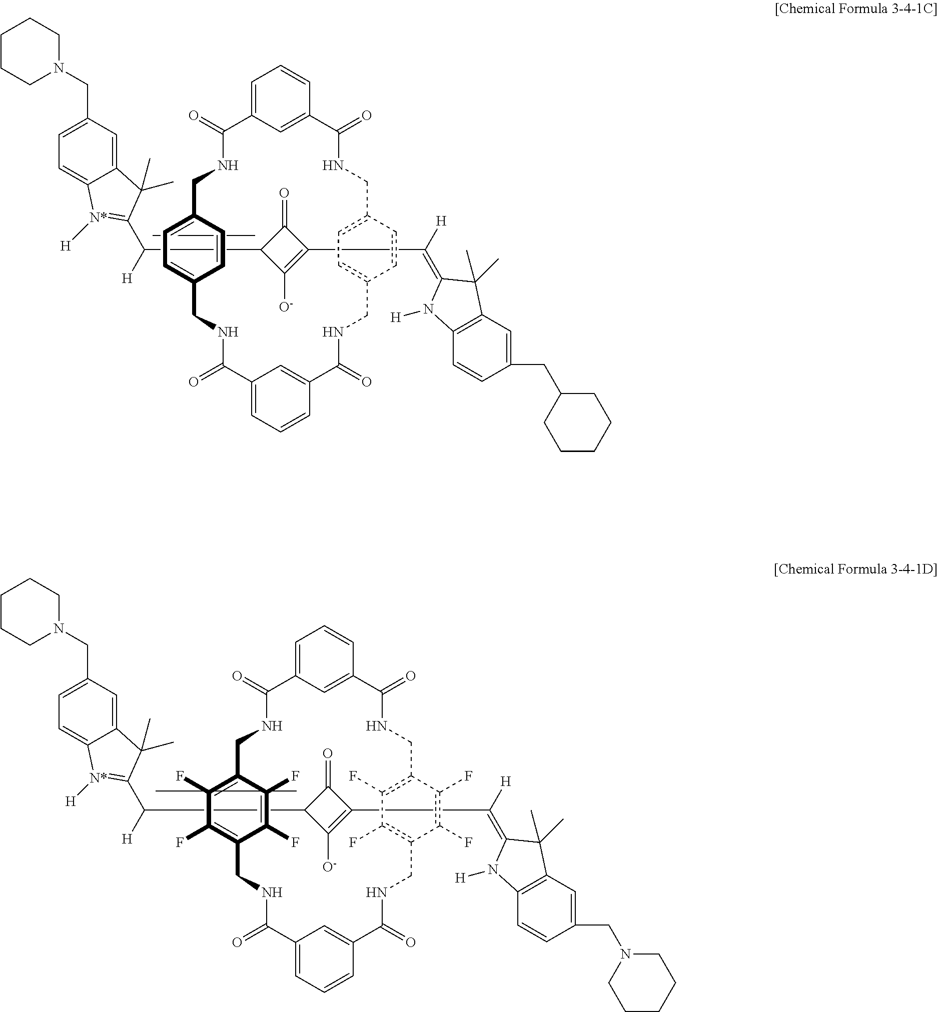

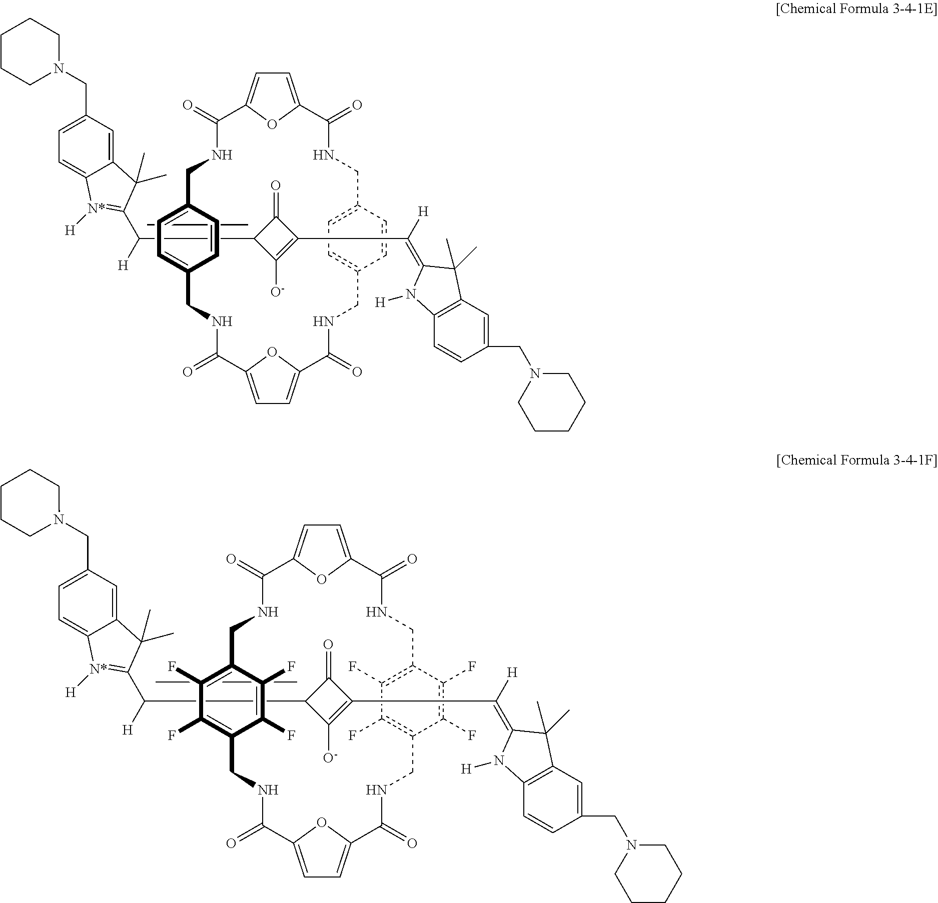

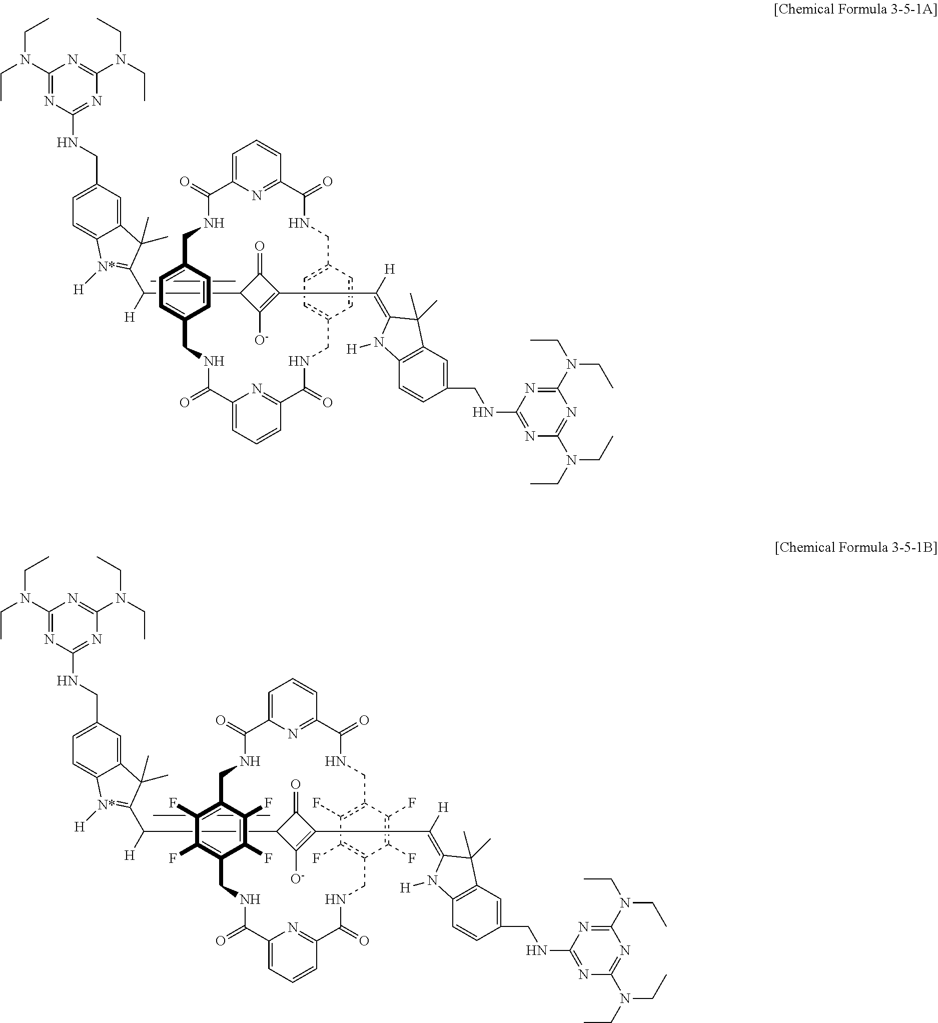

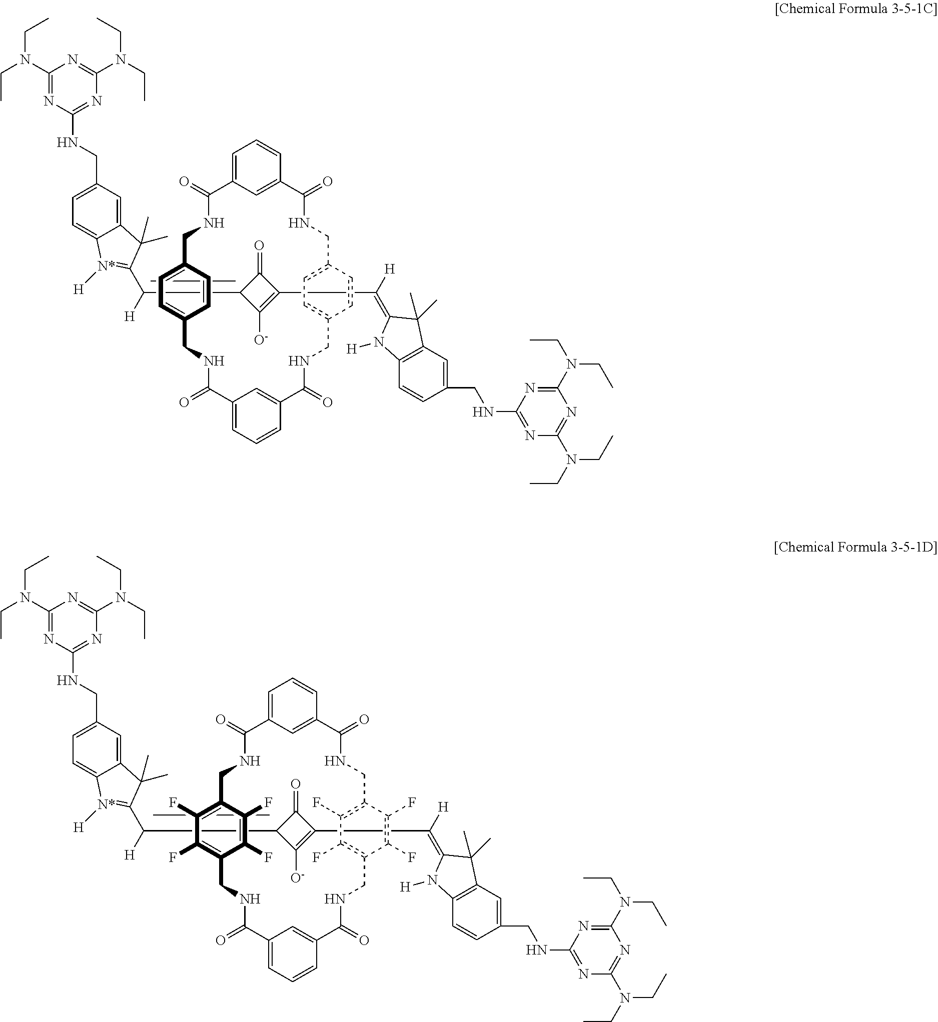

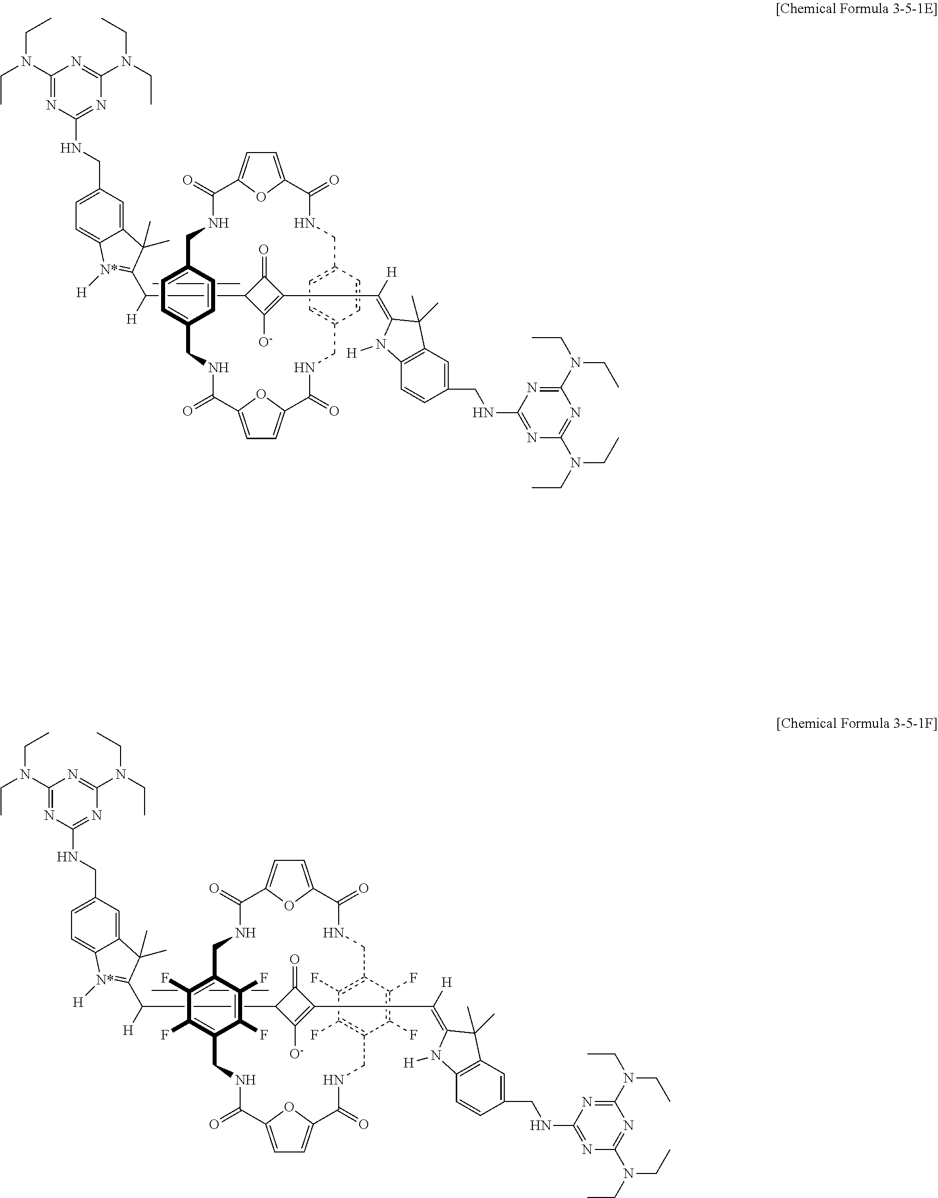

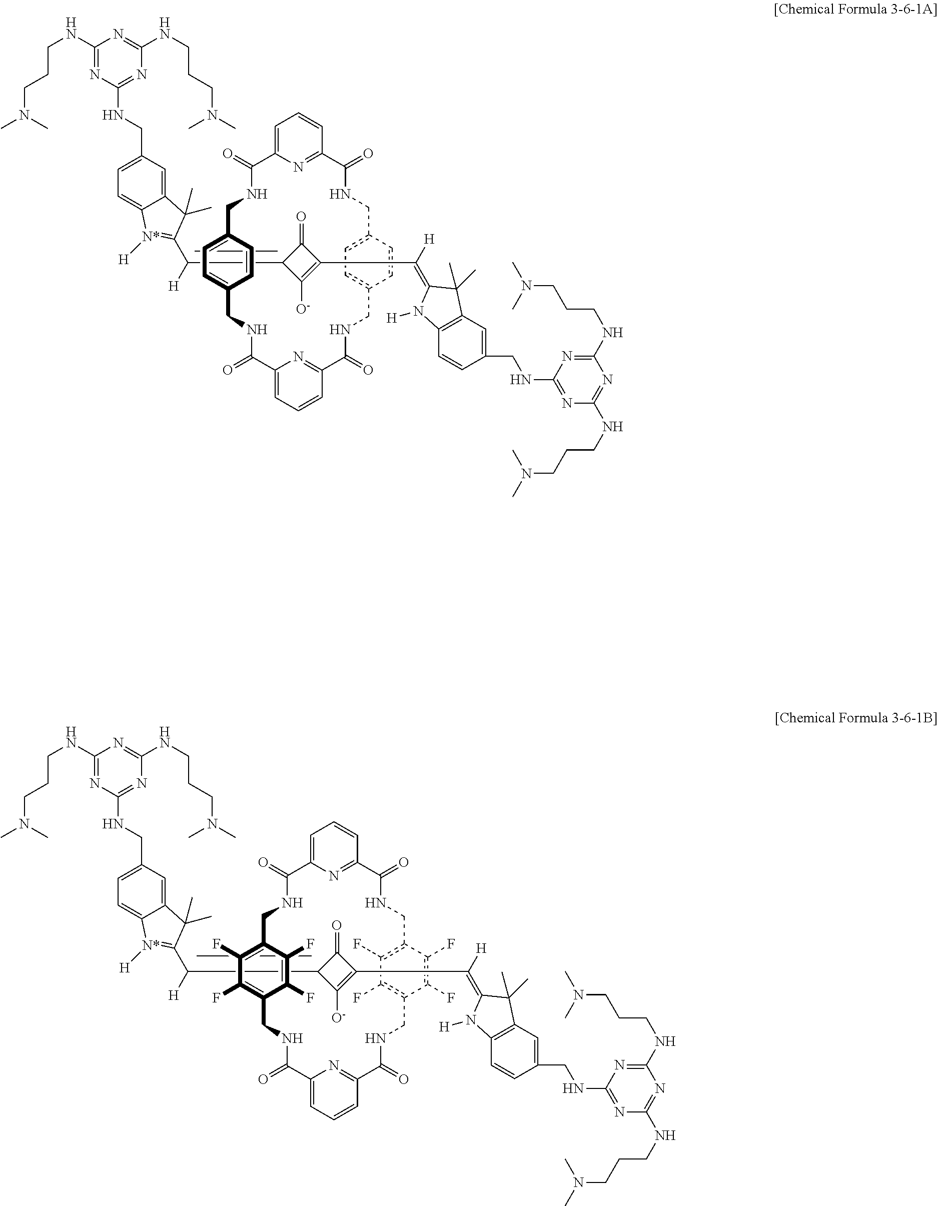

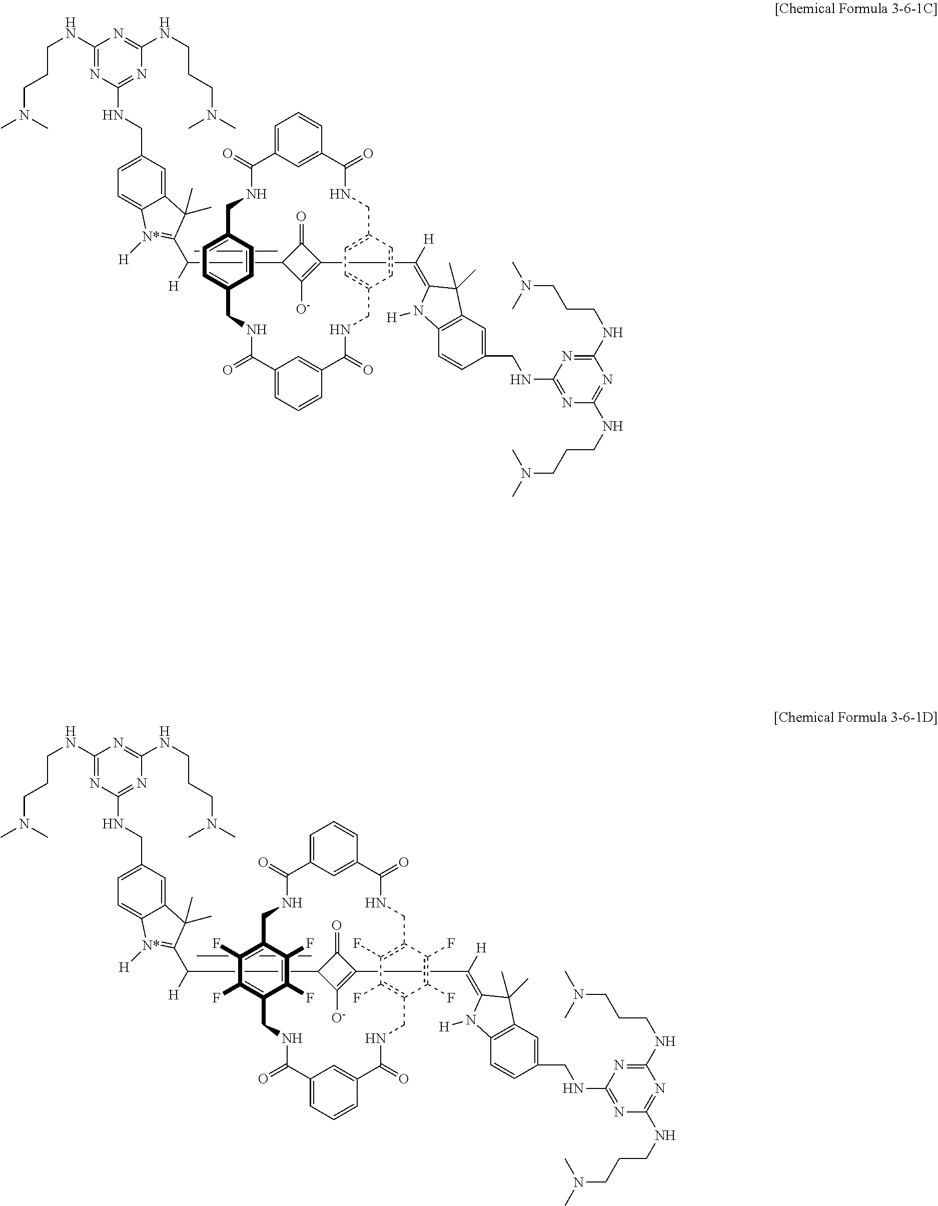

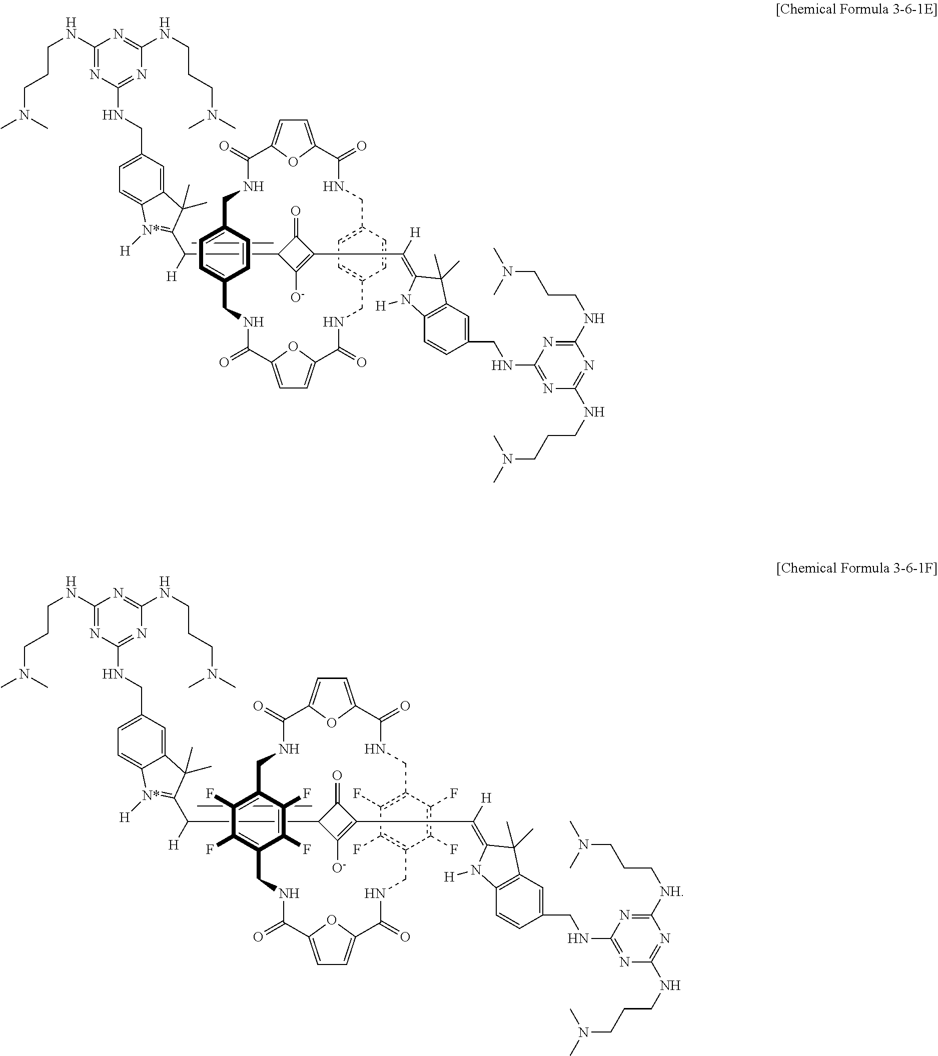

13. The photosensitive resin composition as claimed in claim 1, wherein the dispersion aid has a maximum absorption wavelength of about 530 nm to about 700 nm.

14. The photosensitive resin composition as claimed in claim 1, wherein the dispersion aid is included in the composition in an amount of about 0.5 wt % to about 6 wt % based on a total weight of the photosensitive resin composition.

15. The photosensitive resin composition as claimed in claim 1, wherein a weight ratio of the dispersion aid and the pigment is about 1:20 to about 1:70.

16. The photosensitive resin composition as claimed in claim 1, wherein the photosensitive resin composition includes:
about 0.5 wt % to about 50 wt % of the colorant,
about 0.1 wt % to about 10 wt % of the photopolymerizable compound,
about 0.1 wt % to about 10 wt % of the photopolymerization initiator,
about 0.5 wt % to about 15 wt % of the binder resin, and
the solvent, all wt % being based on a total weight of the photosensitive resin composition.

17. A photosensitive resin layer manufactured using the photosensitive resin composition according to claim 1.

18. The photosensitive resin layer as claimed in claim 17, wherein the photosensitive resin layer is a color negative photoresist.

19. A color filter comprising the photosensitive resin layer according to claim 17.

20. A display device comprising the color filter according to claim 19.
